(19) United States
(12) Patent Application Publication
(10) Pub. No.: US 2015/0333272 A1
(43) Pub. Date: Nov. 19, 2015

(54) TRANSPARENT ELECTRODE, ELECTRONIC DEVICE, AND ORGANIC ELECTROLUMINESCENT ELEMENT

(71) Applicant: Konica Minolta, Inc., Tokyo (JP)

(72) Inventors: Hidekane Ozeki, Tokyo (JP); Takayuki Iijima, Tokyo (JP); Kazuhiro Yoshida, Tokyo (JP); Takeshi Hakii, Kanagawa (JP)

(21) Appl. No.: 14/403,343

(22) PCT Filed: May 24, 2013
(86) PCT No.: PCT/JP2013/064436

§ 371 Date: Nov. 24, 2014

(30) Foreign Application Priority Data
May 31, 2012 (JP) 2012-123860
Oct. 23, 2012 (JP) 2012-233430

(51) Int. Cl. H01L 51/00

(52) U.S. Cl. CPC H01L 51/0072; H01L 51/0071; H01L 51/0073; H01L 51/0067; H01L 51/5215

(57) ABSTRACT

A transparent electrode includes a conductive layer and an intermediate layer disposed adjacent to the conductive layer. The intermediate layer contains an asymmetric compound having a nitrogen atom having an unshared electron pair uninvolved in aromaticity. The conductive layer is composed of silver as a main component.

### TECHNICAL FIELD

Embodiments of the invention relate to a transparent electrode, an electronic device and an organic electroluminescent element, particularly a transparent electrode having both conductivity and optical transparency, and an electronic device and an organic electroluminescent element each provided with the transparent electrode.

### BACKGROUND

An organic electroluminescent element (also called an “organic EL element” or an “organic-field light-emitting element”), which utilizes electroluminescence (hereinafter abbreviated to “EL”) of an organic material, is a thin-film type completely-solid state element capable of light emission at a low voltage of about several volts to several ten volts and having many excellent characteristics; for example, high luminescence, high efficiency of light emission, thin and light, and therefore recently has attracted attention as a surface emitting body for backlights of various displays, display boards such as signboards and emergency lights, and light sources of lights.

The organic EL element is configured in such a way that a luminescent layer composed of an organic material is sandwiched between two electrodes, and emission light generated in the luminescent layer passes through the electrode(s) and is extracted to the outside. For that, at least one of the two electrodes is configured as a transparent electrode.

As a material constituting the transparent electrode, oxide semiconductor materials, such as indium tin oxide (SnO₂—In₂O₃, hereinafter abbreviated to ITO), are used in general, but a material composed of ITO and silver stacked to reduce resistance has been investigated, for example, in Japanese Patent Application Publication Nos. 2002-15623 and 2006-164961. However, because ITO uses a rare metal, indium, material costs are high, and also annealing at about 300° C. is needed after its deposition in order to reduce resistance.

Then, there have been proposed: an art to make a thin film with an alloy of silver (Ag), which has high electrical conductivity, and magnesium (Mg); and an art to make a thin film, instead of indium, with a metal material which is available at low costs as a raw material. (Refer to, for example, Patent Documents 1 and 2.) In the invention of Patent Document 1, use of an alloy of silver and magnesium as an electrode material allows an electrode to have desired conductivity under a thin-film condition as compared with an electrode formed of silver alone, thereby having both transmittance and conductivity.

However, there are problems that resistance of the electrode obtained by the method of Patent Document 1 is about 100Ω/□ at the lowest, which is insufficient as conductivity of a transparent electrode, and a driving voltage cannot be lower, and that performance easily deteriorates over time because magnesium is easily oxidized. Further, in Patent Document 2, there are described transparent conductive films using as raw materials metal materials such as zinc (Zn) and tin (Sn), which are available at low costs, instead of indium (In). However, there are problems that these alternative metals do not reduce resistance sufficiently, that a ZnO transparent conductive film containing zinc reacts with water, whereby its properties easily change, and that an SnO₂ transparent conductive film containing tin is difficult to process by etching.

On the other hand, there is described an organic electroluminescent element using, as a cathode, a thin silver film which is about 15 nm, has high transparency and is formed by vapor deposition. (Refer to, for example, Patent Document 3.) However, in the method proposed in Patent Document 3, because the formed silver film is still thick as an electrode, light transmittance (transparency) as a transparent electrode is insufficient, and migration (transfer of atoms) easily occurs. When the silver film is made thinner, conductivity and the like are difficult to maintain. Therefore, development of an art to achieve both optical transparency and conductivity is desperately desired.

### RELATED ART DOCUMENTS

Patent Document 1: Japanese Patent Application Publication No. 2006-344497

Patent Document 2: Japanese Patent Application Publication No. 2007-031786

Patent Document 3: U.S. Patent Application Publication No. 2011/0260148

### SUMMARY OF THE INVENTION

Embodiments of the claimed invention provide a transparent electrode having sufficient conductivity and optical transparency, and an electronic device and an organic electroluminescent element each provided with the transparent electrode, thereby capable of being driven at a low voltage.

The inventors have found out that a transparent electrode having a multilayer structure of a conductive layer and an intermediate layer disposed adjacent to the conductive layer, wherein the intermediate layer contains an asymmetric compound which has a nitrogen atom having an unshared electron pair uninvolved in aromaticity and has a nitrogen atom content percentage of 0.40 or more, and the conductive layer is composed of silver as a main component can realize a transparent electrode having excellent optical transparency and conductivity and also having excellent durability, and an electronic device and an organic electroluminescent element each using the transparent electrode, thereby having high optical transparency, capable of being driven at a low driving voltage and having excellent durability.

That is, advantages of one or more embodiments of the invention may be achieved by the following aspects.

In one aspect, embodiments of the invention relate to a transparent electrode that includes a conductive layer and an intermediate layer disposed adjacent to the conductive layer. The intermediate layer contains an asymmetric compound having a nitrogen atom having an unshared electron pair uninvolved in aromaticity, and the conductive layer is composed of silver as a main component.

In one or more embodiments of the invention, a content percentage of the nitrogen atom having the unshared electron pair uninvolved in aromaticity in the asymmetric compound determined by an equation (1) below is 0.40 or more:

Content Percentage of Nitrogen Atom=(The Number of Nitrogen Atoms Having Unshared Electron Pairs Uninvolved in Aromaticity/Molecular Weight of Asymmetric Compound)×100. Equation (1)

In one or more embodiments of the invention, the asymmetric compound has an aromatic heterocyclic ring containing a nitrogen atom having an unshared electron pair uninvolved in aromaticity.

In one or more embodiments of the invention, the asymmetric compound has an azacarbazole ring, an azadibenzofuran ring or an azadibenzothiophene ring.

In one or more embodiments of the invention, the asymmetric compound has an azacarbazole ring.

In one or more embodiments of the invention, the asymmetric compound has a pyridine ring.

In one or more embodiments of the invention, the asymmetric compound has a γ,γ′-diazacarbazole ring or a β-carboline ring.

In another aspect, embodiments of the invention include and electronic device that includes one or more embodiments of the transparent electrode.

In another aspect, embodiments of the invention include an organic electroluminescent element that includes one or more embodiments of the transparent electrode.

### Advantageous Effects of the Invention

According to embodiments of the invention, there can be provided: a transparent electrode having excellent conductivity and optical transparency; and an electronic device and an organic electroluminescent element each provided with the transparent electrode, thereby having high optical transparency and capable of being driven at a low voltage.

The structure defined by one or more embodiments of the invention solves the above problems. Although appearance mechanism of the effects of one or more embodiments of the invention and action mechanism thereof are not entirely clear yet, they are conjectured as follows.

The transparent electrode of one or more embodiments of the invention has the conductive layer which contains silver as a main component on the upper side of the intermediate layer, and the intermediate layer contains the asymmetric compound (hereinafter may be referred to as a silver affinitive compound) having a nitrogen atom(s) having an unshared electron pair uninvolved in aromaticity, the nitrogen atom(s) having affinity for a silver atom(s).

With this structure, when the conductive layer is formed on the intermediate layer, the silver atom(s) constituting the conductive layer and the asymmetric compound having a nitrogen atom(s) having an unshared electron pair uninvolved in aromaticity, namely, the silver affinitive compound, contained in the intermediate layer, react with each other, and diffusion distance of the silver atom(s) on the surface of the intermediate layer decreases, whereby cohesion of the silver atom(s) at a specific point can be kept from occurring.

That is, the silver atoms are deposited by film growth in the single-layer growth mode (Frank-van der Merwe (FW) mode), in which the silver atoms first form a two-dimensional nucleus on the surface of the intermediate layer which contains the asymmetric compound having a nitrogen atom(s) having an unshared electron pair uninvolved in aromaticity, the nitrogen atoms having affinity for the silver atoms, and then form a two-dimensional single crystal layer having the formed nucleus as its center.

In general, silver atoms tend to be deposited in the shape of an island(s) by film growth in the island growth mode (Volumer-Weber (VW) mode), in which the silver atoms having adhered to the surface of an intermediate layer bind to each other while diffusing on the surface to forma three-dimensional nucleus (nuclei) and grow in the shape of a three-dimensional island(s). In embodiments of the invention, however, it is conjectured that the asymmetric compound having a nitrogen atom(s) having an unshared electron pair uninvolved in aromaticity contained in the intermediate layer prevents the island growth but promotes the single-layer growth.

Consequently, although being thin, the conductive layer in which silver atoms are uniformly distributed and which is uniform in thickness is obtained. As a result of that, the transparent electrode can be made as the one which ensures conductivity while keeping light transmittance as a thinner layer.

In one or more embodiments of the invention, the silver affinitive compound is the asymmetric compound having a nitrogen atom(s) having an unshared electron pair uninvolved in aromaticity, and the nitrogen atom(s) having an unshared electron pair is the atom(s) having affinity for a silver atom(s). When a large number of compounds having nitrogen atoms having unshared electron pairs uninvolved in aromaticity are contained in the intermediate layer, uniformity of the intermediate layer is occasionally reduced by cohesion of the compounds. However, the compounds being asymmetric increase amorphousness of the intermediate layer which contains the compounds, and also improve film density and uniformity of the intermediate layer. The conductive layer composed of silver as a main component and formed on the intermediate layer is considered to become thin and uniform thereby.

It is conjectured that as a result of that, a transparent electrode can be thinner, whereby there can be realized a transparent electrode having high light transmittance and excellent conductivity simultaneously.

### BRIEF DESCRIPTION OF THE DRAWINGS

FIG. 1A is a schematic cross sectional view showing an example of the structure of a transparent electrode in accordance with one or more embodiments of the invention.

FIG. 1B is a schematic cross sectional view showing an example of the structure of the transparent electrode in accordance with one or more embodiments of the invention.

FIG. 2 is a schematic cross sectional view showing a first embodiment of an organic EL element provided with the transparent electrode in accordance with one or more embodiments of the invention.

FIG. 3 is a schematic cross sectional view showing a second embodiment of an organic EL element provided with the transparent electrode in accordance with one or more embodiments of the invention.

FIG. 4 is a schematic cross sectional view showing a third embodiment of an organic EL element provided with the transparent electrode in accordance with one or more embodiments of the invention.

FIG. 5 is a schematic cross sectional view showing an example of an illumination device having a luminescent face which is enlarged by using organic EL elements provided with the transparent electrodes in accordance with one or more embodiments of the invention.

FIG. 6 is a schematic cross sectional view to explain a luminescent panel provided with an organic EL element produced in Examples in accordance with one or more embodiments of the invention.

### DETAILED DESCRIPTION

A transparent electrode in accordance with one or more embodiments of the invention includes a conductive layer and an intermediate layer disposed adjacent to the conductive layer, wherein the intermediate layer contains an asymmetric compound having a nitrogen atom(s) having an unshared electron pair uninvolved in aromaticity, and the conductive layer is composed of silver as a main component, whereby there can be realized a transparent electrode having sufficient conductivity and optical transparency.

In one or more embodiments of the invention, a content percentage of the nitrogen atom(s) having an unshared electron pair uninvolved in aromaticity in the asymmetric compound determined by Equation (1) be 0.40 or more. Consequently, there can be realized a transparent electrode having sufficient conductivity and optical transparency and also being excellent in durability (light transmittance stability).

As an embodiment of the present invention, the asymmetric compound may have an aromatic heterocyclic ring containing a nitrogen atom(s) having an unshared electron pair uninvolved in aromaticity so that the effects aimed by embodiments of the invention can be well demonstrated. Further, the asymmetric compound may have an azacarbazole ring, an azadibenzofuran ring or an azadibenzofuran ring, particularly an azacarbazole ring.

Further, the asymmetric compound may have a pyridine ring. Further, the asymmetric compound may have a γ,γ′-diazacarbazole ring or a β-carboline ring so that the conductive layer to be formed can be more homogenous.

An electronic device in accordance with one or more embodiments of the invention is provided with the transparent electrode in accordance with one or more embodiments of the invention. An organic electroluminescent element in accordance with one or more embodiments of the invention is provided with the transparent electrode in accordance with one or more embodiments of the invention.

Hereinafter, embodiments of the invention, its components, and forms/modes for carrying out embodiments of the invention are detailed. Note that, in embodiments of the invention, “- (to)” between values is used to mean that the values before and after the sign are inclusive as the lower limit and the upper limit.

<<1. Transparent Electrode>>

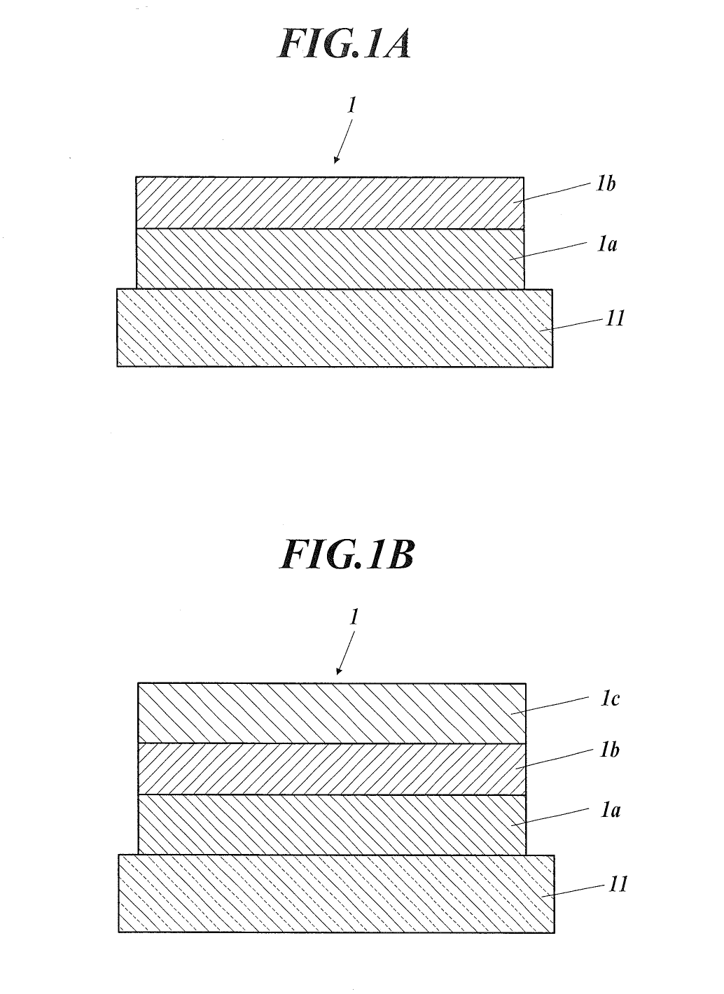

FIG. 1 is a schematic cross sectional view showing examples of the structure of a transparent electrode in accordance with one or more embodiments of the invention.

The structure of a transparent electrode 1 shown in FIG. 1(a) is a two-layer structure of an intermediate layer 1a and a conductive layer 1b disposed on the upper side of the intermediate layer 1a. For example, on the upper side of abase 11, the intermediate layer 1a and the conductive layer 1b are disposed in the order named. The intermediate layer 1a of one or more embodiments of the invention is a layer containing an asymmetric compound having a nitrogen atom(s) having an unshared electron pair uninvolved in aromaticity, and the conductive layer 1b of one or more embodiments of the invention disposed thereon is a layer composed of silver as a main component. In one or more embodiments of the invention, the main component of the conductive layer 1b means that silver content in the conductive layer 1b is 60 mass % or more, 80 mass % or more, 90 mass % or more and 98 mass % or more. Further, the “transparent” of the transparent electrode 1 one or more embodiments of the invention means that light transmittance measured at a wavelength of 550 nm is 50% or more, 70% or more and 80% or more.

As the layer structure of the transparent electrode 1 of one or more embodiments of the invention, as shown in FIG. 1(b), a layer structure in which the intermediate layer 1a and the conductive layer 1b are on the base 11, a second intermediate layer 1c is disposed on the conductive layer 1b, and the conductive layer 1b is sandwiched between the intermediate layer 1a and the intermediate layer 1c.

In one or more embodiments of the invention, the transparent electrode 1 having a multilayer structure of the intermediate layer 1a and the conductive layer 1b formed on the upper side thereof may be configured in such a way that the conductive layer 1b has the upper side which is covered with a protective layer or on which a second conductive layer is disposed. In this case, in order not to reduce optical transparency of the transparent electrode 1, the protective layer and the second conductive layer may have high optical transparency. On the lower side of the intermediate layer 1a, namely, between the intermediate layer 1a and the base 11, a functional layer may also be disposed as needed.

Next, structural requirements of the base 11, which is used to hold the transparent electrode 1 having a multilayer structure, and the intermediate layer 1a and the conductive layer 1b, which constitute the transparent electrode 1, are detailed in the order named in accordance with one or more embodiments of the invention.

[Base]

The base 11, which is used to hold the transparent electrode 1 in one or more embodiments of the invention, is, for example, glass or plastic, but not limited thereto. The base 11 may be transparent or nontransparent. In the case where the transparent electrode 1 of embodiments of the invention is used for an electronic device which extracts light from the base 11 side, the base 11 may be transparent. Examples of the transparent base 11 used may include glass, quartz and a transparent resin film.

Examples of the glass include silica glass, soda-lime silica glass, lead glass, borosilicate glass and alkali-free glass. On the surface of any of these glass materials, as needed, a physical treatment such as polishing may be carried out, or a coating composed of an inorganic matter or an organic matter or a hybrid coating composed of these may be formed, in view of adhesion to the intermediate layer 1a, durability and smoothness.

Examples of the resin film include polyesters, such as polyethylene terephthalate (PET) and polyethylene naphthalate (PEN); polyethylene; polypropylene; cellulose esters and their derivatives, such as cellophane, cellulose diacetate, cellulose triacetate (TAC), cellulose acetate butyrate, cellulose acetate propionate (CAP), cellulose acetate phthalate and cellulose nitrate; polyvinylidene chloride; polyvinyl alcohol; polyethylene vinyl alcohol; syndiotactic polystyrene; polycarbonate; norbornene resin; polymethyl pentene; polyether ketone; polyimide; polyether sulfone (PES); polyphenylene sulfide; polysulfones; polyether imide; polyether ketone imide; polyamide; fluororesin; nylon; polymethyl methacrylate; acrylic; polyarylates; and cycloolefin resins, such as ARTON™ (produced by JSR Corporation) and APEL® (produced by MITSUI CHEMICALS, INC.).

On the surface of the resin film, a coating (also called a barrier layer) composed of an inorganic matter or an organic matter or a hybrid coating composed of these may be formed. This coating or hybrid coating may be a barrier film having a water vapor permeability (at 25±0.5° C. and a relative humidity of 90±2% RH) of 0.01 g/(m²·24 h) or less determined by a method in conformity with JIS-K-7129-1992. Further, the coating or hybrid coating may be a high-barrier film having an oxygen permeability of 1×10⁻³ ml/(m²·24 h·atm) or less determined by a method in conformity with JIS-K-7126-1987 and a water vapor permeability of 1×10⁻⁵ g/(m²·24 h) or less.

As a material which forms the above described barrier film, any material can be used as long as it is impermeable to factors such as moisture and oxygen which cause deterioration of an electronic device or an organic EL element. For example, silicon dioxide, silicon nitride or the like can be used. In order to reduce fragility of the barrier film, the barrier film may have a multilayer structure of an inorganic layer composed of any of the above and a layer (organic layer) composed of an organic material. Although the stacking order of the inorganic layer and the organic layer is not particularly limited, these layers may be alternately stacked multiple times.

A forming method of the barrier film includes but is not particularly limited to: vacuum deposition, sputtering, reactive sputtering, molecular beam epitaxy, cluster ion beam, ion plating, plasma polymerization, atmospheric pressure plasma polymerization, plasma CVD (Chemical Vapor Deposition), laser CVD, thermal CVD and coating. Atmospheric pressure plasma polymerization described in Japanese Patent Application Publication No. 2004-68143 may be used.

On the other hand, in the case where the base 11 is composed of a nontransparent material, a metal substrate or film composed of aluminum, stainless steel or the like, a nontransparent resin substrate, a ceramic substrate, or the like can be used.

[Intermediate Layer]

The intermediate layer 1a of one or more embodiments of the invention is a layer made with an asymmetric compound having a nitrogen atom(s) having an unshared electron pair uninvolved in aromaticity. In the case where this intermediate layer 1a is formed on the base 11, examples of its forming method include wet processes, such as application, the inkjet method, coating and dipping, and dry processes, such as vapor deposition (resistance heating, the EB (Electron Beam) method, etc.), sputtering and CVD.

(Asymmetric Compound Having Nitrogen Atom(s) Having Unshared Electron Pair Uninvolved in Aromaticity)

In the transparent electrode 1 of one or more embodiments of the invention, the intermediate layer 1a contains an asymmetric compound having a nitrogen atom(s) having an unshared electron pair uninvolved in aromaticity.

In accordance with one or more embodiments of the invention, the “nitrogen atom having an unshared electron pair uninvolved in aromaticity” means a nitrogen atom having an unshared electron pair (also called a lone pair) which is not directly involved in aromaticity of an unsaturated cyclic compound as an essential component, namely, a nitrogen atom(s) the unshared electron pair of which is uninvolved in a nonlocalized π electron system on a conjugated unsaturated cyclic structure (aromatic ring) in the chemical structural formula as an essential component to exhibit aromaticity.

The “aromaticity” in embodiments of the invention means that, in the conjugated (resonant) unsaturated cyclic structure in which atoms having π electrons are arranged in the shape of a ring, the number of electrons contained in the nonlocalized π electron system on the ring satisfies 4n+2 (n=0 or a natural number) (i.e. the Hückel's rule).

For example, a nitrogen atom of pyridine, a nitrogen atom of an amino group as a substituent, and the like come under the “nitrogen atom having an unshared electron pair uninvolved in aromaticity” in accordance with one or more embodiments of the invention.

The “asymmetric compound” in embodiments of the invention means that the chemical structure of a compound has neither an axis of line symmetry nor an axis of rotation. Rotational isomers are not regarded as being different but are regarded as the same compound.

For example, ET-1 and ET-2 shown below as comparative compounds (object compounds) each have an axis of line symmetry at the center, and right and left of this axis of line symmetry are mirror images and have line symmetry. This structure is not asymmetric. ET-3 has three-rotational symmetry with which when rotated 120 degrees with the center of the molecule as an axis, ET-3 is superposed on itself. On the other hand, the asymmetric compound of embodiments of the invention has no line symmetry axis, and also when rotated with the center of the molecule as an axis, the asymmetric compound cannot be superposed on itself, and therefore has no axis of rotational symmetry, which is a structural feature.

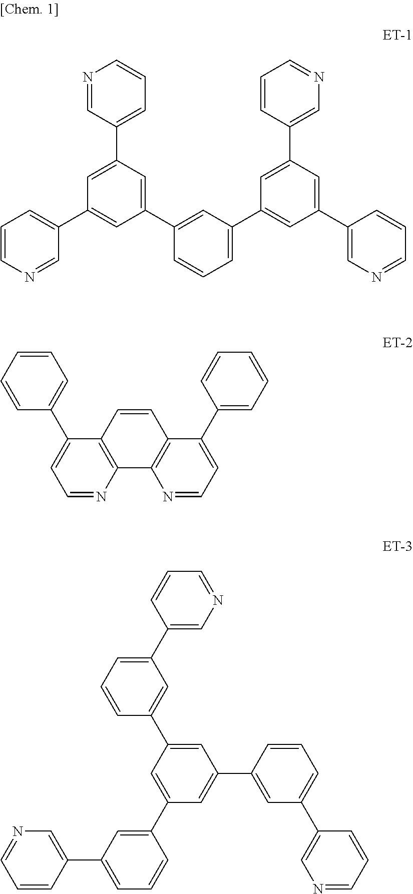 [SMILES: c1cncc(-c2cc(-c3cccnc3)cc(-c3cccc(-c4cc(-c5cccnc5)cc(-c5cccnc5)c4)c3)c2)c1 ; c1ccc(-c2ccnc3c2ccc2c(-c4ccccc4)ccnc23)cc1 ; c1cncc(-c2cccc(-c3cc(-c4cccc(-c5cccnc5)c4)cc(-c4cccc(-c5cccnc5)c4)c3)c2)c1]

It is considered that the compound having a nitrogen atom(s) having an unshared electron pair uninvolved in aromaticity of one or more embodiments of the invention has an asymmetric structure, which keeps the compound(s) from cohering and improves uniformity and film density of the intermediate layer, so that the conductive layer composed of silver as a main component formed as an upper layer can be thin and uniform.

The asymmetric compound having a nitrogen atom(s) having an unshared electron pair uninvolved in aromaticity of one or more embodiments of the invention may have a content percentage of the nitrogen atom(s) uninvolved in aromaticity determined by the following Equation (1) of 0.40 or more.

Content Percentage of Nitrogen Atom(s)=(The Number of Nitrogen Atoms Having Unshared Electron Pairs Uninvolved in Aromaticity/Molecular Weight of Asymmetric Compound)×100 Equation (1)

The nitrogen atom content percentage defined by one or more embodiments of the invention is 0.80 or more and, as the upper limit, and 1.50 or less. Use of the asymmetric compound containing a nitrogen atom(s) within the above range for the intermediate layer of one or more embodiments of the invention enables formation of the conductive layer excellent in uniformity without generating mottles or the like by cohesion of silver atoms which constitute the conductive layer formed on the upper side of the intermediate layer, and therefore can produce a transparent electrode having both optical transparency and conductivity and also being excellent in durability.

Hereinafter, the asymmetric compound having, as the nitrogen atom content percentage, 0.40 or more of the nitrogen atom(s) having an unshared electron pair uninvolved in aromaticity of one or more embodiments of the invention (hereinafter may be referred to as a nitrogen atom-containing asymmetric compound of embodiments of the invention) is detailed.

The nitrogen atom-containing asymmetric compound of one or more embodiments of the invention is not particularly limited as long as it contains a nitrogen atom(s) having an unshared electron pair uninvolved in aromaticity in the molecule and has an asymmetric structure, an asymmetric compound having an aromatic heterocyclic ring in the molecule, an asymmetric compound having an azacarbazole ring in a molecule, or an asymmetric compound having a γ,γ′-diazacarbazole ring or a β-carboline ring in the molecule.

Specific examples of the asymmetric compound having, as the nitrogen atom content percentage, 0.40 or more of the nitrogen atom(s) having an unshared electron pair uninvolved in aromaticity of one or more embodiments of the invention include an asymmetric compound represented by the following General Formula (1A).

The asymmetric compound represented by General Formula (1A) may be an asymmetric compound represented by any one of the following General Formula (1B), General Formula (1C) and General Formula (1D). In addition, an asymmetric compound represented by either one of the following General Formula (1E) and General Formula (1F) may be used as the nitrogen atom-containing asymmetric compound contained in the intermediate layer.

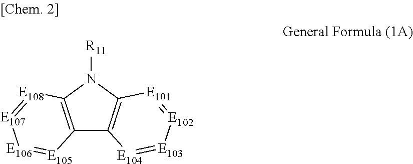

In the above General Formula (1A), E₁₀₁ to E₁₀₈ each represent C(R₁₂) or a nitrogen atom, at least one of E₁₀₁ to E₁₀₈ represents a nitrogen atom, and R₁₁ and R₁₂ in General Formula (1A) each represent a hydrogen atom or a substituent; provided that the structure of the compound represented by General Formula (1A) is asymmetric.

Examples of the substituent include: an alkyl group (a methyl group, an ethyl group, a propyl group, an isopropyl group, a tert-butyl group, a pentyl group, a hexyl group, an octyl group, a dodecyl group, a tridecyl group, a tetradecyl group, a pentadecyl group, etc.); a cycloalkyl group (a cyclopentyl group, a cyclohexyl group, etc.); an alkenyl group (a vinyl group, an allyl group, etc); an alkynyl group (an ethynyl group, a propargyl group, etc.); an aromatic hydrocarbon group (also called an aromatic carbocyclic group, an aryl group or the like; a phenyl group, a p-chlorophenyl group, a mesityl group, a tolyl group, a xylyl group, a naphthyl group, an anthryl group, an azulenyl group, an acenaphthenyl group, a fluorenyl group, a phenanthryl group, an indenyl group, a pyrenyl group, a biphenyryl group, etc.); an aromatic heterocyclic group (a furyl group, a thienyl group, a pyridyl group, a pyridazinyl group, a pyrimidinyl group, a pyrazinyl group, a triazinyl group, an imidazolyl group, a pyrazolyl group, a thiazolyl group, a quinazolinyl group, a carbazolyl group, a carbolinyl group, a diazacarbazolyl group (indicating a group formed in such a way that one of carbon atoms constituting a carboline ring of a carbolinyl group is substituted by a nitrogen atom), a phtharazinyl group, etc.); a heterocyclic group (a pyrrolidyl group, an imidazolidyl group, a morpholyl group, an oxazolidyl group, etc.); an alkoxy group (a methoxy group, an ethoxy group, a propyloxy group, a pentyloxy group, an hexyloxy group, an octyloxy group, a dodecyloxy group, etc.); a cycloalkoxy group (a cyclopentyloxy group, a cyclohexyloxy group, etc.); an aryloxy group (a phenoxy group, a naphthyloxy group, etc.); an alkylthio group (a methylthio group, an ethylthio group, a propylthio group, a pentylthio group, a hexylthio group, an octylthio group, a dodecylthio group, etc.); a cycloalkylthio group (a cyclopentylthio group, a cyclohexylthio group, etc.); an arylthio group (a phenylthio group, a naphthylthio group, etc.); an alkoxycarbonyl group (a methyloxycarbonyl group, an ethyloxycarbonyl group, a butyloxycarbonyl group, an octyloxycarbonyl group, a dodecyloxycarbonyl group, etc.); an aryloxycarbonyl group (a phenyloxycarbonyl group, a naphthyloxycarbonyl group, etc.); a sulfamoyl group (an aminosulfonyl group, a methylaminosulfonyl group, a dimethylaminosulfonyl group, a butylaminosulfonyl group, a hexylaminosulfonyl group, a cyclohexylaminosulfonyl group, an octylaminosulfonyl group, a dodecylaminosulfonyl group, a phenylaminosulfonyl group, a naphthylaminosulfonyl group, a 2-pyridylaminosulfonyl group, etc.); an acyl group (an acetyl group, an ethylcarbonyl group, a propylcarbonyl group, a pentylcarbonyl group, a cyclohexylcarbonyl group, an octylcarbonyl group, a 2-ethylhexylcarbonyl group, a dodecylcarbonyl group, a phenylcarbonyl group, a naphthylcarbonyl group, a pyridylcarbonyl group, etc.); an acyloxy group (an acetyloxy group, an ethylcarbonyloxy group, a butylcarbonyloxy group, an octylcarbonyloxy group, a dodecylcarbonyloxy group, a phenylcarbonyloxy group, etc.); an amido group (a methylcarbonylamino group, an ethylcarbonylamino group, a dimethylcarbonylamino group, a propylcarbonylamino group, a pentylcarbonylamino group, a cyclohexylcarbonylamino group, a 2-ethylhexylcarbonylamino group, an octylcarbonylamino group, a dodecylcarbonylamino group, a phenylcarbonylamino group, a naphthylcarbonylamino group, etc.); a carbamoyl group (an aminocarbonyl group, a methylaminocarbonyl group, a dimethylaminocarbonyl group, a propylaminocarbonyl group, a pentylaminocarbonyl group, a cyclohexylaminocarbonyl group, an octylaminocarbonyl group, a 2-ethylhexylaminocarbonyl group, a dodecylaminocarbonyl group, a phenylaminocarbonyl group, a naphthylaminocarbonyl group, a 2-pyridylaminocarbonyl group, etc.); an ureido group (a methylureido group, an ethylureido group, a pentylureido group, a cyclohexylureido group, an octylureido group, a dodecylureido group, a phenylureido group, a naphthylureido group, a 2-pyridylaminoureido group, etc.); a sulfinyl group (a methylsulfinyl group, an ethylsulfinyl group, a butylsulfinyl group, a cyclohexylsulfinyl group, a 2-ethylhexylsulfinyl group, a dodecylsulfinyl group, a phenylsulfinyl group, a naphthylsulfinyl group, a 2-pyridylsulfinyl group, etc.); an alkylsulfonyl group (a methylsulfonyl group, an ethylsulfonyl group, a butylsulfonyl group, a cyclohexylsulfonyl group, a 2-ethylhexylsulfonyl group, a dodecylsulfonyl group, etc.); an arylsulfonyl group or a heteroarylsulfonyl group (a phenylsulfonyl group, a naphthylsulfonyl group, a 2-pyridylsulfonyl group, etc.); an amino group (an amino group, an ethylamino group, a dimethylamino group, a butylamino group, a cyclopentylamino group, a 2-ethylhexylamino group, a dodecylamino group, an anilino group, a naphthylamino group, a 2-pyridylamino group, a piperidyl group (also called a piperidinyl group), a 2,2,6,6-tetramethylpiperidinyl group, etc.); a halogen atom (a fluorine atom, a chlorine atom, a bromine atom, etc.); a fluorohydrocarbon group (a fluoromethyl group, a trifluoromethyl group, a pentafluoroethyl group, a pentafluorophenyl group, etc.); a cyano group; a nitro group; a hydroxyl group; a mercapto group; a silyl group (a trimethylsilyl group, a triisopropylsilyl group, a triphenylsilyl group, a phenyldiethylsilyl group, etc.); a phosphate group (dihexylphosphoryl group, etc.); a phosphite group (diphenylphosphinyl group, etc.); and a phosphono group.

A portion of each of these substituents may further be substituted by a substitute of the above substituents. Further, a plurality of these substituents may bind to each other to form a ring(s).

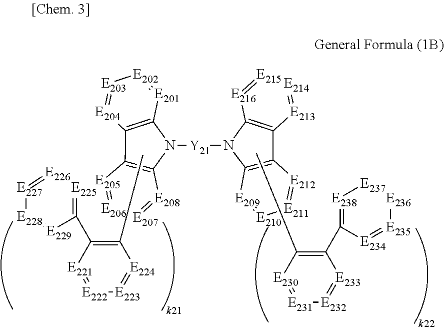

The above General Formula (1B) is a form of General Formula (1A).

In the above General Formula (1B) Y₂₁ represents a divalent linking group composed of an arylene group, a heteroarylene group or a combination thereof; E₂₀₁ to E₂₁₆ and E₂₂₁ to E₂₃₈ each represent C(R₂₁) or a nitrogen atom, and R₂₁ represents a hydrogen atom or a substituent, provided that at least one of E₂₂₁ to E₂₂₉ and at least one of E₂₃₀ to E₂₃₈ each represent a nitrogen atom; and k21 and k22 each represent an integer of zero to four, provided that the sum of k21 and k22 is an integer of two or more; provided that structure of the compound represented by General Formula (1B) is asymmetric.

Examples of the arylene group represented by Y₂₁ in General Formula (2) include an o-phenylene group, a p-phenylene group, a naphthalenediyl group, an anthracenediyl group, a naphthacenediyl group, a pyrenediyl group, a naphthylnaphthalenediyl group, a biphenyldiyl group (for example, a [1,1′-biphenyl]-4,4′-diyl group, a 3,3′-biphenyldiyl group and a 3,6-biphenyldiyl group), a terphenyldiyl group, a quaterphenyldiyl group, a quinquephenyldiyl group, a sexiphenyldiyl group, a septiphenyldiyl group, an octiphenyldiyl group, a nobiphenyldiyl group and a deciphenyldiyl group.

Examples of the heteroarylene group represented by Y₂₁ in General Formula (1B) include divalent groups derived from a group consisting of a carbazole ring, a carboline ring, a diazacarbazole ring (also called a monoazacarboline ring, indicating a ring formed in such away that one of carbon atoms constituting a carboline ring is substituted by a nitrogen atom), a triazole ring, a pyrrole ring, a pyridine ring, a pyrazine ring, a quinoxaline ring, a thiophene ring, an oxadiazole ring, a dibenzofuran ring, a dibenzothiophene ring and an indole ring.

As an example of the divalent linking group composed of an arylene group, a heteroarylene group or a combination thereof represented by Y₂₁, among the above heteroarylene groups, a heteroarylene group containing a group derived from a condensed aromatic heterocyclic ring formed in such a way that three or more rings are condensed may be used. As the group derived from a condensed aromatic heterocyclic ring formed in such a way that three or more rings are condensed, a group derived from a dibenzofuran ring or a group derived from a dibenzothiophene ring may be used.

In the case where R₂₁ in —C(R₂₁)═ represented by each of E₂₀₁ to E₂₁₆ and E₂₂₁ to E₂₃₈ in General Formula (1B) represents a substituent, as examples of the substituent, the examples of the substituent cited for R₁₁ and R₁₂ in General Formula (1A) are used.

In General Formula (1B), six or more of E₂₀₁ to E₂₀₈ and six or more of E₂₀₉ to E₂₁₆ may each represent —C(R₂₁)═.

In General Formula (1B), at least one of E₂₂₅ to E₂₂₉ and at least one of E₂₃₄ to E₂₃₈ may each represent —N═.

Further, in General Formula (1B), one of E₂₂₅ to E₂₂₉ and one of E₂₃₄ to E₂₃₈ may each represent —N═.

In General Formula (1B), E₂₂₁ to E₂₂₄ and E₂₃₀ to E₂₃₃ may each represent —C(R₂₁)═.

Further, in the compound represented by General Formula (1B), E₂₀₃ may represent —C(R₂₁)═ and R₂₁ represent a linking site, and further, E₂₁₁ may also represent —C(R₂₁)═ and R₂₁ represent a linking site.

Further, E₂₂₅ and E₂₃₄ may each represent —N═, and E₂₂₁ to E₂₂₄ and E₂₃₀ to E₂₃₃ may each represent —C(R₂₁)═.

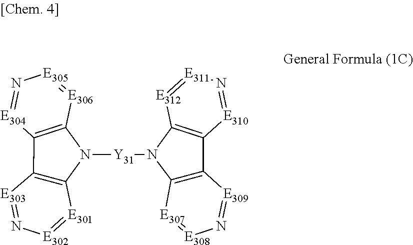

The above General Formula (1C) is a form of General Formula (1A).

In the above General Formula (1C), E₃₀₁ to E₃₁₂ each represent —C(R₃₁)═, and R₃₁ represents a hydrogen atom or a substituent; and Y₃₁ represents a divalent linking group composed of an arylene group, a heteroarylene group or a combination thereof; provided that the structure of the compound represented by General Formula (1C) is asymmetric.

In the case where R₃₁ in —C(R₃₁)═ represented by each of E₃₀₁ to E₃₁₂ in the above General Formula (1C) represents a substituent, as examples of the substituent, the examples of the substituent cited for R₁₁ and R₁₂ in General Formula (1A) are used.

Examples of the divalent linking group composed of an arylene group, a heteroarylene group or a combination thereof represented by Y₃₁ in General Formula (1C) are the same as those of the divalent linking group represented by Y₂₁ in General Formula (1B).

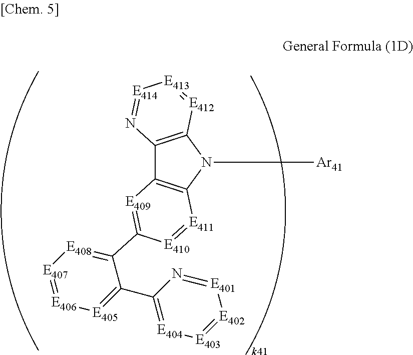

The above General Formula (1D) is a form of General Formula (1A).

In the above General Formula (1D), E₄₀₁ to E₄₁₄ each represent —C(R₄₁)═, and R₄₁ represents a hydrogen atom or a substituent; Ar₄₁ represents a substituted or non-substituted aromatic hydrocarbon ring or a substituted or non-substituted aromatic heterocyclic ring; and k41 represents an integer of three or more; provided that the structure of the compound represented by the above General Formula (1D) is asymmetric.

In the case where R₄₁ in —C(R₄₁)═ represented by each of E₄₀₁ to E₄₁₄ in the above General Formula (1D) represents a substituent, as examples of the substituent, the examples of the substituent cited for R₁₁ and R₁₂ in General Formula (1A) are used.

In the case where Ar₄₁ in the above General Formula (1D) represents an aromatic hydrocarbon ring, examples of the aromatic hydrocarbon ring include a benzene ring, a biphenyl ring, a naphthalene ring, an azulene ring, an anthracene ring, a phenanthrene ring, a pyrene ring, a chrysene ring, a naphthacene ring, a triphenylene ring, an o-terphenyl ring, an m-terphenyl ring, a p-terphenyl ring, an acenaphthene ring, a coronene ring, a fluorene ring, a fluoranthrene ring, a naphthacene ring, a pentacene ring, a perylene ring, a pentaphene ring, a picene ring, a pyrene ring, a pyranthrene ring and an anthranthrene ring. These rings may each have a substituent, the examples of which are cited for R₁₁ and R₁₂ in General Formula (1A).

In the case where Ar₄₁ in the above General Formula (1D) represents an aromatic heterocyclic ring, examples of the aromatic heterocyclic ring include a furan ring, a thiophene ring, an oxazole ring, a pyrrole ring, a pyridine ring, a pyridazine ring, a pyrimidine ring, a pyrazine ring, a triazine ring, a benzimidazole ring, an oxadiazole ring, a triazole ring, an imidazole ring, a pyrazole ring, a thiazole ring, an indole ring, a benzimidazole ring, a benzothiazole ring, a benzoxazole ring, a quinoxaline ring, a quinazoline ring, a phthalazine ring, a carbazole ring and an azacarbazole ring. The azacarbazole ring is a ring formed in such a way that at least one of carbon atoms of a benzene ring constituting a carbazole ring is substituted by a nitrogen atom. These rings may each have a substituent, the examples of which are cited for R₁₁ and R₁₂ in General Formula (1A).

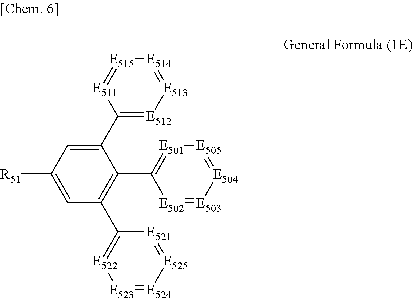

In the above General Formula (1E), at least one of E₅₀₁ and E₅₀₂ represents a nitrogen atom, at least one of E₅₁₁ to E₅₁₅ represents a nitrogen atom, at least one of E₅₂₁ to E₅₂₅ represents a nitrogen atom, and R₅₁ represents a substituent; provided that the structure of the compound represented by the above General Formula (1E) is asymmetric.

In the case where R₅₁ in the above General Formula (1E) represents a substituent, as examples of the substituent, the examples of the substituent cited for R₁₁ and R₁₂ in General Formula (1A) are used.

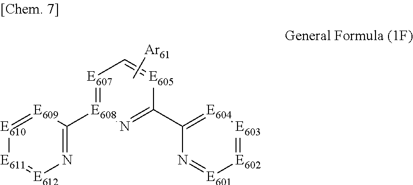

In the above General Formula (1F), E₆₀₁ to E₆₁₂ each represent —C(R₆₁)═ or N═, and R₆₁ represents a hydrogen atom or a substituent; and Ar₆₁ represents a substituted or non-substituted aromatic hydrocarbon ring or a substituted or non-substituted aromatic heterocyclic ring; provided that the structure of the compound represented by the above General Formula (1F) is asymmetric.

In the case where R₆₁ in —C(R₆₁)═ represented by each of E₆₀₁ to E₆₁₂ in the above General Formula (1F) represents a substituent, as examples of the substituent, the examples of the substituent cited for R₁₁ and R₁₂ in General Formula (1A) are used.

Examples of the substituted or non-substituted aromatic hydrocarbon ring and examples of the substituted or non-substituted aromatic heterocyclic ring represented by Ar₆₁ in General Formula (1F) are the same as those of the substituted or non-substituted aromatic hydrocarbon ring and those of the substituted or non-substituted aromatic heterocyclic ring represented by Ar₄₁ in General Formula (1D), respectively.

Specific examples of the asymmetric compound having a nitrogen atom(s) having an unshared electron pair uninvolved in aromaticity, the asymmetric compound having a nitrogen atom content percentage of 0.40 or more, of one or more embodiments of the invention are shown below. Numeral values (N) shown in the illustrated compounds below each indicate the nitrogen atom content percentage.

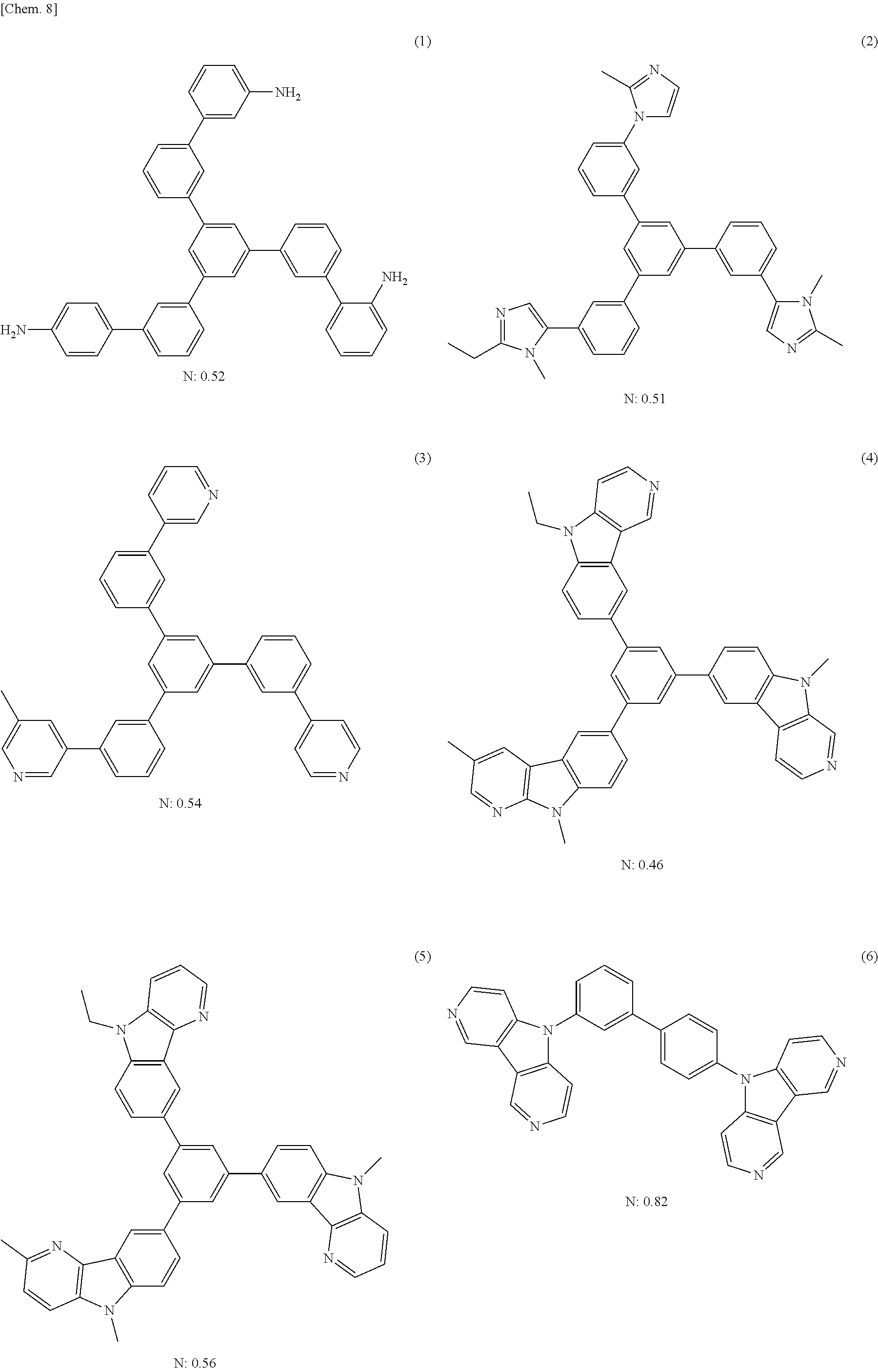 [SMILES: Nc1ccc(-c2cccc(-c3cc(-c4cccc(-c5cccc(N)c5)c4)cc(-c4cccc(-c5ccccc5N)c4)c3)c2)cc1 ; CCc1ncc(-c2cccc(-c3cc(-c4cccc(-c5cnc(C)n5C)c4)cc(-c4cccc(-n5ccnc5C)c4)c3)c2)n1C ; Cc1cncc(-c2cccc(-c3cc(-c4cccc(-c5ccncc5)c4)cc(-c4cccc(-c5cccnc5)c4)c3)c2)c1 ; CCn1c2ccncc2c2cc(-c3cc(-c4ccc5c(c4)c4ccncc4n5C)cc(-c4ccc5c(c4)c4cc(C)cnc4n5C)c3)ccc21 ; CCn1c2ccc(-c3cc(-c4ccc5c(c4)c4ncccc4n5C)cc(-c4ccc5c(c4)c4nc(C)ccc4n5C)c3)cc2c2ncccc21 ; c1cc(-c2ccc(-n3c4ccncc4c4cnccc43)cc2)cc(-n2c3ccncc3c3cnccc32)c1]

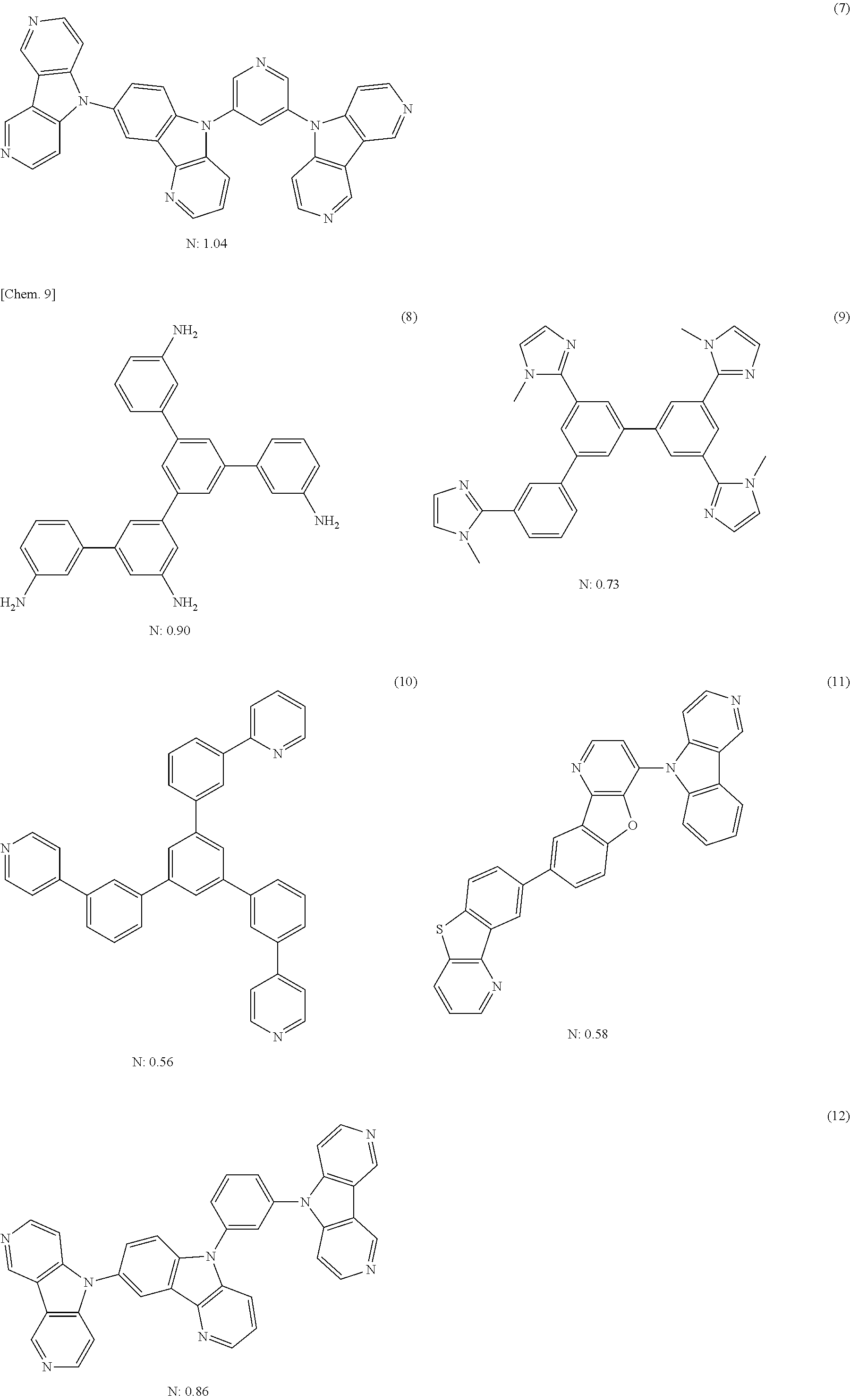 [SMILES: c1cnc2c3cc(-n4c5ccncc5c5cnccc54)ccc3n(-c3cncc(-n4c5ccncc5c5cnccc54)c3)c2c1 ; Nc1cccc(-c2cc(N)cc(-c3cc(-c4cccc(N)c4)cc(-c4cccc(N)c4)c3)c2)c1 ; Cn1ccnc1-c1cccc(-c2cc(-c3cc(-c4nccn4C)cc(-c4nccn4C)c3)cc(-c3nccn3C)c2)c1 ; c1ccc(-c2cccc(-c3cc(-c4cccc(-c5ccncc5)c4)cc(-c4cccc(-c5ccncc5)c4)c3)c2)nc1 ; c1cnc2c(c1)sc1ccc(-c3ccc4oc5c(-n6c7ccccc7c7cnccc76)ccnc5c4c3)cc12 ; c1cc(-n2c3ccncc3c3cnccc32)cc(-n2c3ccc(-n4c5ccncc5c5cnccc54)cc3c3ncccc32)c1]

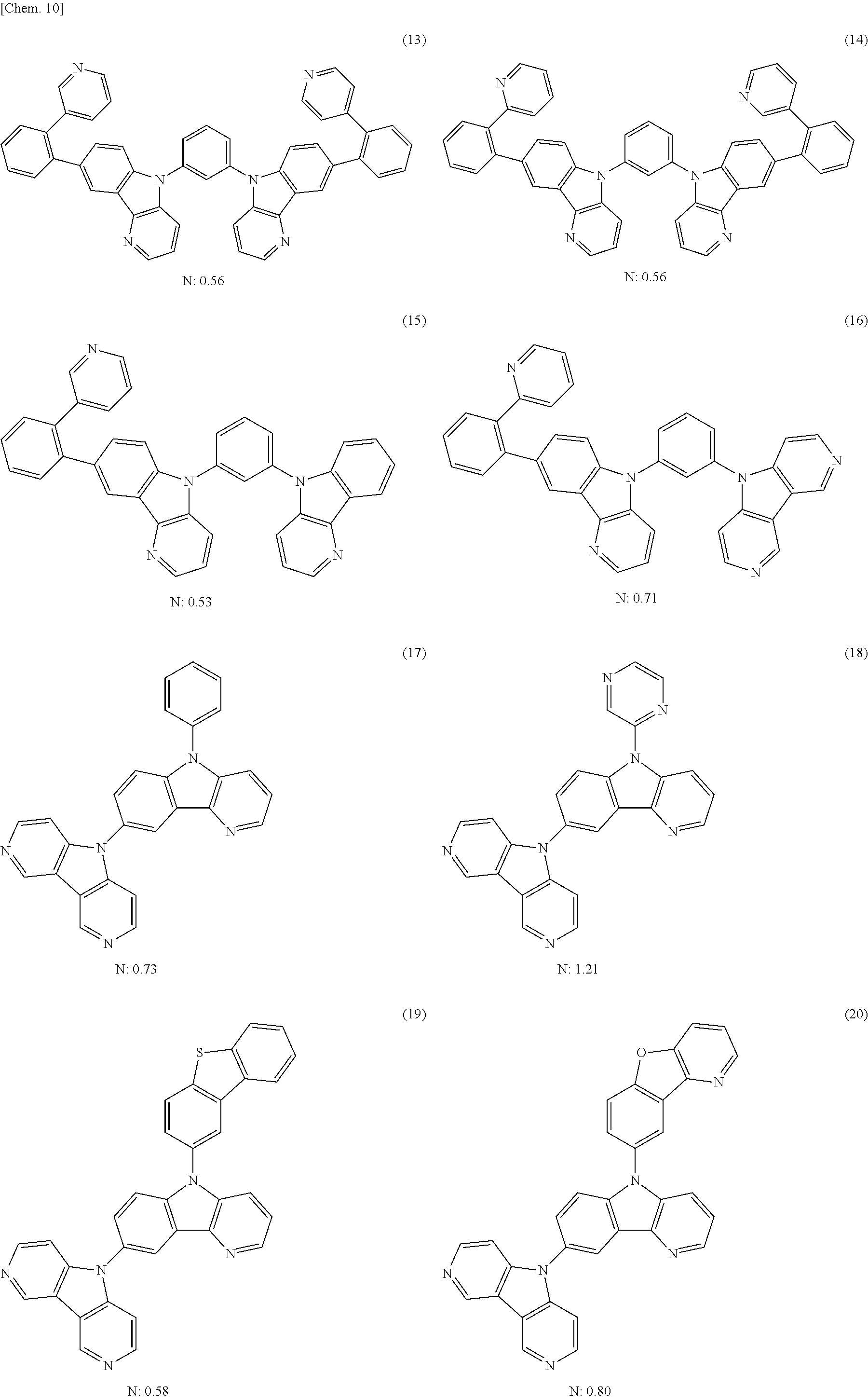

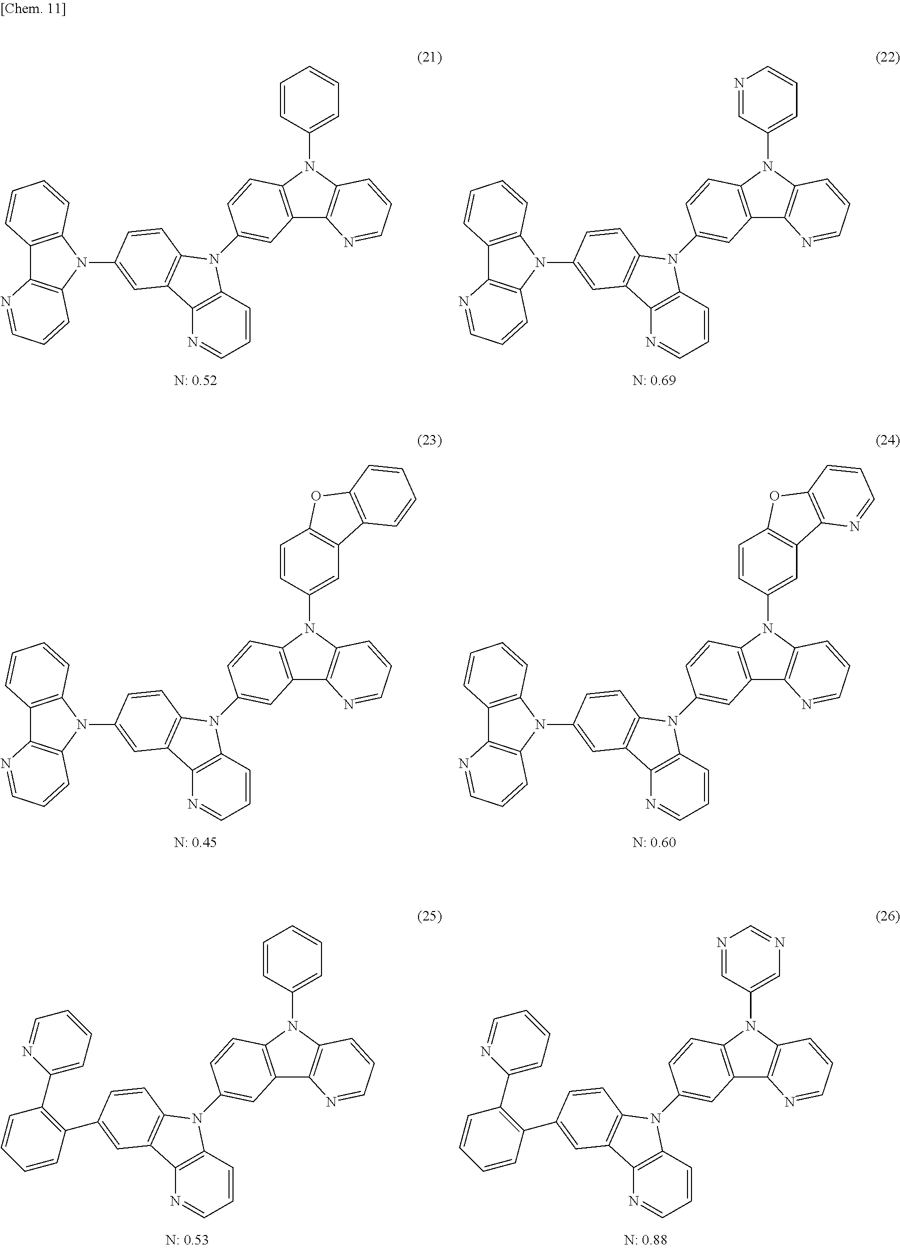 [SMILES: c1ccc(-n2c3ccc(-n4c5ccc(-n6c7ccccc7c7ncccc76)cc5c5ncccc54)cc3c3ncccc32)cc1 ; c1cncc(-n2c3ccc(-n4c5ccc(-n6c7ccccc7c7ncccc76)cc5c5ncccc54)cc3c3ncccc32)c1 ; c1ccc2c(c1)oc1ccc(-n3c4ccc(-n5c6ccc(-n7c8ccccc8c8ncccc87)cc6c6ncccc65)cc4c4ncccc43)cc12 ; c1cnc2c(c1)oc1ccc(-n3c4ccc(-n5c6ccc(-n7c8ccccc8c8ncccc87)cc6c6ncccc65)cc4c4ncccc43)cc12 ; c1ccc(-n2c3ccc(-n4c5ccc(-c6ccccc6-c6ccccn6)cc5c5ncccc54)cc3c3ncccc32)cc1 ; c1ccc(-c2ccccc2-c2ccc3c(c2)c2ncccc2n3-c2ccc3c(c2)c2ncccc2n3-c2cncnc2)nc1]

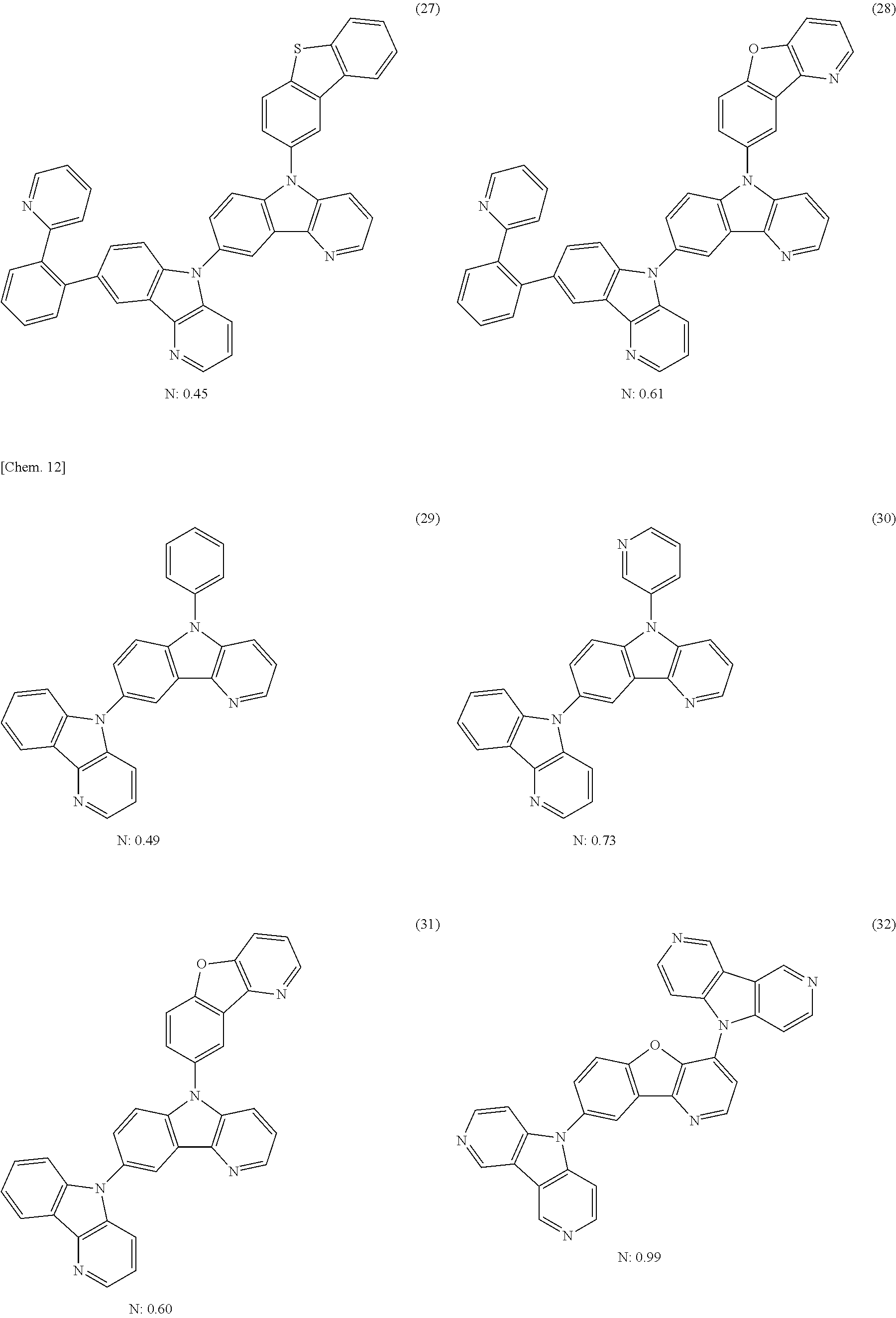 [SMILES: c1ccc(-c2ccccc2-c2ccc3c(c2)c2ncccc2n3-c2ccc3c(c2)c2ncccc2n3-c2ccc3sc4ccccc4c3c2)nc1 ; c1ccc(-c2ccccc2-c2ccc3c(c2)c2ncccc2n3-c2ccc3c(c2)c2ncccc2n3-c2ccc3oc4cccnc4c3c2)nc1 ; c1ccc(-n2c3ccc(-n4c5ccccc5c5ncccc54)cc3c3ncccc32)cc1 ; c1cncc(-n2c3ccc(-n4c5ccccc5c5ncccc54)cc3c3ncccc32)c1 ; c1cnc2c(c1)oc1ccc(-n3c4ccc(-n5c6ccccc6c6ncccc65)cc4c4ncccc43)cc12 ; c1cc2c(cn1)c1cnccc1n2-c1ccc2oc3c(-n4c5ccncc5c5cnccc54)ccnc3c2c1]

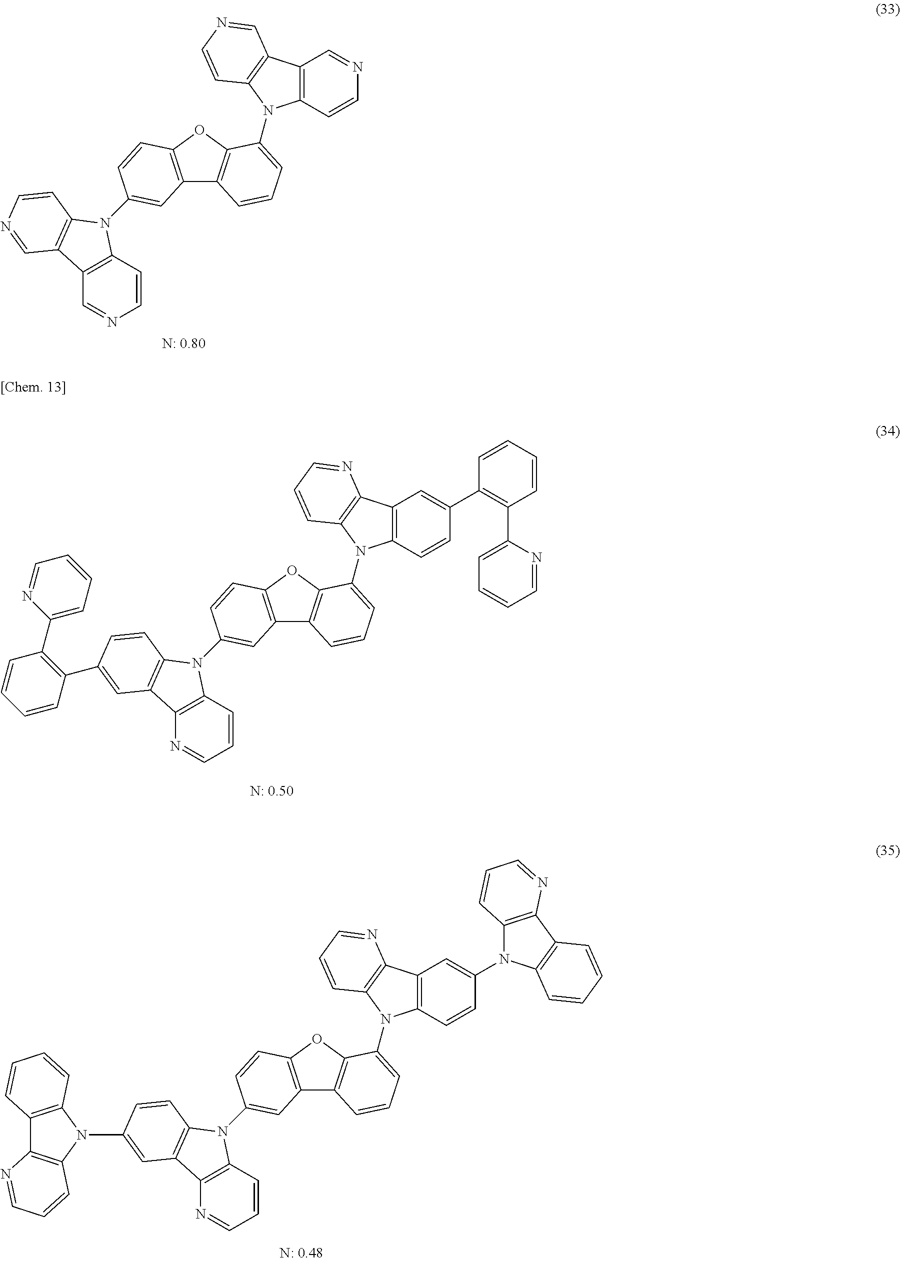 [SMILES: c1cc(-n2c3ccncc3c3cnccc32)c2oc3ccc(-n4c5ccncc5c5cnccc54)cc3c2c1 ; c1ccc(-c2ccccc2-c2ccc3c(c2)c2ncccc2n3-c2ccc3oc4c(-n5c6ccc(-c7ccccc7-c7ccccn7)cc6c6ncccc65)cccc4c3c2)nc1 ; c1cc(-n2c3ccc(-n4c5ccccc5c5ncccc54)cc3c3ncccc32)c2oc3ccc(-n4c5ccc(-n6c7ccccc7c7ncccc76)cc5c5ncccc54)cc3c2c1]

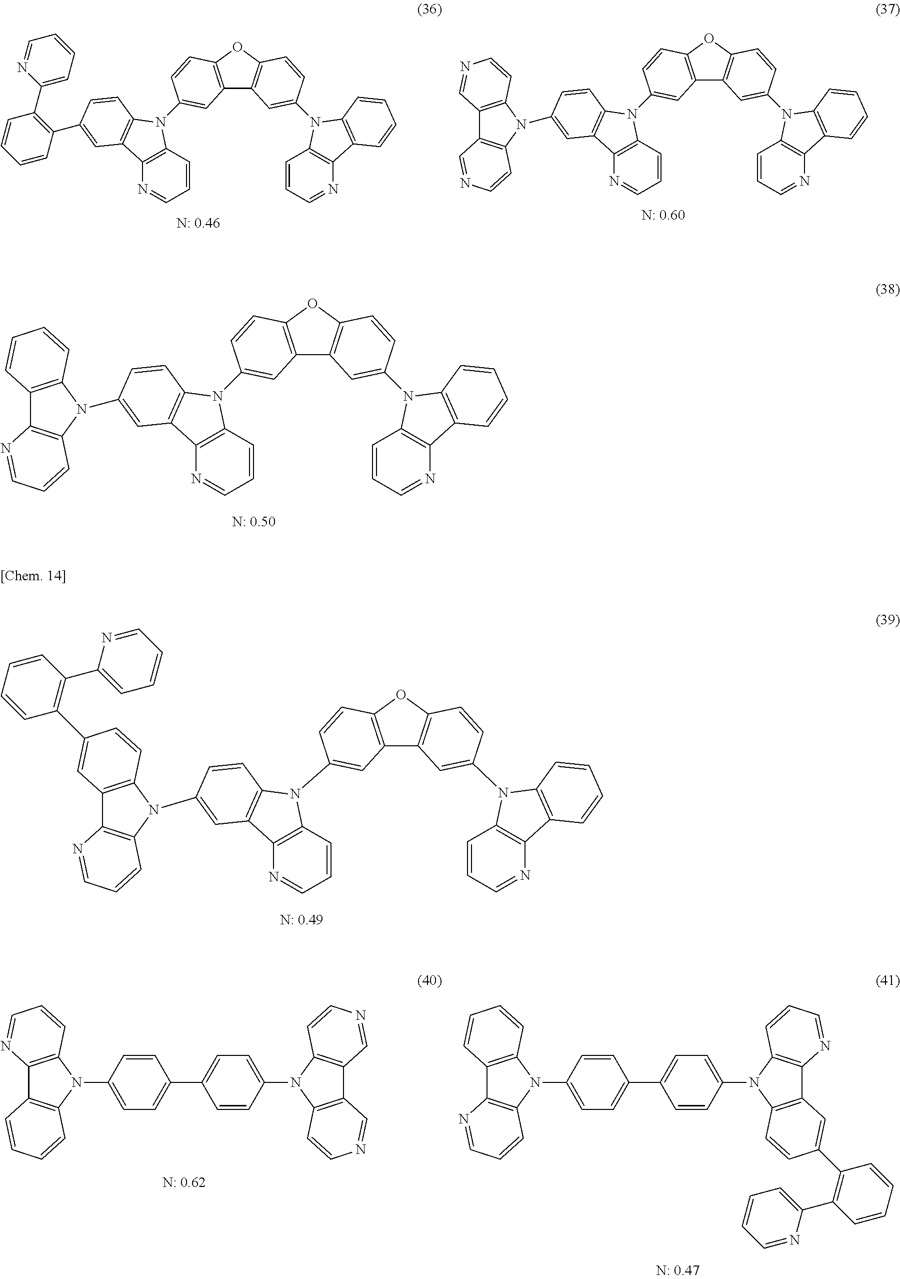

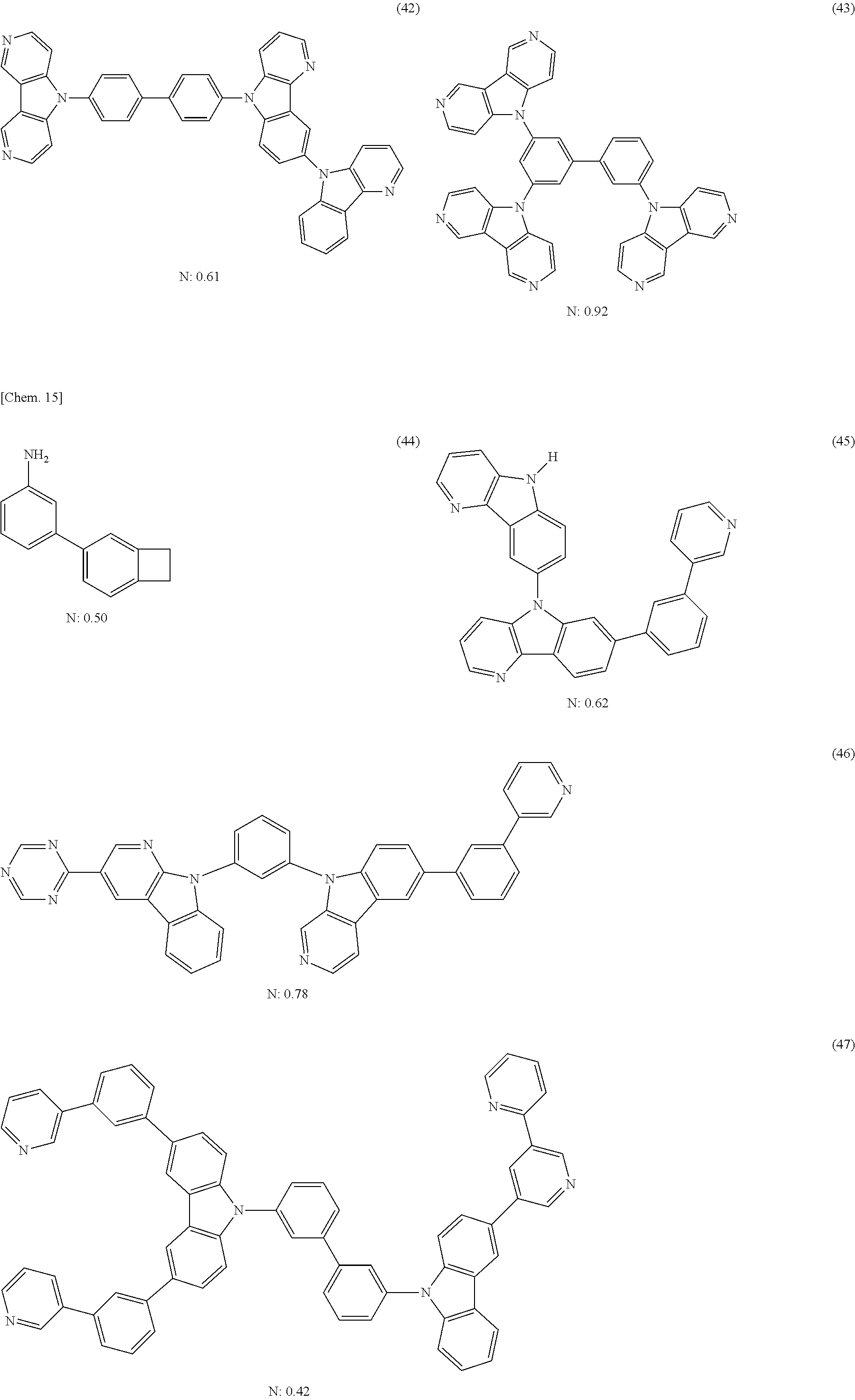 [SMILES: c1ccc2c(c1)c1ncccc1n2-c1ccc2c(c1)c1ncccc1n2-c1ccc(-c2ccc(-n3c4ccncc4c4cnccc43)cc2)cc1 ; c1cc(-c2cc(-n3c4ccncc4c4cnccc43)cc(-n3c4ccncc4c4cnccc43)c2)cc(-n2c3ccncc3c3cnccc32)c1 ; Nc1cccc(-c2ccc3c(c2)CC3)c1 ; c1cncc(-c2cccc(-c3ccc4c5ncccc5n(-c5ccc6[nH]c7cccnc7c6c5)c4c3)c2)c1 ; c1cncc(-c2cccc(-c3ccc4c(c3)c3ccncc3n4-c3cccc(-n4c5ccccc5c5cc(-c6ncncn6)cnc54)c3)c2)c1 ; c1ccc(-c2cncc(-c3ccc4c(c3)c3ccccc3n4-c3cccc(-c4cccc(-n5c6ccc(-c7cccc(-c8cccnc8)c7)cc6c6cc(-c7cccc(-c8cccnc8)c7)ccc65)c4)c3)c2)nc1]

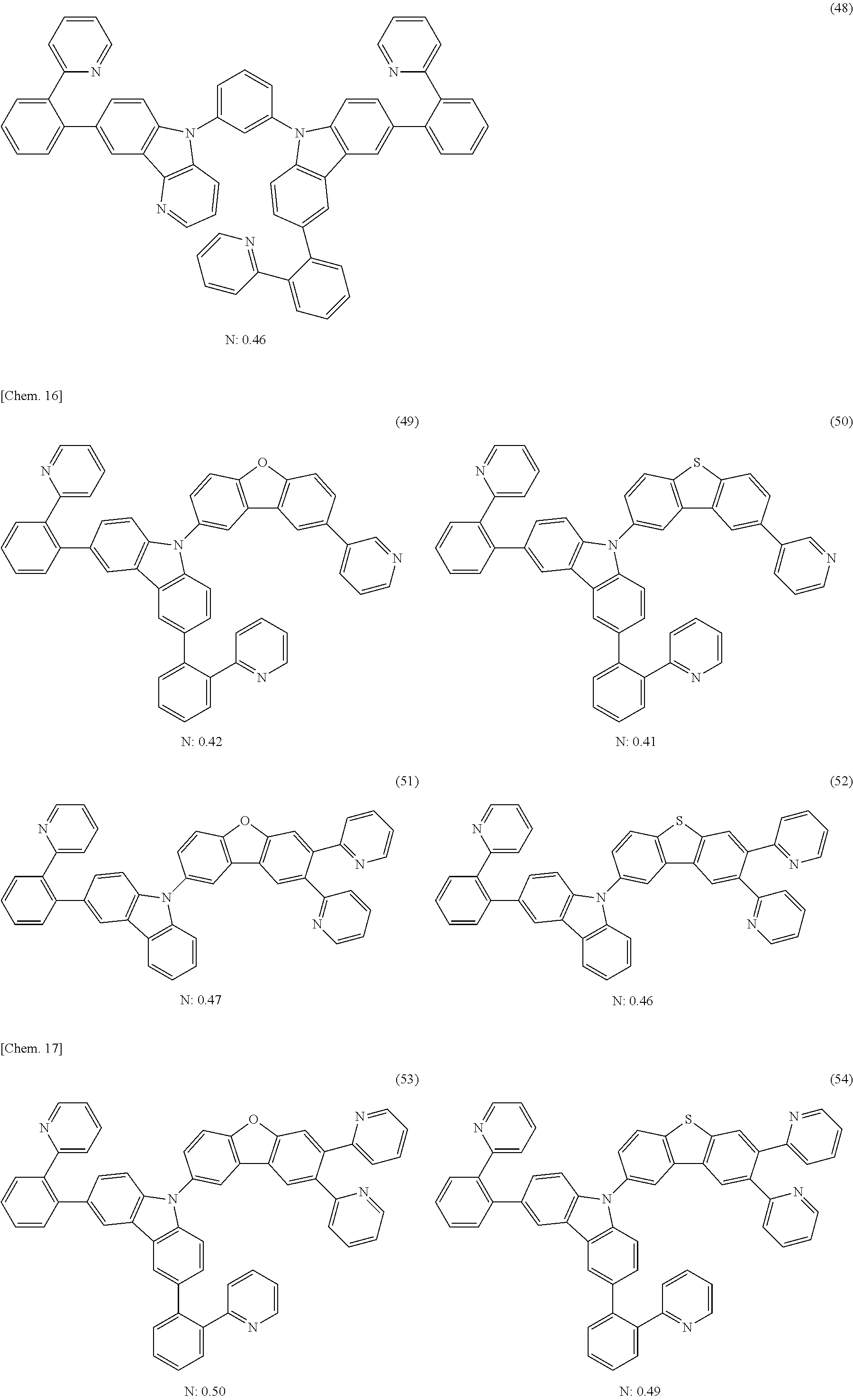

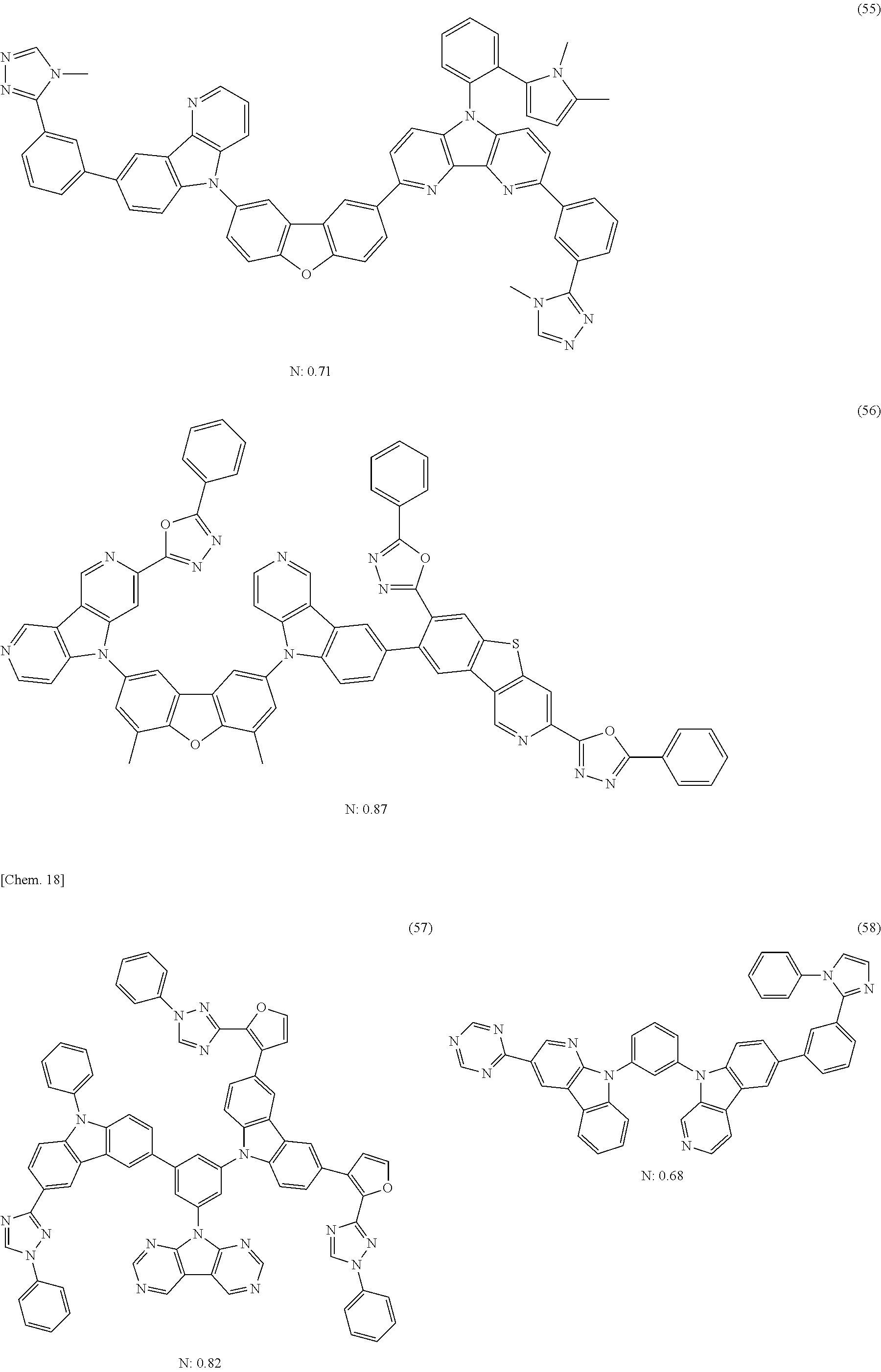

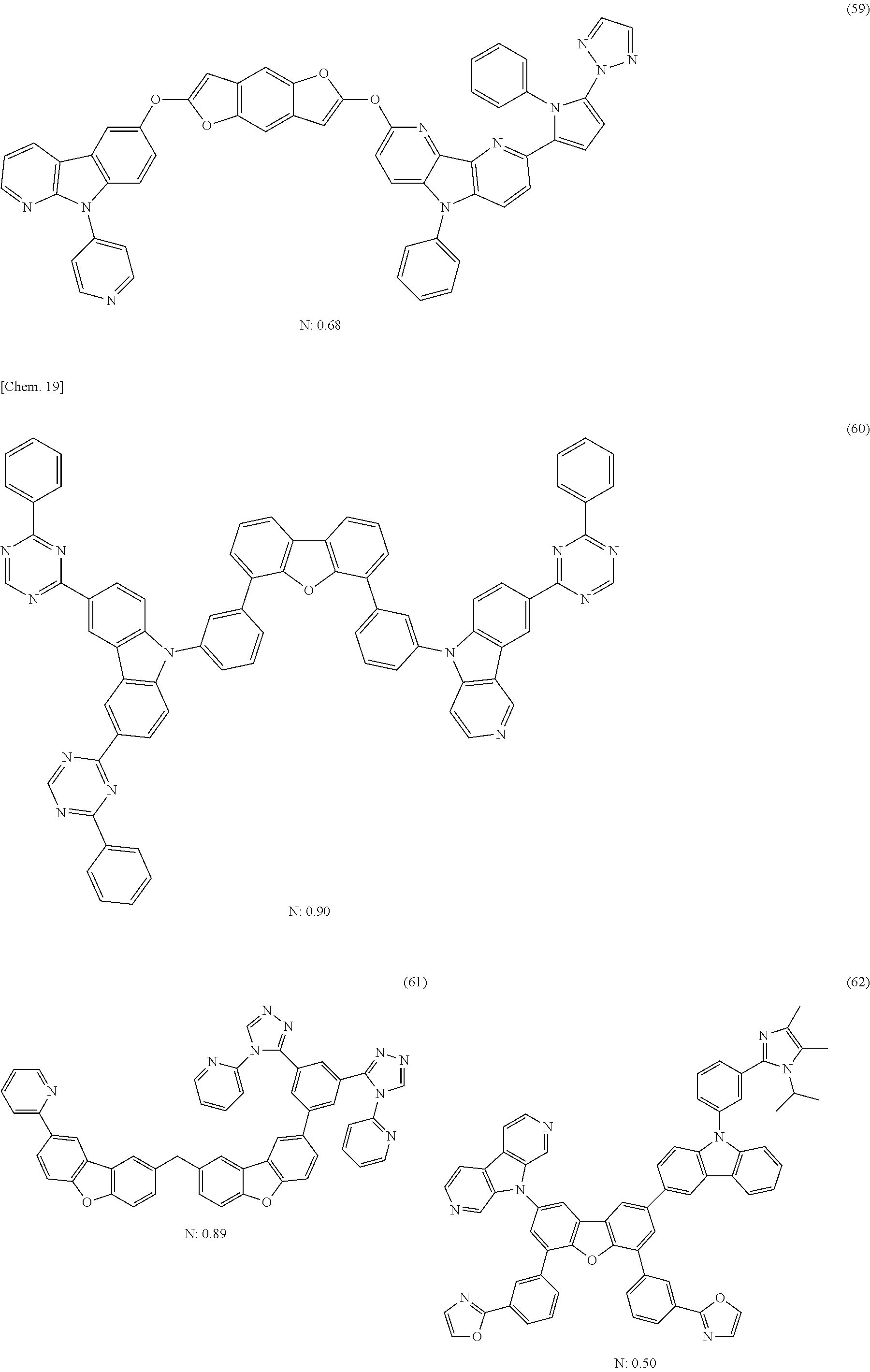

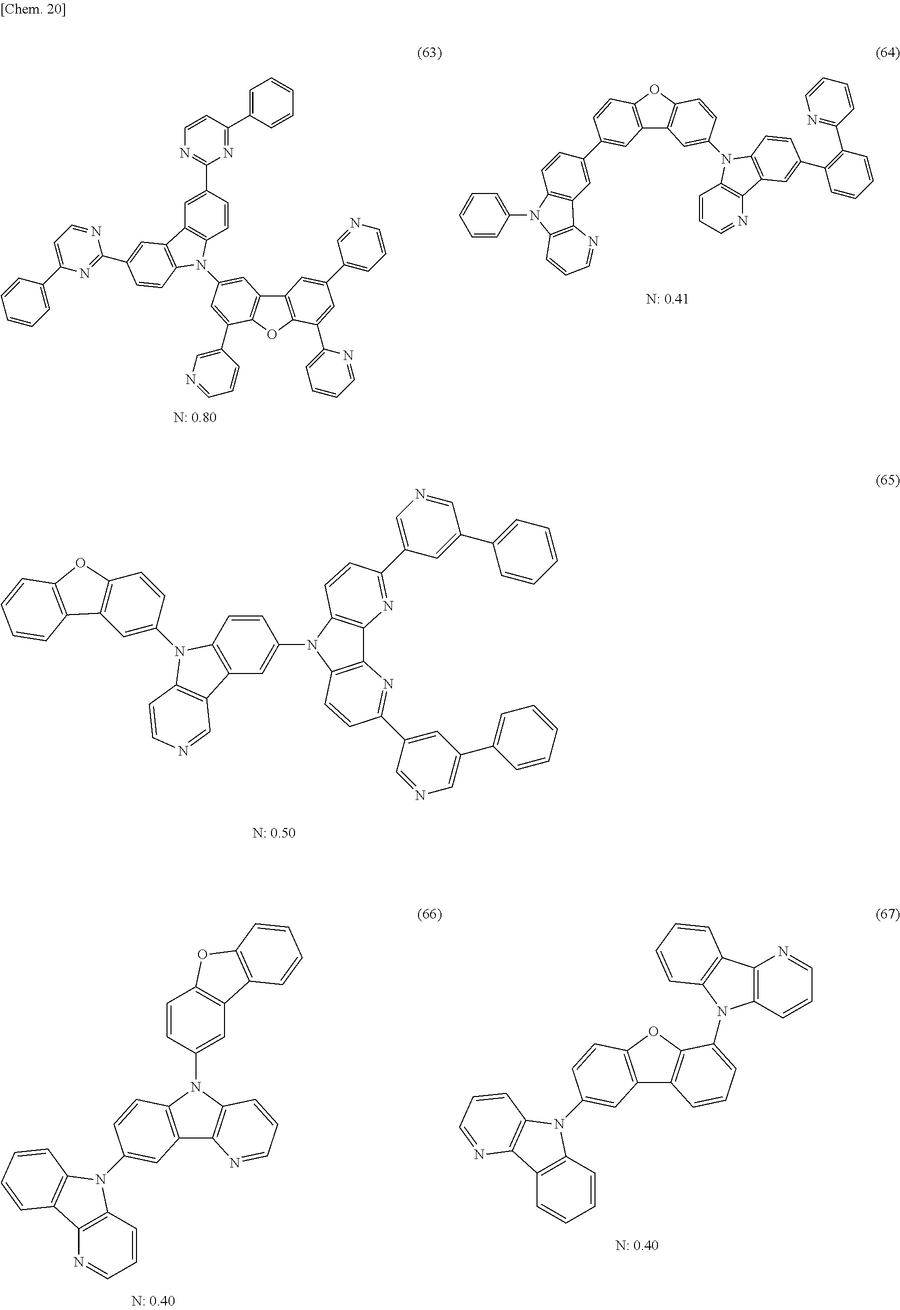 [SMILES: c1ccc(-c2ccnc(-c3ccc4c(c3)c3cc(-c5nccc(-c6ccccc6)n5)ccc3n4-c3cc(-c4cccnc4)c4oc5c(-c6ccccn6)cc(-c6cccnc6)cc5c4c3)n2)cc1 ; c1ccc(-n2c3ccc(-c4ccc5oc6ccc(-n7c8ccc(-c9ccccc9-c9ccccn9)cc8c8ncccc87)cc6c5c4)cc3c3ncccc32)cc1 ; c1ccc(-c2cncc(-c3ccc4c(n3)c3nc(-c5cncc(-c6ccccc6)c5)ccc3n4-c3ccc4c(c3)c3cnccc3n4-c3ccc4oc5ccccc5c4c3)c2)cc1 ; c1ccc2c(c1)oc1ccc(-n3c4ccc(-n5c6ccccc6c6ncccc65)cc4c4ncccc43)cc12 ; c1cc(-n2c3ccccc3c3ncccc32)c2oc3ccc(-n4c5ccccc5c5ncccc54)cc3c2c1]

The asymmetric compound having a nitrogen atom(s) having an unshared electron pair uninvolved in aromaticity of the present invention can be easily synthesized by a well-known synthesis method.

[Conductive Layer]

The conductive layer 1b of one or more embodiments of the invention is a layer composed of silver as a main component and is formed on the intermediate layer 1a. Examples of a forming method of the conductive layer 1b of one or more embodiments of the invention include wet processes, such as application, the inkjet method, coating and dipping, and dry processes, such as vapor deposition (resistance heating, the EB method, etc.), sputtering and CVD. By being formed on the intermediate layer 1a, the conductive layer 1b has sufficient conductivity without annealing at high temperature (for example, a heating process at 150° C. or more) after its formation, but, as needed, may be subjected to annealing at high temperature or the like after its formation.

The layer composed of silver as a main component in one or more embodiments of the invention means, as described above, that silver content in the conductive layer 1b is 60 mass % or more, 80 mass % or more, 90 mass % or more or 98 mass % or more.

The conductive layer 1b may be formed of silver alone or may be composed of an alloy containing silver (Ag). Examples of the alloy include silver and magnesium (Ag.Mg), silver and copper (Ag.Cu), silver and palladium(Ag.Pd), silver, palladium and copper (Ag.Pd.Cu), and silver and indium (Ag.In).

A conventional electrode formed of a silver-and-magnesium alloy does not have sufficient conductivity. However, it has been found that the electrode composed of the intermediate layer 1a and the conductive layer 1b composed of a silver-and-magnesium alloy disposed on the intermediate layer 1a can have higher conductivity than the conventional electrode. Although its mechanism is not clear yet, it is conjectured owing to increase in smoothness of the conductive layer 1b by disposing the conductive layer 1b on the intermediate layer 1a.

The conductive layer 1b of one or more embodiments of the invention may be configured, as needed, in such a way that a layer composed of silver as a main component is divided into a plurality of layers and the layers are stacked.

The thickness of the conductive layer 1b may be within a range from 4 to 9 nm. If the thickness is 8 nm or less, an absorbing component or a reflection component of the layer decreases and transmittance of the transparent electrode increases, which may be preferable. On the other hand, if the thickness is 5 nm or more, conductivity of the layer is sufficient, which may be preferable.

[Effects of Transparent Electrode]

As described above, the transparent electrode 1 of one or more embodiments of the invention is configured in such a way that the conductive layer 1b composed of silver as a main component is disposed on the intermediate layer 1a containing the asymmetric compound having a nitrogen atom(s) having an unshared electron pair uninvolved in aromaticity. It is conjectured that, with this structure, when the conductive layer 1b is formed on the upper side of the intermediate layer 1a, the silver atom(s) constituting the conductive layer 1b and the nitrogen atom(s) having an unshared electron pair uninvolved in aromaticity constituting the intermediate layer 1a react with each other, and diffusion distance of the silver atom(s) on the surface of the intermediate layer 1a decreases, whereby silver cohesion can be kept from occurring.

As described above, in forming the conductive layer 1b composed of silver as a main component, film growth is carried out in the island growth mode (Volumer-Weber (VW) mode). Hence, the silver particles are easily isolated in the shape of islands, and when the layer is thin, conductivity is difficult to obtain, and sheet resistance increases. Therefore, in order to ensure conductivity, the layer needs to be somewhat thick. However, when the layer is thick, the light transmittance decreases, which is improper as a transparent electrode.

In the transparent electrode 1 having the structure defined by one or more embodiments of the invention, however, it is conjectured that silver cohesion is kept from occurring by the interaction of a nitrogen atom(s) and silver on the intermediate layer 1a which contains the compound having the nitrogen atom(s) having an unshared electron pair uninvolved in aromaticity, and hence, in forming the conductive layer 1b composed of silver as a main component, film growth is carried out in the single-layer growth mode (Frank-van der Merwe (FW) mode).

The “transparent” of the transparent electrode 1 of one or more embodiments of the invention means that light transmittance at a wavelength of 550 nm is 50% or more. The above materials used for the intermediate layer 1a each have sufficient optical transparency and thereby forming an excellent layer having sufficient optical transparency as compared with the conductive layer 1b composed silver as a main component. Meanwhile, conductivity of the transparent electrode 1 is mainly ensured by the conductive layer 1b. Therefore, as described above, with the conductive layer 1b composed of silver as a main component being thinner and ensuring conductivity, both conductivity and optical transparency of the transparent electrode 1 are increased.

<<2. Uses of Transparent Electrode>>

The transparent electrode 1, having the above structure, of one or more embodiments of the invention can be used for various electronic devices. Examples of the electronic devices include an organic EL element, an LED (Light Emitting Diode), a liquid crystal element, a solar cell and a touch panel. As an electrode member which requires optical transparency in each of these electronic devices, the transparent electrode 1 of one or more embodiments of the invention can be used.

Hereinafter, as an example of the uses, embodiments of organic EL elements each using the transparent electrode are described.

<<3. First Embodiment of Organic EL Element>>

[Structure of Organic EL Element]

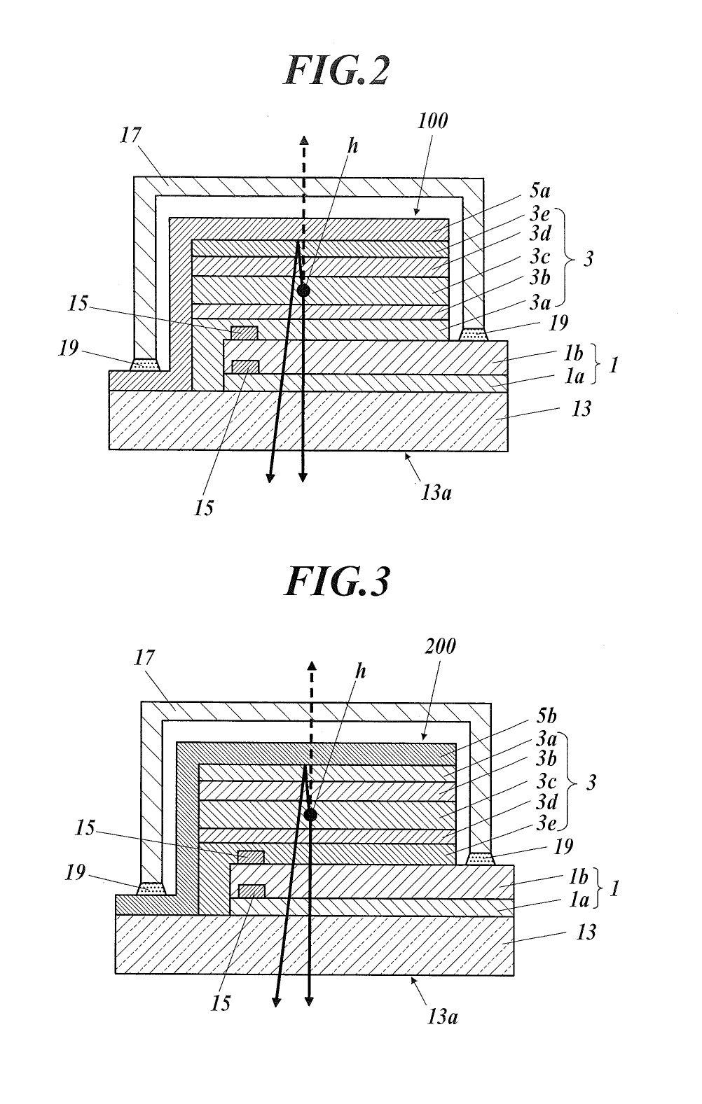

FIG. 2 is a cross sectional view showing the structure of a first embodiment of an organic EL element provided with the transparent electrode 1 of one or more embodiments of the invention as an example of an electronic device of embodiments of the invention. Hereinafter, an example of the structure of the organic EL element is described with reference to FIG. 2.

An organic EL element 100 shown in FIG. 2 is disposed on a transparent substrate (base) 13 and is configured in such a way that a transparent electrode 1, a light-emitting functional layer 3 made with an organic material and the like and a counter electrode 5a are stacked on the transparent substrate 13 in the order named. In the organic EL element 100, as the transparent electrode 1, the above described transparent electrode 1 of one or more embodiments of the invention is used. Hence, the organic EL element 100 is configured to extract the generated light (hereinafter “emission light h”) at least from the transparent substrate 13 side.

Next, the layer structure of the organic EL element 100 is described. In one or more embodiments of the invention, the layer structure thereof is not limited to the illustrated structure example and may be a general layer structure.

FIG. 2 shows a structure in which the transparent electrode 1 functions as an anode (i.e. a positive pole), and the counter electrode 5a functions as a cathode (i.e. a negative pole) in accordance with one or more embodiments of the invention. For this case, the light-emitting functional layer 3 has a layer structure of a positive hole injection layer 3a, a positive hole transport layer 3b, a luminescent layer 3c, an electron transport layer 3d and an electron injection layer 3e stacked on the transparent electrode 1 as an anode in the order named as shown in FIG. 2. It is an essential condition for the organic EL element that the organic EL element be provided with, among them, at least the luminescent layer 3c made with an organic material. The positive hole injection layer 3a and the positive hole transport layer 3b may be provided as a positive hole transport.injection layer. The electron transport layer 3d and the electron injection layer 3e may be provided as an electron transport.injection layer. Further, of the light-emitting functional layer 3, for example, the electron injection layer 3e may be composed of an inorganic material.

In the light-emitting functional layer 3, in addition to these illustrated constituent layers, a positive hole block layer, an electron block layer and the like may be disposed at their needed positions as needed. Further, the luminescent layer 3c may have a plurality of luminescent layers for different colors, the luminescent layers generating emission light of respective wavelength ranges, and may have a multilayer structure of these luminescent layers stacked with a non-luminescent auxiliary layer(s) in between. The auxiliary layer(s) may double as a positive hole block layer and an electron block layer. Further, the counter electrode 5a as a cathode may also have a multilayer structure as needed. In the structure described above, only the portion where the light-emitting functional layer 3 is sandwiched between the transparent electrode 1 and the counter electrode 5a is a luminescent region in the organic EL element 100.

In the above described layer structure, in order to reduce resistance of the transparent electrode 1, an auxiliary electrode 15 shown in FIG. 2 may be disposed in contact with the conductive layer 1b of the transparent electrode 1.

The organic EL element 100 thus configured is provided with a sealing member 17, which is described below, on the transparent substrate 13, whereby a sealing structure is formed, in order to prevent deterioration of the light-emitting functional layer 3 made mainly with an organic material or the like. The sealing member 17 is fixed to the transparent substrate 13 side with an adhesive 19. Terminal portions of the transparent electrode 1 and the counter electrode 5a are disposed in such away as to be exposed from the sealing member 17 while being insulated from each other by the light-emitting functional layer 3 on the transparent substrate 13.

Hereinafter, the main layers of the above described organic EL element 100 shown in FIG. 2 are detailed in the following order; the transparent substrate 13, the transparent electrode 1, the counter electrode 5a, the luminescent layer 3c of the light-emitting functional layer 3, other functional layers of the light-emitting functional layer 3, the auxiliary electrode 15 and the sealing member 17.

[Transparent Substrate]

The transparent substrate 13 is the above described base on which the transparent electrode 1 of one or more embodiments of the invention is disposed, and of the above described base 11, the base 11 which is transparent and has optical transparency is used therefor.

[Transparent Electrode]

The transparent electrode 1 (anode or positive pole) is the above detailed transparent electrode 1 of one or more embodiments of the invention and configured in such a way that the intermediate layer 1a, which contains the compound having a nitrogen atom(s) having an unshared electron pair uninvolved in aromaticity, and the conductive layer 1b, which is composed of silver as a main component, are formed on the transparent substrate 13 in the order named. Especially in the embodiment, the transparent electrode 1 functions as an anode (positive pole), and the conductive layer 1b is the substantial anode.

[Counter Electrode]

The counter electrode 5a (cathode or negative pole) is an electrode layer which functions as a cathode (negative pole) for supplying electrons to the light-emitting functional layer 3 and is composed of, for example, a metal, an alloy, an organic conductive compound, an inorganic conductive compound or a mixture of any of these. Examples thereof include: aluminum; silver; magnesium; lithium; magnesium/copper mixture; magnesium/silver mixture; magnesium/aluminum mixture; magnesium/indium mixture; indium; lithium/aluminum mixture; rare-earth metal; and oxide semiconductors, such as ITO, ZnO, TiO₂ and SnO₂.

The counter electrode 5a can be produced by forming a thin film of any of the above mentioned conductive materials by vapor deposition, sputtering or another method. The sheet resistance of the counter electrode 5a may be several hundred Ω/□ or less. The thickness is selected from normally a range of 5 nm to 5 μm, or a range of 5 nm to 200 nm.

In the case where the organic EL element 100 is configured to extract emission light h from the counter electrode 5a side too, the counter electrode 5a should be composed of a conductive material having excellent optical transparency selected from the above mentioned conductive materials.

[Light-Emitting Functional Layer]

(Luminescent Layer)

The luminescent layer 3c, which constitutes the organic EL element of one or more embodiments of the invention, contains a luminescent material, a phosphorescent compound as the luminescent material may be used.

The luminescent layer 3c is a layer which emits light through rebinding of electrons injected from the electrode or the electron transport layer 3d and positive holes injected from the positive hole transport layer 3b. A portion to emit light may be either inside of the luminescent layer 3c or an interface between the luminescent layer 3c and its adjacent layer.

The structure of the luminescent layer 3c is not particularly limited as long as the luminescent material contained therein satisfies a light emission requirement. Further, the luminescent layer 3c may be composed of a plurality of layers having the same emission spectrum and/or maximum emission wavelength. In this case, non-luminescent auxiliary layers (not shown) may be present between the luminescent layers 3c.

The total thickness of the luminescent layer(s) 3c may be within a range from 1 to 100 nm and, in order to obtain a lower driving voltage, within a range from 1 to 30 nm. The total thickness of the luminescent layer(s) 3c is, if the non-luminescent auxiliary layers are present between the luminescent layers 3c, the thickness including the thickness of the auxiliary layers.

In the case where the luminescent layer 3c has a multilayer structure of a plurality of layers stacked, the thickness of each luminescent layer may be adjusted to be within a range from 1 to 50 nm and the thickness thereof may be adjusted to be within a range from 1 to 20 nm. In the case where the stacked luminescent layers are for respective luminescent colors of blue, green and red, a relationship between the thickness of the luminescent layer for blue, the thickness of the luminescent layer for green and the thickness of the luminescent layer for red is not particularly limited.

The luminescent layer 3c thus configured can be formed by forming a thin film of a luminescent material and a host compound, which are described below, by a well-known thin-film forming method such as vacuum deposition, spin coating, casting, the LB method or the inkjet method.

The luminescent layer 3c may be composed of a plurality of luminescent materials mixed or a phosphorescent material and a fluorescent material (hereinafter may be referred to as a fluorescent dopant or a fluorescent compound) mixed.

The luminescent layer 3c may contain a host compound (hereinafter may be referred to as a luminescent host or the like) and a luminescent material (hereinafter may be referred to as a luminescent dopant compound or a dopant compound) and emit light from the luminescent material.

<Host Compound>

The host compound contained in the luminescent layer 3c is a compound exhibiting, in phosphorescence emission at room temperature (25° C.), a phosphorescence quantum yield of less than 0.1 and a phosphorescence quantum yield of less than 0.01. Further, of the compounds contained in the luminescent layer 3c, a volume percentage of the host compound in the layer being 50% or more may be used.

As the host compound, one type of well-known host compounds may be used alone, or a plurality of types thereof may be used together. Use of a plurality of types of host compounds enables adjustment of transfer of charges, thereby increasing efficiency of the organic EL element. Further, use of a plurality of types of luminescent materials described below enables mixture of emission light of different colors, thereby producing any luminescent color.

The host compound to be used may be a well-known low molecular weight compound, a high polymer having a repeating unit or a low molecular weight compound (a vapor deposition polymerizable luminescent host) having a polymerizable group such as a vinyl group or an epoxy group.

Of the well-known host compounds, a compound which has a positive hole transport property and an electron transport property, prevents red shift and has a high Tg (glass transition temperature) may be used. The glass transition temperature (Tg) here is a value obtained using DSC (Differential Scanning Colorimetry) by a method in conformity with JIS-K-7121.

Specific examples (H1 to H79) of the host compound usable in one or more embodiments of the invention are shown below, but the host compound is not limited thereto. In the host compounds H68 to H79, x and y represent a ratio in a random copolymer. The ratio can be x:y=1:10, for example.

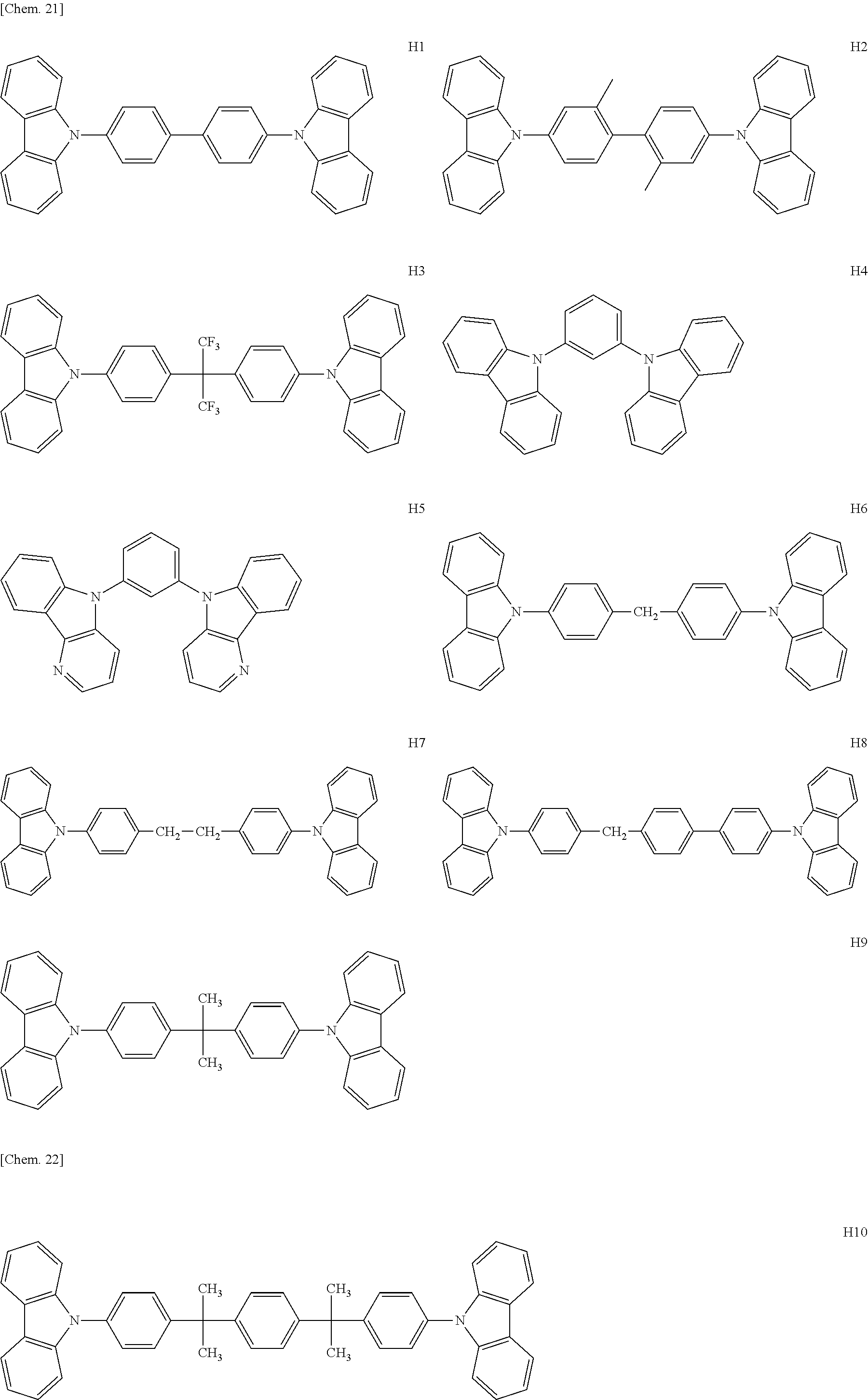

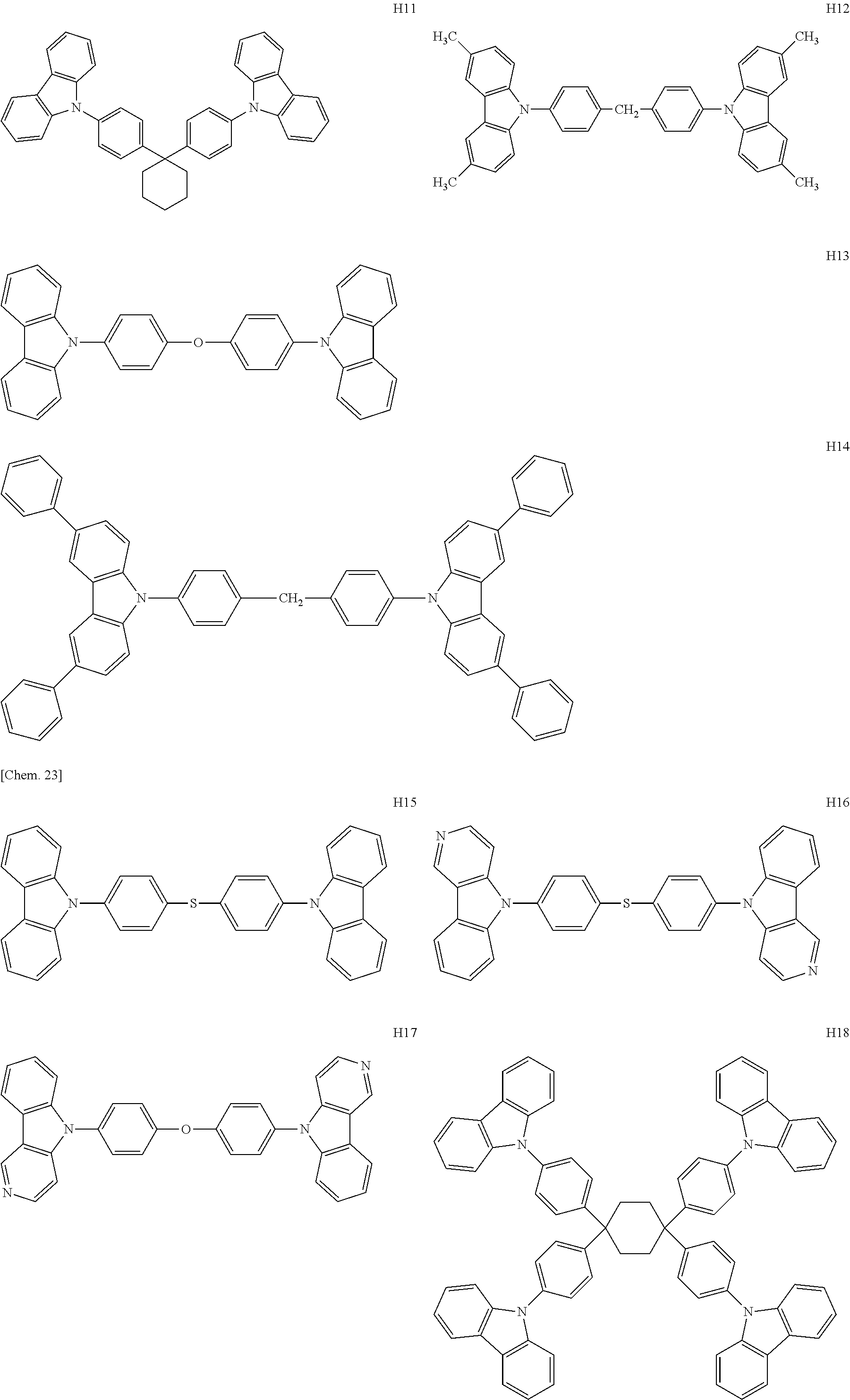

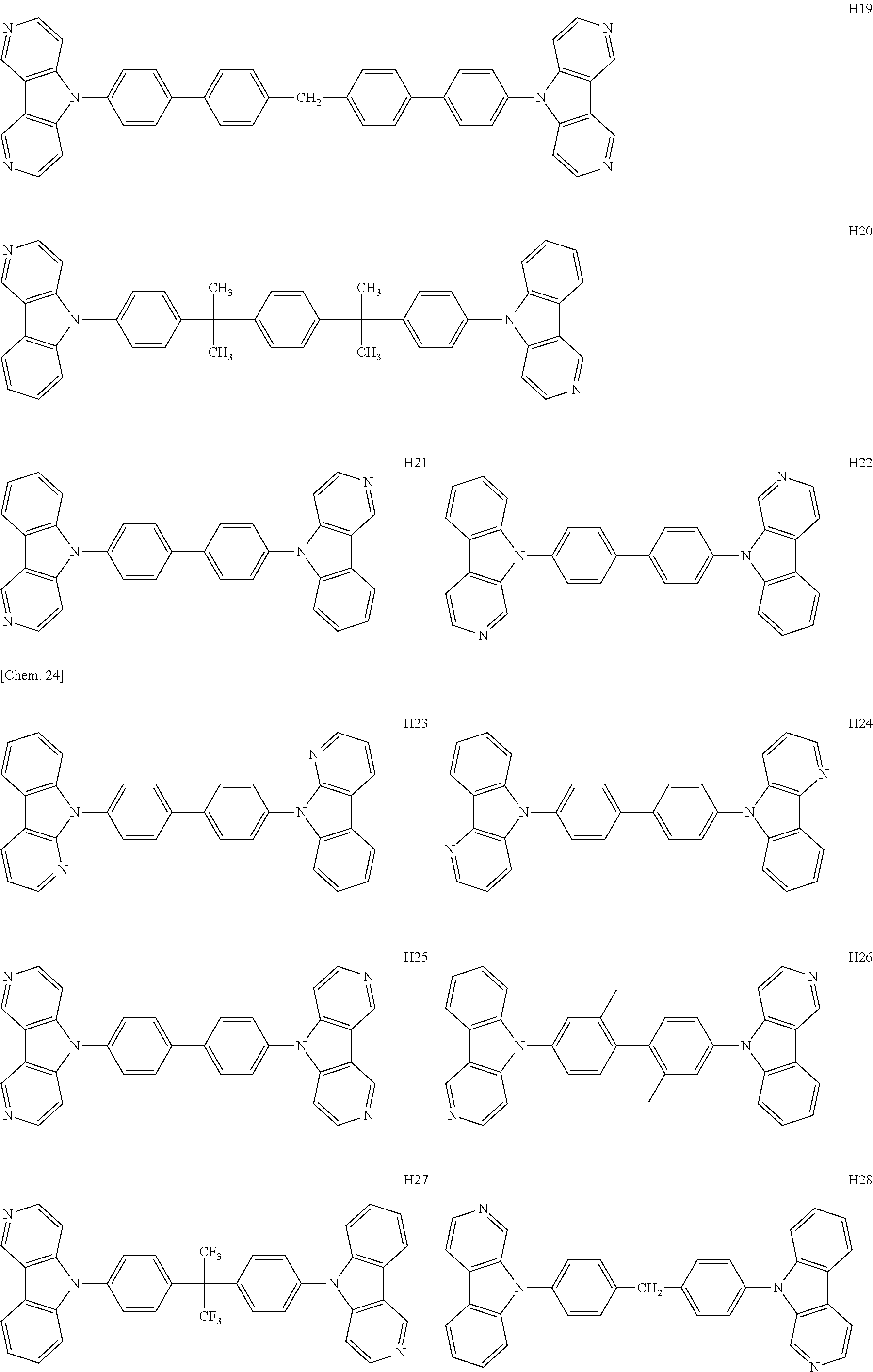

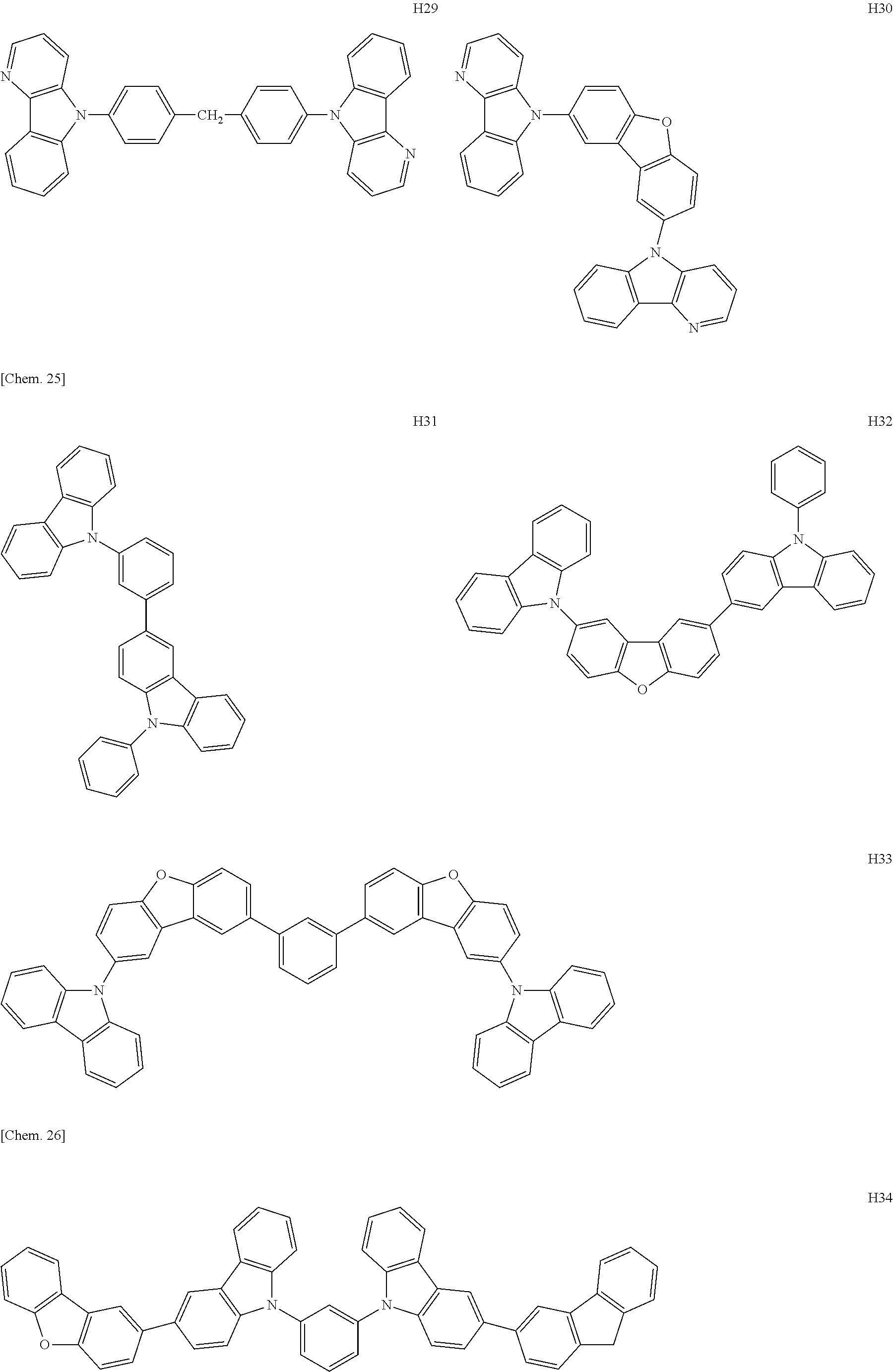 [SMILES: c1ccc2c(c1)c1ncccc1n2-c1ccc(Cc2ccc(-n3c4ccccc4c4ncccc43)cc2)cc1 ; c1ccc2c(c1)c1ncccc1n2-c1ccc2oc3ccc(-n4c5ccccc5c5ncccc54)cc3c2c1 ; c1ccc(-n2c3ccccc3c3cc(-c4cccc(-n5c6ccccc6c6ccccc65)c4)ccc32)cc1 ; c1ccc(-n2c3ccccc3c3cc(-c4ccc5oc6ccc(-n7c8ccccc8c8ccccc87)cc6c5c4)ccc32)cc1 ; c1cc(-c2ccc3oc4ccc(-n5c6ccccc6c6ccccc65)cc4c3c2)cc(-c2ccc3oc4ccc(-n5c6ccccc6c6ccccc65)cc4c3c2)c1 ; c1cc(-n2c3ccccc3c3cc(-c4ccc5c(c4)-c4ccccc4C5)ccc32)cc(-n2c3ccccc3c3cc(-c4ccc5oc6ccccc6c5c4)ccc32)c1]

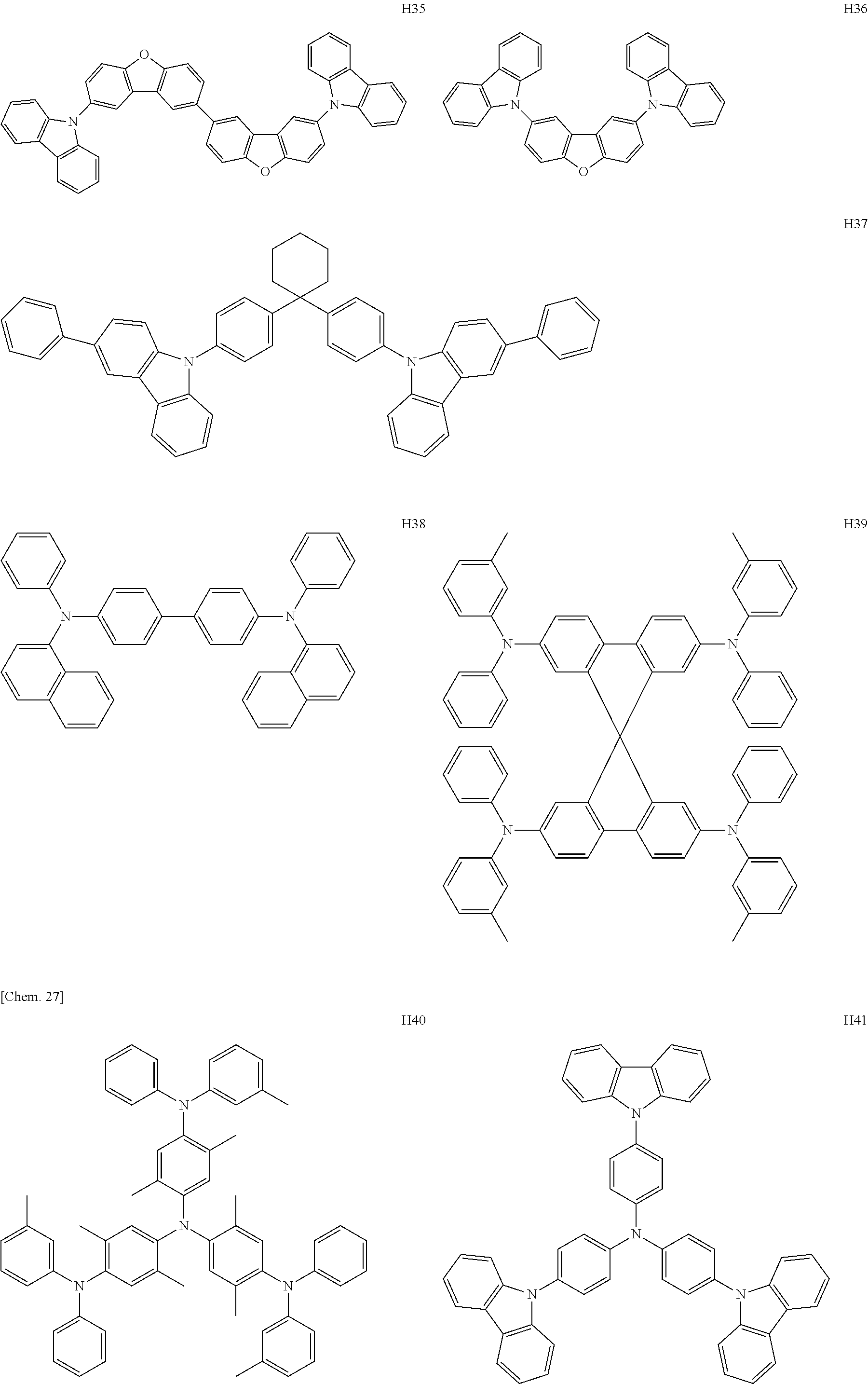

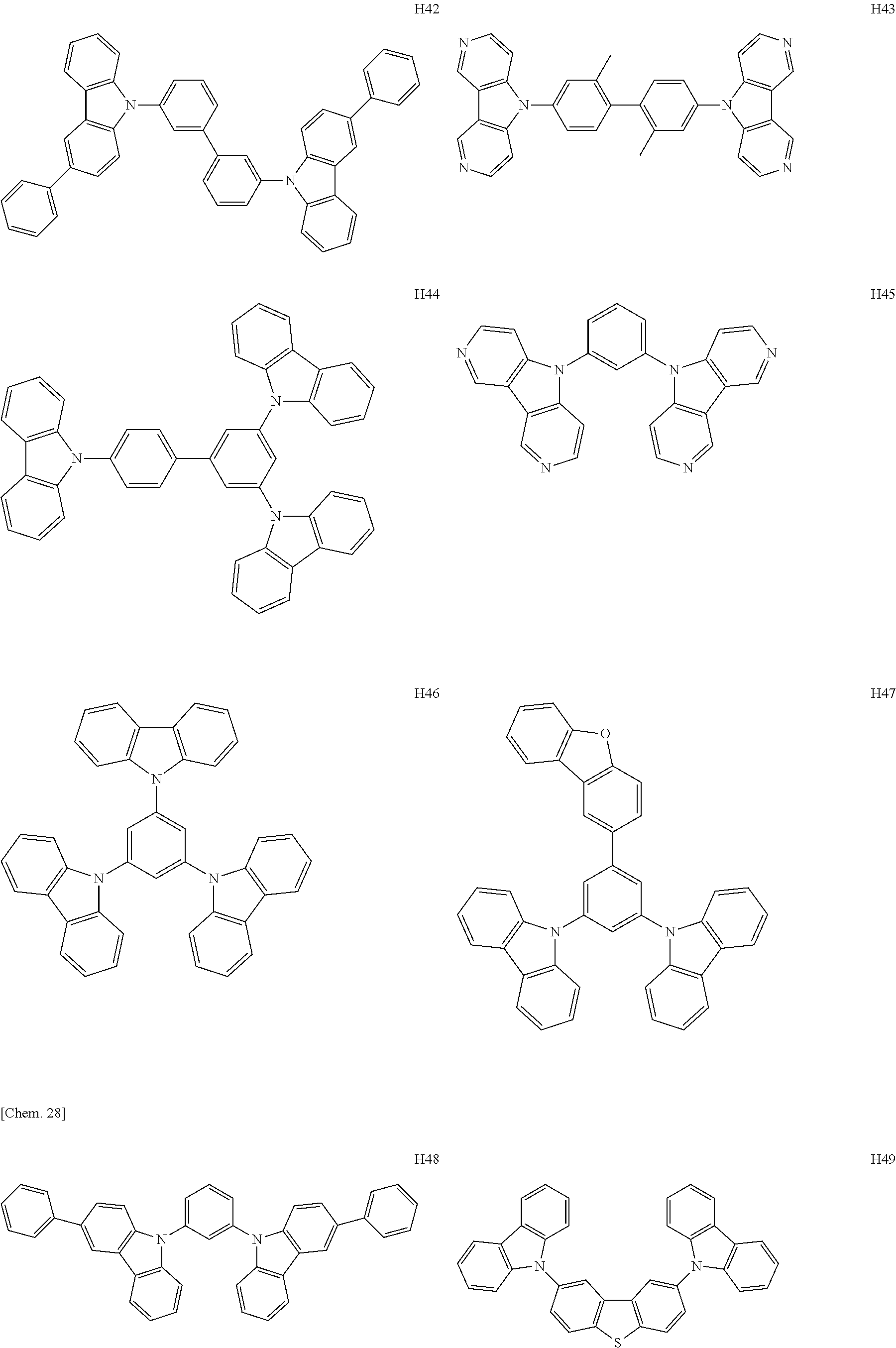

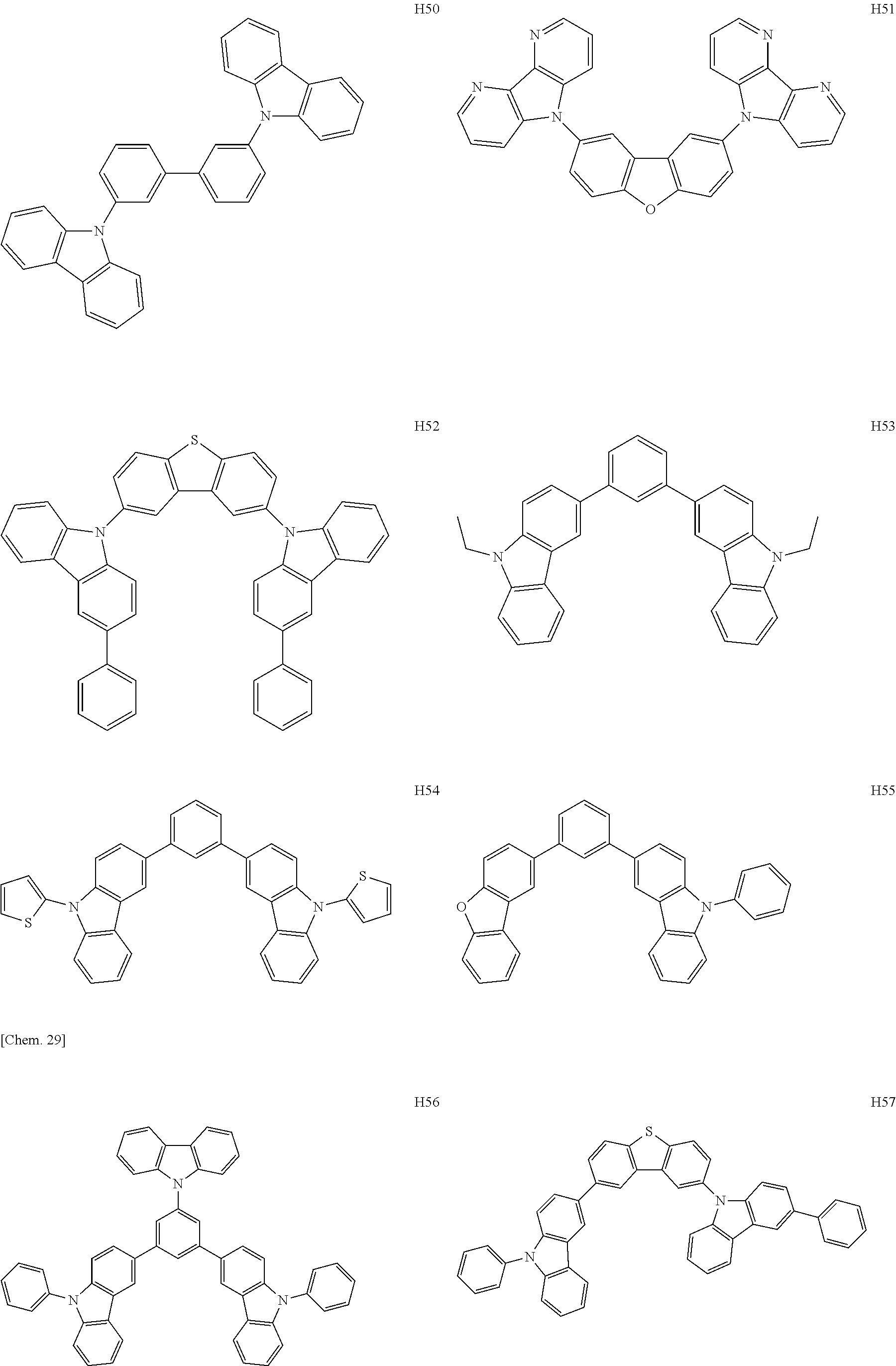

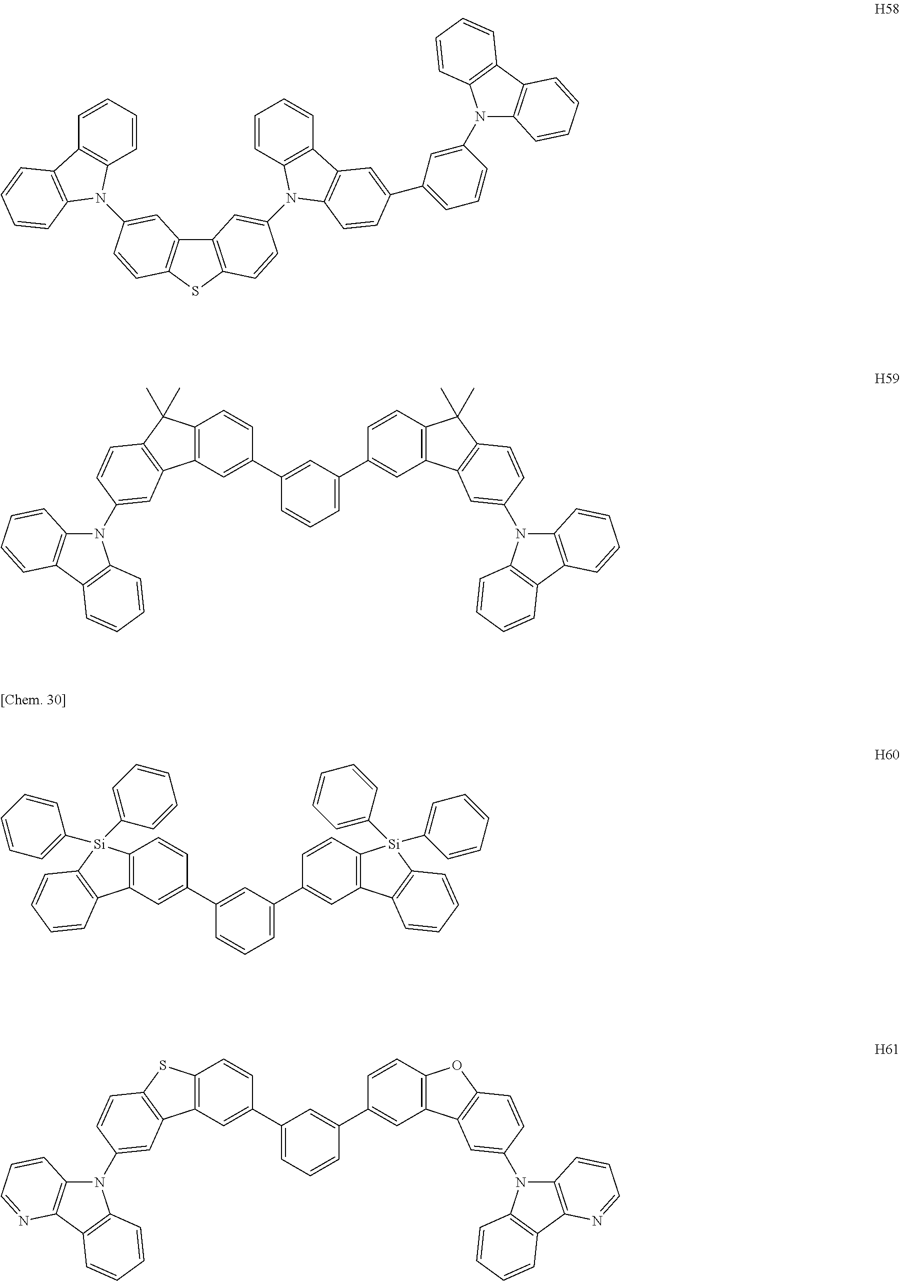 [SMILES: c1cc(-c2ccc3c(c2)c2ccccc2n3-c2ccc3sc4ccc(-n5c6ccccc6c6ccccc65)cc4c3c2)cc(-n2c3ccccc3c3ccccc32)c1 ; CC1(C)c2ccc(-c3cccc(-c4ccc5c(c4)-c4cc(-n6c7ccccc7c7ccccc76)ccc4C5(C)C)c3)cc2-c2cc(-n3c4ccccc4c4ccccc43)ccc21 ; c1ccc([Si]2(c3ccccc3)c3ccccc3-c3cc(-c4cccc(-c5ccc6c(c5)-c5ccccc5[Si]6(c5ccccc5)c5ccccc5)c4)ccc32)cc1 ; c1cc(-c2ccc3oc4ccc(-n5c6ccccc6c6ncccc65)cc4c3c2)cc(-c2ccc3sc4ccc(-n5c6ccccc6c6ncccc65)cc4c3c2)c1]

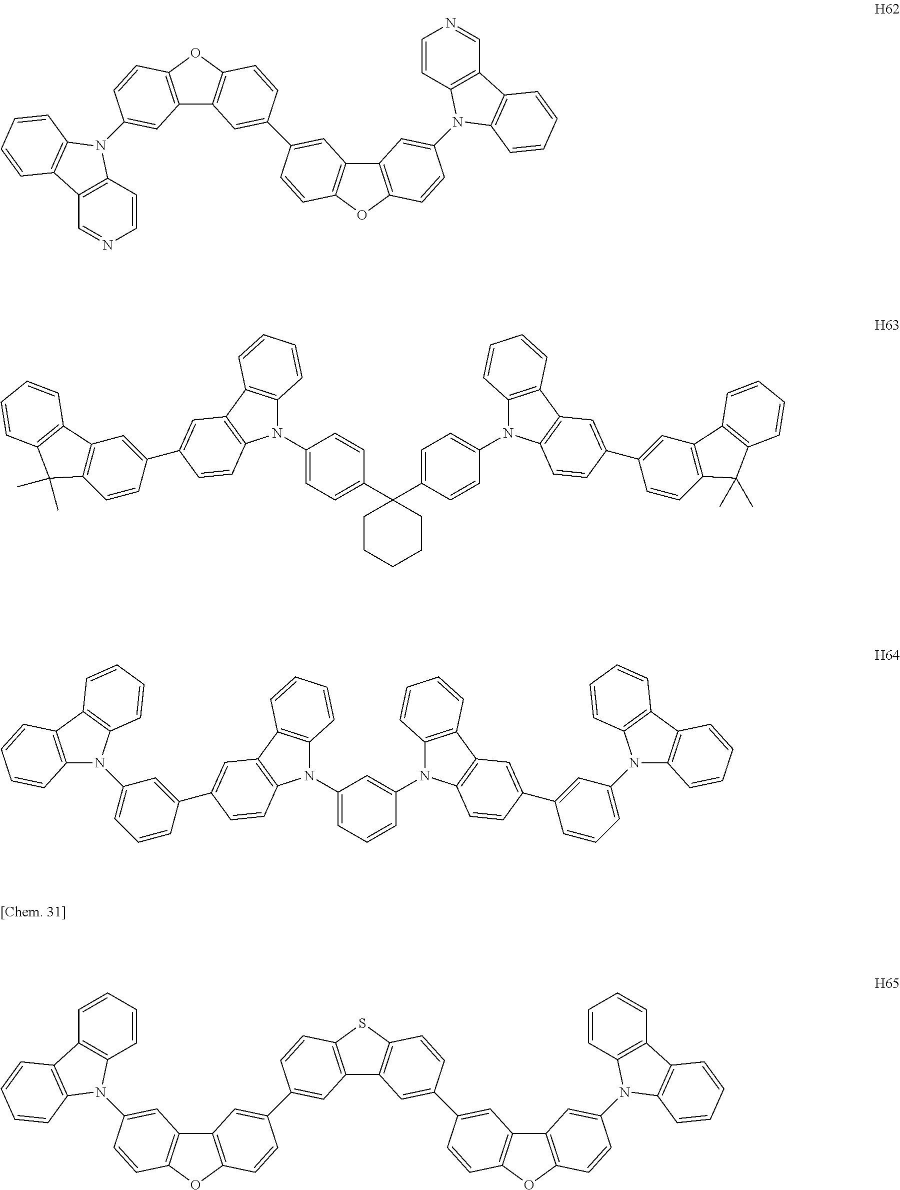 [SMILES: c1ccc2c(c1)c1cnccc1n2-c1ccc2oc3ccc(-c4ccc5oc6ccc(-n7c8ccccc8c8cnccc87)cc6c5c4)cc3c2c1 ; CC1(C)c2ccccc2-c2cc(-c3ccc4c(c3)c3ccccc3n4-c3ccc(C4(c5ccc(-n6c7ccccc7c7cc(-c8ccc9c(c8)-c8ccccc8C9(C)C)ccc76)cc5)CCCCC4)cc3)ccc21 ; c1cc(-c2ccc3c(c2)c2ccccc2n3-c2cccc(-n3c4ccccc4c4cc(-c5cccc(-n6c7ccccc7c7ccccc76)c5)ccc43)c2)cc(-n2c3ccccc3c3ccccc32)c1 ; c1ccc2c(c1)c1ccccc1n2-c1ccc2oc3ccc(-c4ccc5sc6ccc(-c7ccc8oc9ccc(-n%10c%11ccccc%11c%11ccccc%11%10)cc9c8c7)cc6c5c4)cc3c2c1]

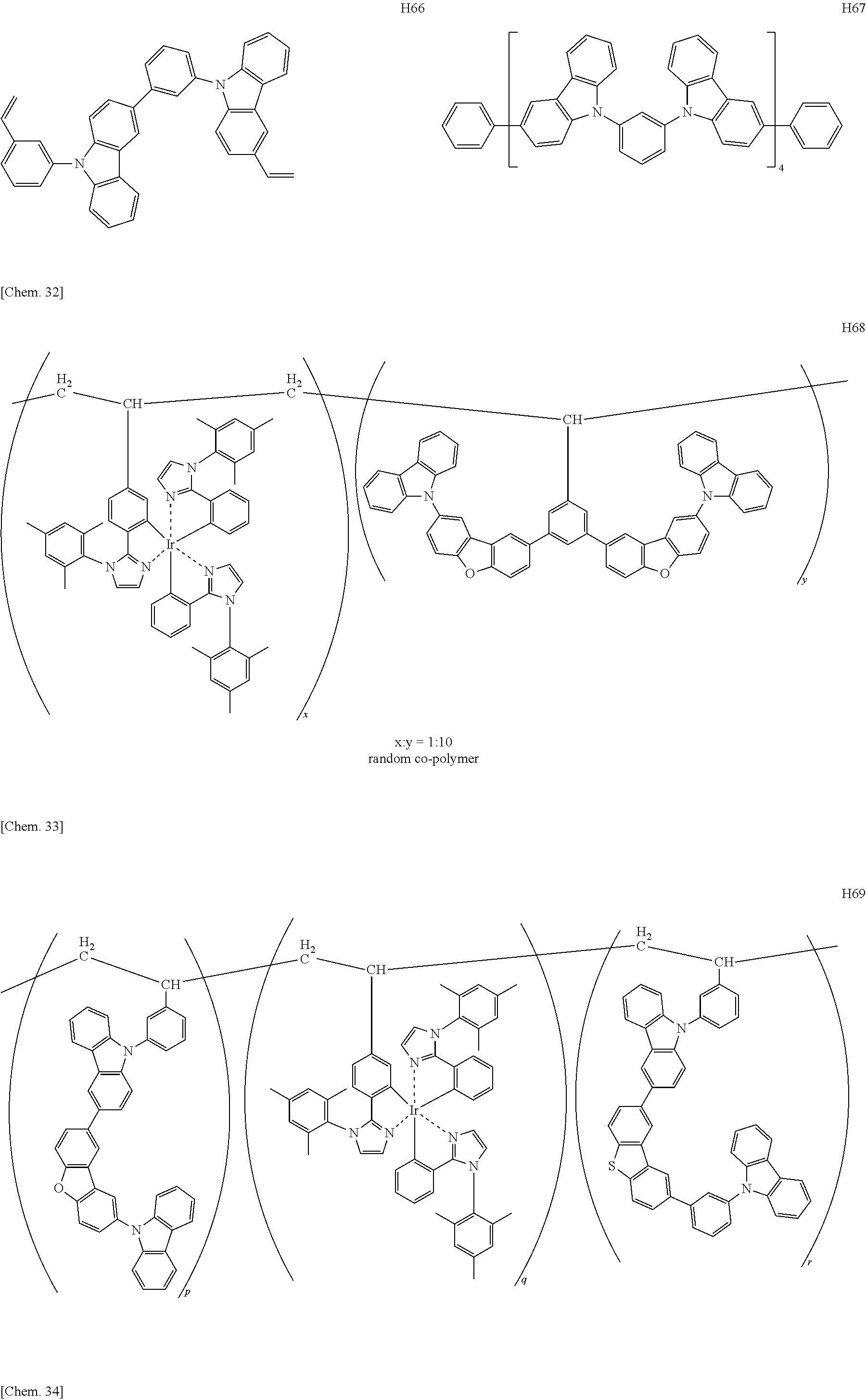

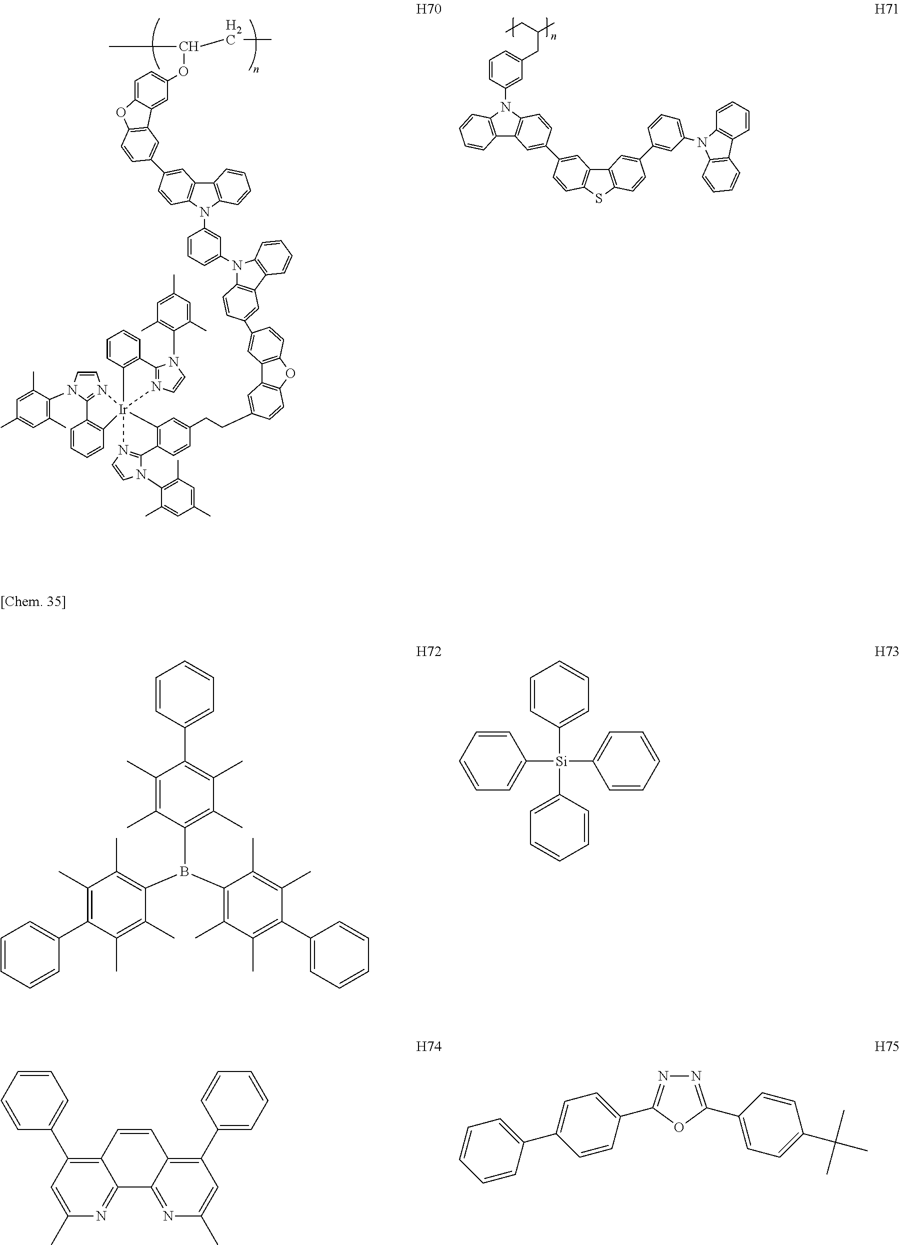

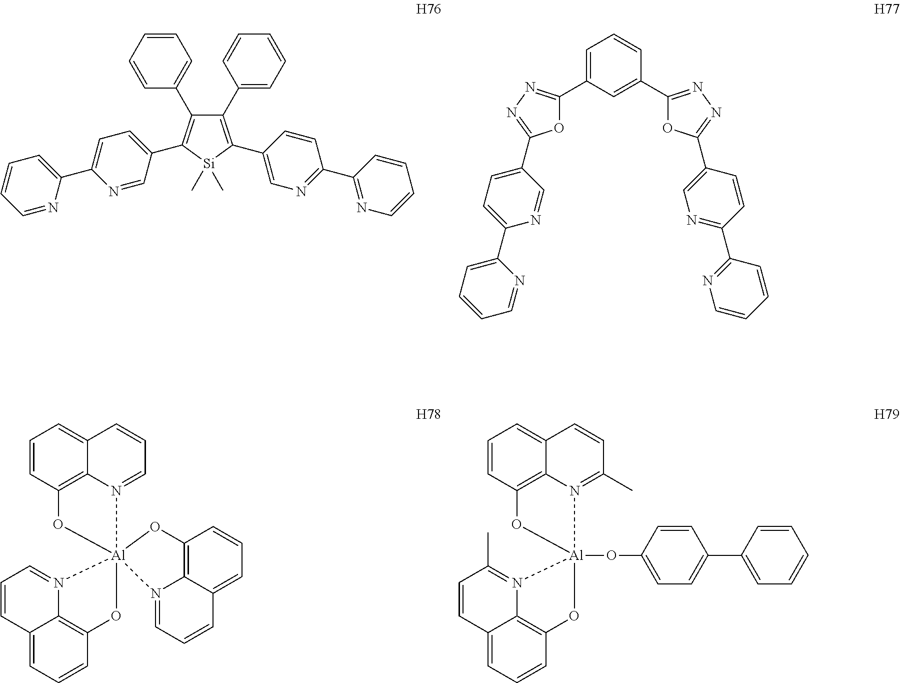

As the specific examples of other well-known host compounds usable in one or more embodiments of the invention, compounds mentioned in the following documents can be cited; for example, Japanese Patent Application Laid-Open Publication Nos. 2001-257076, 2002-308855, 2001-313179, 2002-319491, 2001-357977, 2002-334786, 2002-8860, 2002-334787, 2002-15871, 2002-334788, 2002-43056, 2002-334789, 2002-75645, 2002-338579, 2002-105445, 2002-343568, 2002-141173, 2002-352957, 2002-203683, 2002-363227, 2002-231453, 2003-3165, 2002-234888, 2003-27048, 2002-255934, 2002-260861, 2002-280183, 2002-299060, 2002-302516, 2002-305083, 2002-305084 and 2002-308837.

<Luminescent Material>

Examples of the luminescent material usable in one or more embodiments of the invention include a phosphorescent compound (also called a phosphorescent material or the like).

The phosphorescent compound is a compound in which light emission from an excited triplet state is observed, and, to be more specific, a compound which emits phosphorescence at room temperature (25° C.) and exhibits at 25° C. a phosphorescence quantum yield of 0.01 or more, or a phosphorescence quantum yield of 0.1 or more.

The phosphorescence quantum yield can be measured by a method mentioned on page 398 of Bunko II of Dai 4 Han Jikken Kagaku Koza 7 (Spectroscopy II of Lecture of Experimental Chemistry vol. 7, 4^{th} edition) (1992, published by Maruzen Co., Ltd.). The phosphorescence quantum yield in a solution can be measured by using various solvents. With respect to the phosphorescent compound used in one or more embodiments of the invention, it is only necessary to achieve the above mentioned phosphorescence quantum yield of 0.01 or more with one of appropriate solvents.

As principles regarding light emission of the phosphorescent compound, two methods are cited. One method is an energy transfer type, wherein carriers rebind on a host compound to which the carriers are transferred so as to produce an excited state of the host compound, this energy is transferred to a phosphorescent compound, and hence light emission from the phosphorescent compound is carried out. The other method is a carrier trap type, wherein a phosphorescent compound serves as a carrier trap, carriers rebind on the phosphorescent compound, and hence light emission from the phosphorescent compound is carried out. In either case, the excited state energy of the phosphorescent compound is required to be lower than that of the host compound.

The phosphorescent compound to be used can be suitably selected from well-known phosphorescent compounds used for luminescent layers of general organic EL elements, a complex compound containing a metal of Groups 8 to 10 in the element periodic table; an iridium compound, an osmium compound, a platinum compound (a platinum complex compound) or a rare-earth complex; or an iridium compound.

In one or more embodiments of the invention, at least one luminescent layer 3c may contain two or more types of phosphorescent compounds, and a concentration ratio of the phosphorescent compounds in the luminescent layer 3c may be various in a direction of the thickness of the luminescent layer 3c.

The content of the phosphorescent compound(s) in the total amount of the luminescent layer(s) 3c may be within a range from 0.1 to 30 vol %.

<1> Compound Represented by General Formula (A)

The luminescent layer 3c of one or more embodiments of the invention may contain a compound represented by the following General Formula (A) as the phosphorescent compound.

The phosphorescent compound (also called a phosphorescent metal complex) represented by the following General Formula (A) may be contained in the luminescent layer 3c of the organic EL element 100 as a luminescent dopant, but the compound may be contained in a layer of the light-emitting functional layer other than the luminescent layer 3c.

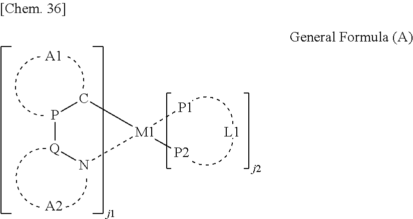

In the above General Formula (A), P and Q each represent a carbon atom or a nitrogen atom; A₁ represents an atomic group which forms an aromatic hydrocarbon ring or an aromatic heterocyclic ring with P-C; A₂ represents an atomic group which forms an aromatic heterocyclic ring with Q-N; P₁-L₁-P₂ represents a bidentate ligand, P₁ and P₂ each independently represent a carbon atom, a nitrogen atom or an oxygen atom, and L1 represents an atomic group which forms the bidentate ligand with P₁ and P₂; j1 represents an integer of one to three, and j2 represents an integer of zero to two, provided that the sum of j1 and j2 is two or three; and M₁ represents a transition metal element of Groups 8 to 10 in the element periodic table.

In General Formula (A), P and Q each represent a carbon atom or a nitrogen atom.

Examples of the aromatic hydrocarbon ring which is formed by A₁ with P-C in General Formula (A) include a benzene ring, a biphenyl ring, a naphthalene ring, an azulene ring, an anthracene ring, a phenanthrene ring, a pyrene ring, a chrysene ring, a naphthacene ring, a triphenylene ring, an o-terphenyl ring, an m-terphenyl ring, a p-terphenyl ring, an acenaphthene ring, a coronene ring, a fluorene ring, a fluoranthrene ring, a naphthacene ring, a pentacene ring, a perylene ring, a pentaphene ring, a picene ring, a pyrene ring, a pyranthrene ring and an anthranthrene ring.

These rings may each have a substituent, and examples of the substituent include: an alkyl group (a methyl group, an ethyl group, a propyl group, an isopropyl group, a tert-butyl group, a pentyl group, a hexyl group, an octyl group, a dodecyl group, a tridecyl group, a tetradecyl group, a pentadecyl group, etc.); a cycloalkyl group (a cyclopentyl group, a cyclohexyl group, etc.); an alkenyl group (a vinyl group, an allyl group, etc); an alkynyl group (an ethynyl group, a propargyl group, etc.); an aromatic hydrocarbon group (also called an aromatic carbocyclic group, an aryl group or the like; a phenyl group, a p-chlorophenyl group, a mesityl group, a tolyl group, a xylyl group, a naphthyl group, an anthryl group, an azulenyl group, an acenaphthenyl group, a fluorenyl group, a phenanthryl group, an indenyl group, a pyrenyl group, a biphenyryl group, etc.); an aromatic heterocyclic group (a furyl group, a thienyl group, a pyridyl group, a pyridazinyl group, a pyrimidinyl group, a pyrazinyl group, a triazinyl group, an imidazolyl group, a pyrazolyl group, a thiazolyl group, a quinazolinyl group, a carbazolyl group, a carbolinyl group, a diazacarbazolyl group (indicating a group formed in such a way that one of carbon atoms constituting a carboline ring of a carbolinyl group is substituted by a nitrogen atom), a phtharazinyl group, etc.); a heterocyclic group (a pyrrolidyl group, an imidazolidyl group, a morpholyl group, an oxazolidyl group, etc.); an alkoxy group (a methoxy group, an ethoxy group, a propyloxy group, a pentyloxy group, an hexyloxy group, an octyloxy group, a dodecyloxy group, etc.); a cycloalkoxy group (a cyclopentyloxy group, a cyclohexyloxy group, etc.); an aryloxy group (a phenoxy group, a naphthyloxy group, etc.); an alkylthio group (a methylthio group, an ethylthio group, a propylthio group, a pentylthio group, a hexylthio group, an octylthio group, a dodecylthio group, etc.); a cycloalkylthio group (a cyclopentylthio group, a cyclohexylthio group, etc.); an arylthio group (a phenylthio group, a naphthylthio group, etc.); an alkoxycarbonyl group (a methyloxycarbonyl group, an ethyloxycarbonyl group, a butyloxycarbonyl group, an octyloxycarbonyl group, a dodecyloxycarbonyl group, etc.); an aryloxycarbonyl group (a phenyloxycarbonyl group, a naphthyloxycarbonyl group, etc.); a sulfamoyl group (an aminosulfonyl group, a methylaminosulfonyl group, a dimethylaminosulfonyl group, a butylaminosulfonyl group, a hexylaminosulfonyl group, a cyclohexylaminosulfonyl group, an octylaminosulfonyl group, a dodecylaminosulfonyl group, a phenylaminosulfonyl group, a naphthylaminosulfonyl group, a 2-pyridylaminosulfonyl group, etc.); an acyl group (an acetyl group, an ethylcarbonyl group, a propylcarbonyl group, a pentylcarbonyl group, a cyclohexylcarbonyl group, an octylcarbonyl group, a 2-ethylhexylcarbonyl group, a dodecylcarbonyl group, a phenylcarbonyl group, a naphthylcarbonyl group, a pyridylcarbonyl group, etc.); an acyloxy group (an acetyloxy group, an ethylcarbonyloxy group, a butylcarbonyloxy group, an octylcarbonyloxy group, a dodecylcarbonyloxy group, a phenylcarbonyloxy group, etc.); an amido group (a methylcarbonylamino group, an ethylcarbonylamino group, a dimethylcarbonylamino group, a propylcarbonylamino group, a pentylcarbonylamino group, a cyclohexylcarbonylamino group, a 2-ethylhexylcarbonylamino group, an octylcarbonylamino group, a dodecylcarbonylamino group, a phenylcarbonylamino group, a naphthylcarbonylamino group, etc.); a carbamoyl group (an aminocarbonyl group, a methylaminocarbonyl group, a dimethylaminocarbonyl group, a propylaminocarbonyl group, a pentylaminocarbonyl group, a cyclohexylaminocarbonyl group, an octylaminocarbonyl group, a 2-ethylhexylaminocarbonyl group, a dodecylaminocarbonyl group, a phenylaminocarbonyl group, a naphthylaminocarbonyl group, a 2-pyridylaminocarbonyl group, etc.); an ureido group (a methylureido group, an ethylureido group, a pentylureido group, a cyclohexylureido group, an octylureido group, a dodecylureido group, a phenylureido group naphthylureido group, a 2-pyridylaminoureido group, etc.); a sulfinyl group (a methylsulfinyl group, an ethylsulfinyl group, a butylsulfinyl group, a cyclohexylsulfinyl group, a 2-ethylhexylsulfinyl group, a dodecylsulfinyl group, a phenylsulfinyl group, a naphthylsulfinyl group, a 2-pyridylsulfinyl group, etc.); an alkylsulfonyl group (a methylsulfonyl group, an ethylsulfonyl group, a butylsulfonyl group, a cyclohexylsulfonyl group, a 2-ethylhexylsulfonyl group, a dodecylsulfonyl group, etc.); an arylsulfonyl group or a heteroarylsulfonyl group (a phenylsulfonyl group, a naphthylsulfonyl group, a 2-pyridylsulfonyl group, etc.); an amino group (an amino group, an ethylamino group, a dimethylamino group, a butylamino group, a cyclopentylamino group, a 2-ethylhexylamino group, a dodecylamino group, an anilino group, a naphthylamino group, a 2-pyridylamino group, a piperidyl group (also called a piperidinyl group), a 2,2,6,6-tetramethylpiperidinyl group, etc.); a halogen atom (a fluorine atom, a chlorine atom, a bromine atom, etc.); a fluorohydrocarbon group (a fluoromethyl group, a trifluoromethyl group, a pentafluoroethyl group, a pentafluorophenyl group, etc.); a cyano group; a nitro group; a hydroxyl group; a mercapto group; a silyl group (a trimethylsilyl group, a triisopropylsilyl group, a triphenylsilyl group, a phenyldiethylsilyl group, etc.); a phosphate group (dihexylphosphoryl group, etc.); a phosphite group (diphenylphosphinyl group, etc.); and a phosphono group.

Examples of the aromatic heterocyclic ring which is formed by A1 with P-C in General Formula (A) include a furan ring, a thiophene ring, an oxazole ring, a pyrrole ring, a pyridine ring, a pyridazine ring, a pyrimidine ring, a pyrazine ring, a triazine ring, a benzimidazole ring, an oxadiazole ring, a triazole ring, an imidazole ring, a pyrazole ring, a thiazole ring, an indole ring, a benzimidazole ring, a benzothiazole ring, a benzoxazole ring, a quinoxaline ring, a quinazoline ring, a phthalazine ring, a carbazole ring and an azacarbazole ring.

The azacarbazole ring indicates a ring formed in such a way that at least one of carbon atoms of a benzene ring constituting a carbazole ring is substituted by a nitrogen atom.

These rings may each have the substituent mentioned above.

Examples of the aromatic heterocyclic ring which is formed by A₂ with Q-N in General Formula (A) include an oxazole ring, an oxadiazole ring, an oxatriazole ring, an isoxazole ring, a tetrazole ring, a thiadiazole ring, a thiatriazole ring, an isothiazole ring, a pyrrole ring, a pyridine ring, a pyridazine ring, a pyrimidine ring, a pyrazine ring, a triazine ring, an imidazole ring, a pyrazole ring and a triazole ring.

These rings may each have the substituent mentioned above.

In General Formula (A), P₁-L₁-P₂ represents a bidentate ligand, P₁ and P₂ each independently represent a carbon atom, a nitrogen atom or an oxygen atom, and L₁ represents an atomic group which forms the bidentate ligand with P₁ and P₂.

Examples of the bidentate ligand represented by P₁-L₁-P₂ include phenylpyridine, phenylpyrazole, phenylimidazole, phenyltriazole, phenyltetrazole, pyrazabole, acetylacetone and picolinic acid.

In General Formula (A), j1 represents an integer of one to three, and j2 represents an integer of zero to two, provided that the sum of j1 and j2 is two or three. j2 may be zero.

In General Formula (A), M₁ represents a transition metal element (simply called a transition metal) of Groups 8 to 10 in the element periodic table. M₁ being iridium may be used.

<2> Compound Represented by General Formula (B)

The compound represented by General Formula (A) described above may be a compound represented by the following General Formula (B).

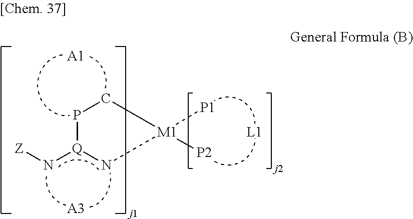

In the above General Formula (B), Z represents a hydrocarbon ring group or a heterocyclic group; P and Q each represent a carbon atom or a nitrogen atom; A₁ represents an atomic group which forms an aromatic hydrocarbon ring or an aromatic heterocyclic ring with P-C; A₃ represents —C(R₀₁)═C(R₀₂)—N═C(R₀₂)—, —C(R₀₁)═N— or —N═N—, and R₀₁ and R₀₂ each represent a hydrogen atom or a substituent; P₁-L₁-P₂ represents a bidentate ligand, P₁ and P₂ each independently represent a carbon atom, a nitrogen atom or an oxygen atom, and L₁ represents an atomic group which forms the bidentate ligand with P₁ and P₂; j1 represents an integer of one to three, and j2 represents an integer of zero to two, provided that the sum of j1 and j2 is two or three; M₁ represents a transition metal element of Groups 8 to 10 in the element periodic table.

Examples of the hydrocarbon ring group represented by Z in General Formula (B) include a non-aromatic hydrocarbon ring group and an aromatic hydrocarbon ring group. Examples of the non-aromatic hydrocarbon ring group include a cyclopropyl group, a cyclopentyl group and a cyclohexyl group. These groups may be each a non-substituted group or may each have a substituent which is the same as the substituent which the ring represented by A₁ in the above General Formula (A) may have.

Examples of the aromatic hydrocarbon ring group (also called an aromatic hydrocarbon group, an aryl group or the like) include a phenyl group, a p-chlorophenyl group, a mesityl group, a tolyl group, a xylyl group, a naphthyl group, an anthryl group, an azulenyl group, an acenaphthenyl group, a fluorenyl group, a phenanthryl group, an indenyl group, a pyrenyl group and a biphenyl group.

These groups may be each a non-substituted group or may each have a substituent. Examples of the substituent include those of the substituent which the ring represented by A₁ in the above General Formula (A) may have.

Examples of the heterocyclic group represented by Z in General Formula (B) include a non-aromatic heterocyclic group and an aromatic heterocyclic group. Examples of the non-aromatic heterocyclic group include groups derived from, for example, an epoxy ring, an aziridine ring, a thiirane ring, an oxetane ring, an azetidine ring, a thietane ring, a tetrahydrofuran ring, a dioxorane ring, a pyrrolidine ring, a pyrazolidine ring, an imidazolidine ring, an oxazolidine ring, a tetrahydrothiophene ring, a sulforane ring, a thiazolidine ring, an ε-caprolactone ring, an ε-caprolactam ring, a piperidine ring, a hexahydropyridazine ring, a hexahydropyrimidine ring, a piperazine ring, a morpholine ring, a tetrahydropyrane ring, a 1,3-dioxane ring, a 1,4-dioxane ring, a trioxane ring, a tetrahydrothiopyrane ring, a thiomorpholine ring, a thiomorpholine-1,1-dioxide ring, a pyranose ring and a diazabicyclo[2,2,2]-octane ring.

These groups may be each a non-substituted group or may each have a substituent. Examples of the substituent include those of the substituent which the ring represented by A₁ in the above General Formula (A) may have.

Examples of the aromatic heterocyclic group include a pyridyl group, a pyrimidinyl group, a furyl group, a pyrrolyl group, an imidazolyl group, a benzimidazolyl group, a pyrrazolyl group, a pyradinyl group, a triazolyl group (a 1,2,4-triazole-1-yl group, a 1,2,3-triazole-1-yl group, etc.), an oxazolyl group, a benzoxazolyl group, a thiazolyl group, an isoxazolyl group, an isothiazolyl group, a furazanyl group, a thienyl group, a quinolyl group, a benzofuryl group, a dibenzofuryl group, a benzothienyl group, a dibenzothienyl group, an indolyl group, a carbazolyl group, a carbolinyl group, a diazacarbazolyl group (indicating a group formed in such a way that one of carbon atoms constituting a carboline ring of a carbolinyl group is substituted by a nitrogen atom), a quinoxalinyl group, a pyridazinyl group, a triazinyl group, a quinazolinyl group and a phthalazinyl group.

These groups may be each a non-substituted group or may each have a substituent. Examples of the substituent include those of the substituent which the ring represented by A₁ in the above General Formula (A) may have.

The group represented by Z may be an aromatic hydrocarbon ring group or an aromatic heterocyclic group.

Examples of the aromatic hydrocarbon ring which is formed by A₁ with P-C in General Formula (B) include a benzene ring, a biphenyl ring, a naphthalene ring, an azulene ring, an anthracene ring, a phenanthrene ring, a pyrene ring, a chrysene ring, a naphthacene ring, a triphenylene ring, an o-terphenyl ring, an m-terphenyl ring, a p-terphenyl ring, an acenaphthene ring, a coronene ring, a fluorene ring, a fluoranthrene ring, a naphthacene ring, a pentacene ring, a perylene ring, a pentaphene ring, a picene ring, a pyrene ring, a pyranthrene ring and an anthranthrene ring.

These rings may each have a substituent. Examples of the substituent include those of the substituent which the ring represented by A₁ in the above General Formula (A) may have.

Examples of the aromatic heterocyclic ring which is formed by A₁ with P-C in General Formula (B) include a furan ring, a thiophene ring, an oxazole ring, a pyrrole ring, a pyridine ring, a pyridazine ring, a pyrimidine ring, a pyrazine ring, a triazine ring, a benzimidazole ring, an oxadiazole ring, a triazole ring, an imidazole ring, a pyrazole ring, a triazole ring, an indole ring, a benzimidazole ring, a benzothiazole ring, a benzoxazole ring, a quinoxaline ring, a quinazoline ring, a phthalazine ring, a carbazole ring, a carboline ring and an azacarbazole ring.

The azacarbazole ring indicates a ring formed in such a way that at least one of carbon atoms of a benzene ring constituting a carbazole ring is substituted by a nitrogen atom.

These rings may each have a substituent. Examples of the substituent include those of the substituent which the ring represented by A₁ in the above General Formula (A) may have.

The substituent represented by each of R₀₁ and R₀₂ in each of —C(R₀₁)═C(R₀₂)—, —N═C(R₀₂)— and —C(R₀₁)═N— represented by A₃ in General Formula (B) is synonymous with the substituent which the ring represented by A₁ in the above General Formula (A) may have.

Examples of the bidentate ligand represented by P₁-L₁-P₂ in General Formula (B) include phenylpyridine, phenylpyrazole, phenylimidazole, phenyltriazole, phenyltetrazole, pyrazabole, acetylacetone and picolinic acid.

j1 represents an integer of one to three, and j2 represents an integer of zero to two, provided that the sum of j1 and j2 is two or three. j2 may be zero.

The transition metal element (simply called a transition metal) of Groups 8 to 10 in the element periodic table represented by M₁ in General Formula (B) is synonymous with the transition metal element of Groups 8 to 10 in the element periodic table represented by M₁ in the above General Formula (A)

<3> Compound Represented by General Formula (C)

In one or more embodiments of the invention, of the compounds represented by the above General Formula (B), compound represented by the following General Formula (C) may be used.

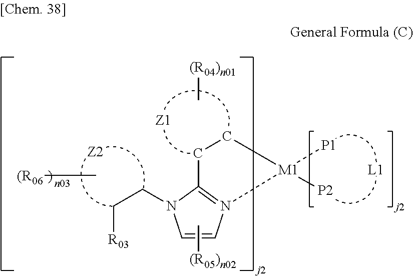

In the above General Formula (C), R₀₃ represents a substituent; R₀₄ represents a hydrogen atom or a substituent, and a plurality of R₀₄ may bind to each other to form a ring; n01 represents an integer of one to four; R₀₅ represents a hydrogen atom or a substituent, and a plurality of R₀₅ may bind to each other to form a ring; n02 represents an integer of one to two; R₀₆ represents a hydrogen atom or a substituent, and a plurality of R₀₆ may bind to each other to form a ring; n03 represents an integer of one to four; Z₁ represents an atomic group required to form a six-membered aromatic hydrocarbon ring or a five-membered or six-membered aromatic heterocyclic ring with C—C; Z₂ represents an atomic group required to form a hydrocarbon ring group or a heterocyclic group; P₁-L₁-P₂ represents a bidentate ligand, P₁ and P₂ each independently represent a carbon atom, a nitrogen atom or an oxygen atom, and L₁ represents an atomic group which forms the bidentate ligand with P₁ and P₂; j1 represents an integer of one to three, and j2 represents an integer of zero to two, provided that the sum of j1 and j2 is two or three; M₁ represents a transition metal element of Groups 8 to 10 in the element periodic table; and R₀₃ and R₀₆, R₀₄ and R₀₆, and R₀₅ and R₀₆ may each bind to each other to form a ring.

The substituent represented by each of R₀₃, R₀₄, R₀₅ and R₀₆ in General Formula (C) is synonymous with the substituent which the ring represented by A₁ in the above General Formula (A) may have.

Examples of the six-membered aromatic hydrocarbon ring which is formed by Z₁ with C—C in General Formula (C) include a benzene ring.

These rings may each have a substituent. Examples of the substituent include those of the substituent which the ring represented by A₁ in the above General Formula (A) may have.

Examples of the five-membered or six-membered aromatic heterocyclic ring which is formed by Z₁ with C—C in General Formula (C) include an oxazole ring, an oxadiazole ring, an oxatriazole ring, an isoxazole ring, a tetrazole ring, a thiadiazole ring, a thiatriazole ring, an isothiazole ring, a thiophene ring, a furan ring, a pyrrole ring, a pyridine ring, a pyridazine ring, a pyrimidine ring, a pyrazine ring, a triazine ring, an imidazole ring, a pyrazole ring and a triazole ring.

These rings may each have a substituent. Examples of the substituent include those of the substituent which the ring represented by A₁ in the above General Formula (A) may have.

Examples of the hydrocarbon ring group represented by Z₂ in General Formula (C) include a non-aromatic hydrocarbon ring group and an aromatic hydrocarbon ring group. Examples of the non-aromatic hydrocarbon ring group include a cyclopropyl group, a cyclopentyl group and a cyclohexyl group. These groups may be each a non-substituted group or may each have a substituent. Examples of the substituent include those of the substituent which the ring represented by A₁ in the above General Formula (A) may have.

Examples of the aromatic hydrocarbon ring group (also called an aromatic hydrocarbon group, an aryl group or the like) include a phenyl group, a p-chlorophenyl group, a mesityl group, a tolyl group, a xylyl group, a naphthyl group, an anthryl group, an azulenyl group, an acenaphthenyl group, a fluorenyl group, a phenanthryl group, an indenyl group, a pyrenyl group and a biphenyl group. These groups may be each a non-substituted group or may each have a substituent. Examples of the substituent include those of the substituent which the ring represented by A₁ in General Formula (A) may have.

Examples of the heterocyclic group represented by Z₂ in General Formula (C) include a non-aromatic heterocyclic group and an aromatic heterocyclic group. Examples of the non-aromatic heterocyclic group include groups derived from, for example, an epoxy ring, an aziridine ring, a thiirane ring, an oxetane ring, an azetidine ring, a thietane ring, a tetrahydrofuran ring, a dioxorane ring, a pyrrolidine ring, a pyrazolidine ring, an imidazolidine ring, an oxazolidine ring, a tetrahydrothiophene ring, a sulforane ring, a thiazolidine ring, an ε-caprolactone ring, an ε-caprolactam ring, a piperidine ring, a hexahydropyridazine ring, a hexahydropyrimidine ring, a piperazine ring, a morpholine ring, a tetrahydropyrane ring, a 1,3-dioxane ring, a 1,4-dioxane ring, a trioxane ring, a tetrahydrothiopyrane ring, a thiomorpholine ring, a thiomorpholine-1,1-dioxide ring, a pyranose ring and a diazabicyclo[2,2,2]-octane ring. These groups may be each a non-substituted group or may each have a substituent. Examples of the substituent include those of the substituent which the ring represented by A₁ in General Formula (A) may have.

Examples of the aromatic heterocyclic group include a pyridyl group, a pyrimidinyl group, a furyl group, a pyrrolyl group, an imidazolyl group, a benzimidazolyl group, a pyrrazolyl group, a pyradinyl group, a triazolyl group (a 1,2,4-triazole-1-yl group, a 1,2,3-triazole-1-yl group, etc.), an oxazolyl group, a benzoxazolyl group, a thiazolyl group, an isoxazolyl group, an isothiazolyl group, a furazanyl group, a thienyl group, a quinolyl group, a benzofuryl group, a dibenzofuryl group, a benzothienyl group, a dibenzothienyl group, an indolyl group, a carbazolyl group, a carbolinyl group, a diazacarbazolyl group (indicating a group formed in such a way that one of carbon atoms constituting a carboline ring of a carbolinyl group is substituted by a nitrogen atom), a quinoxalinyl group, a pyridazinyl group, a triazinyl group, a quinazolinyl group and a phthalazinyl group.

These rings may be each a non-substituted ring or may each have a substituent. Examples of the substituent include those of the substituent which the ring represented by A₁ in the above General Formula (A) may have.

The group which is formed by each of Z₁ and Z₂ in General Formula (C) may be a benzene ring.

The bidentate ligand represented by P₁-L₁-P₂ in General Formula (C) is synonymous with the bidentate ligand represented by P₁-L₁-P₂ in the above General Formula (A).

The transition metal element of Groups 8 to 10 in the element periodic table represented by M₁ in General Formula (C) is synonymous with the transition metal element of Groups 8 to 10 in the element periodic table represented by M₁ in the above General Formula (A).

The phosphorescent compound to be used can be suitably selected from the well-known phosphorescent compounds, which are usable for the luminescent layer 3c of the organic EL element 100.

The phosphorescent compound of one or more embodiments of the invention may be a complex compound containing a metal of Groups 8 to 10 in the element periodic table; an iridium compound, an osmium compound, a platinum compound (a platinum complex compound) or a rare-earth complex; and an iridium compound.

Specific examples Pt-1 to Pt-3, A-1, and Ir-1 to Ir-45 of the phosphorescent compound of one or more embodiments of the invention are shown below, but embodiments of the invention are not limited thereto. In these compounds, m and n each represent the number of repeats.

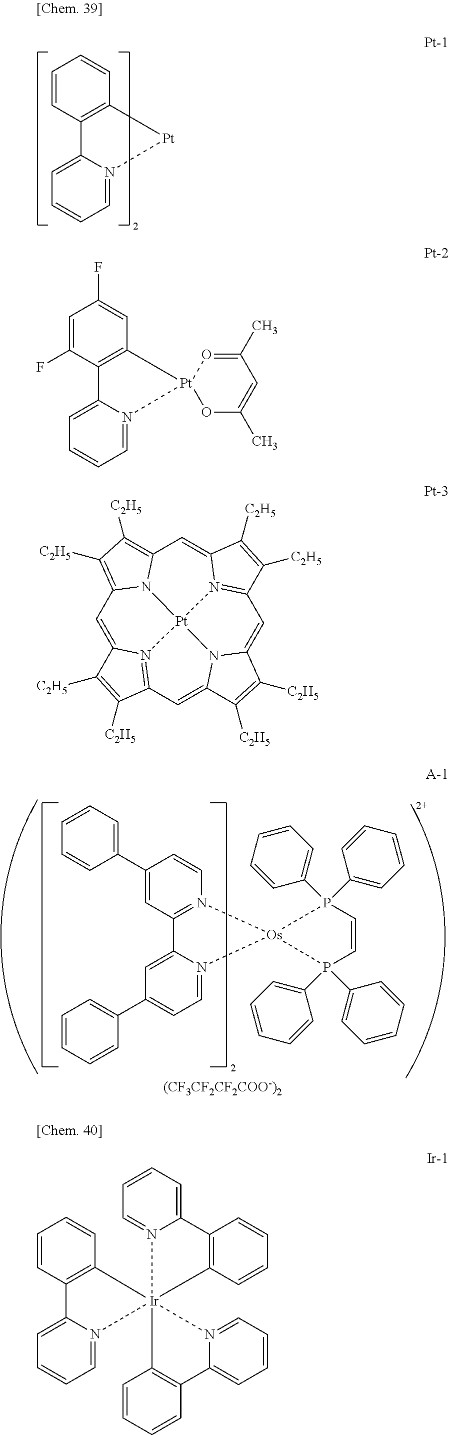

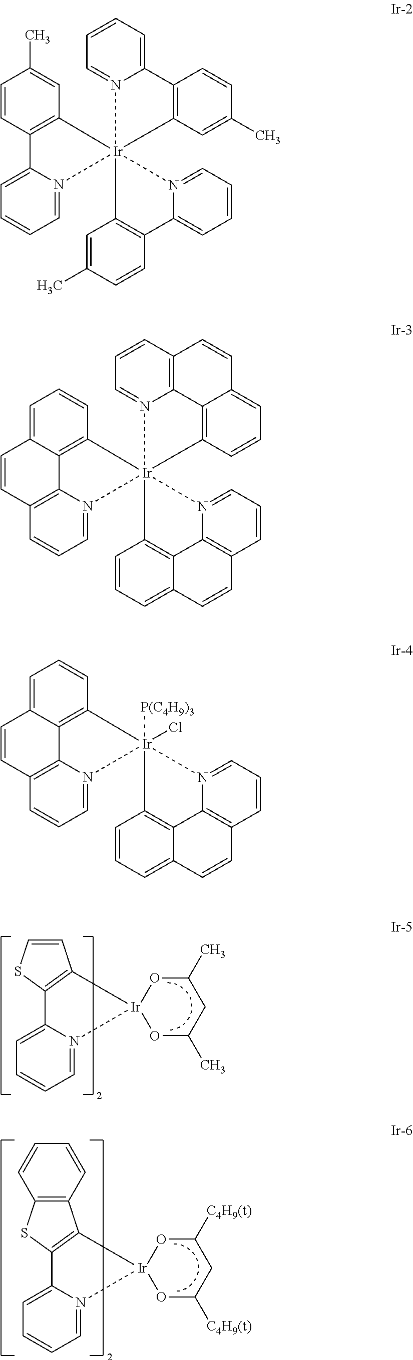

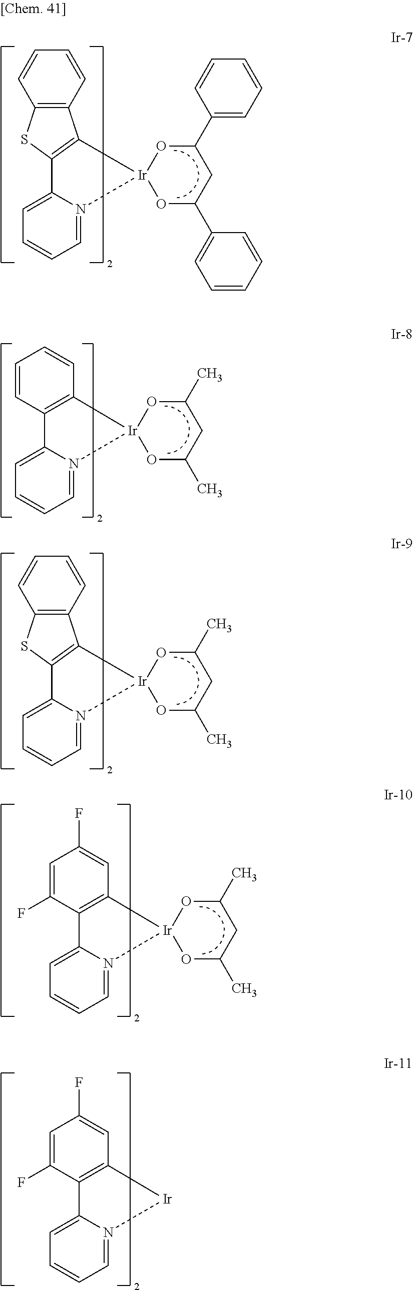

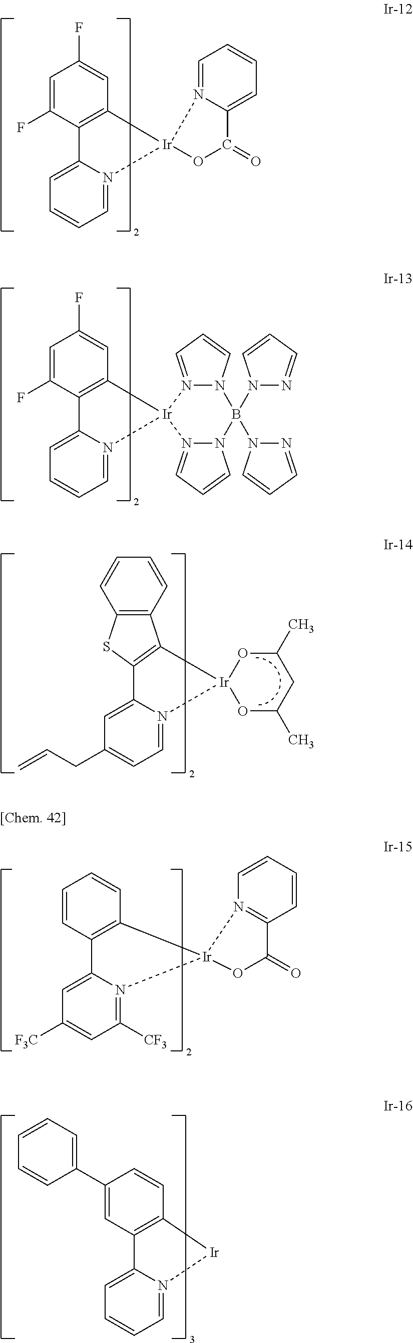

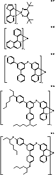

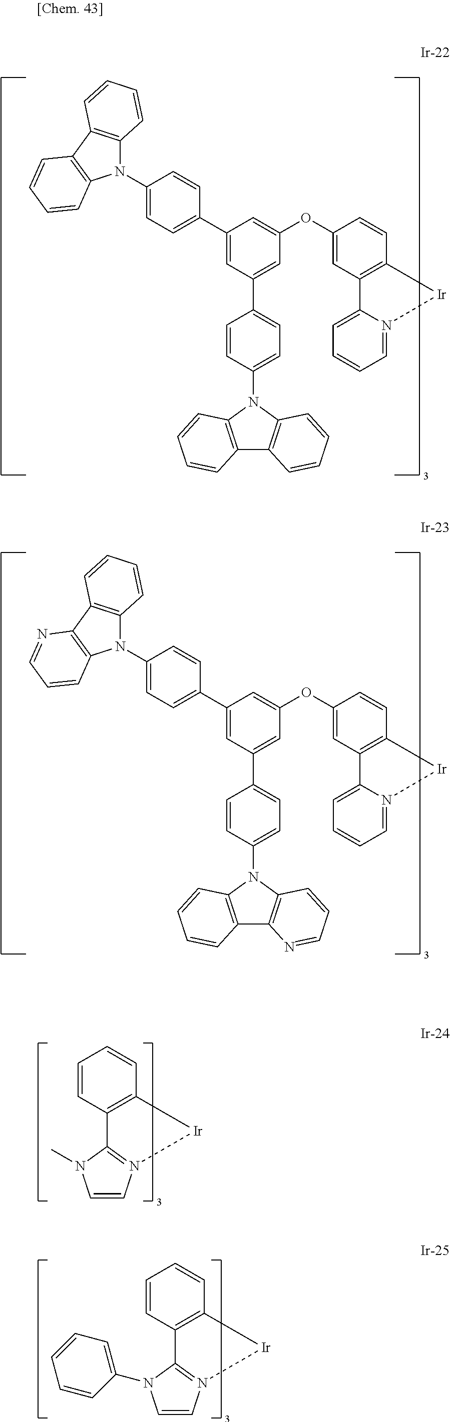

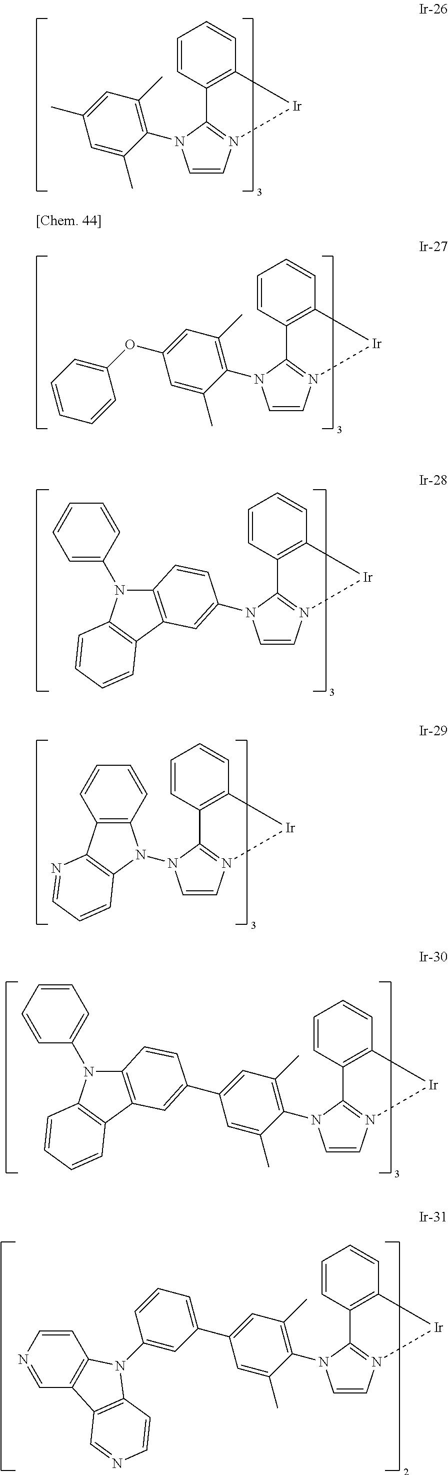

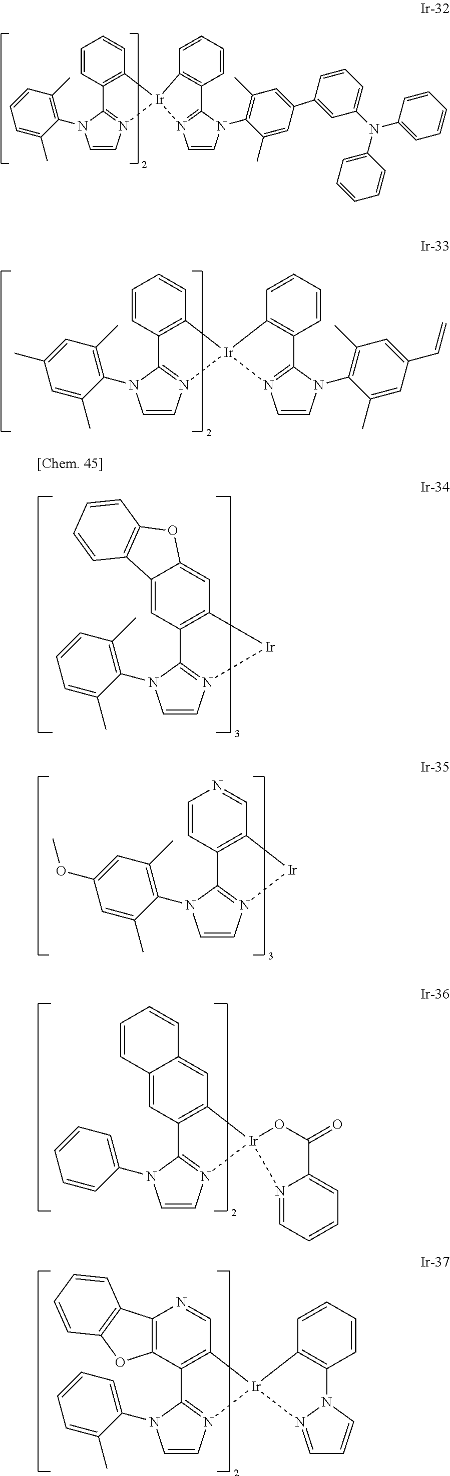

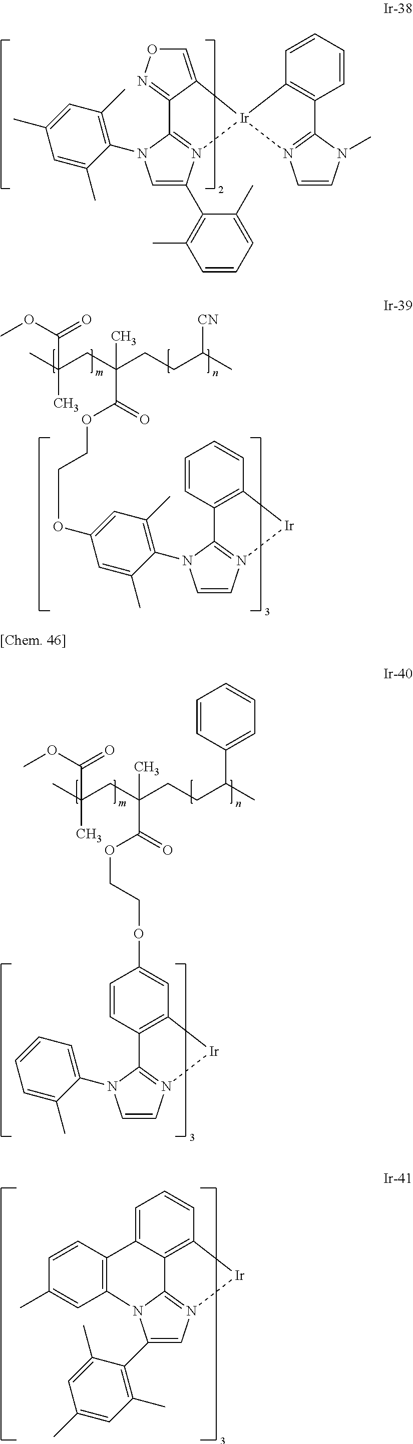

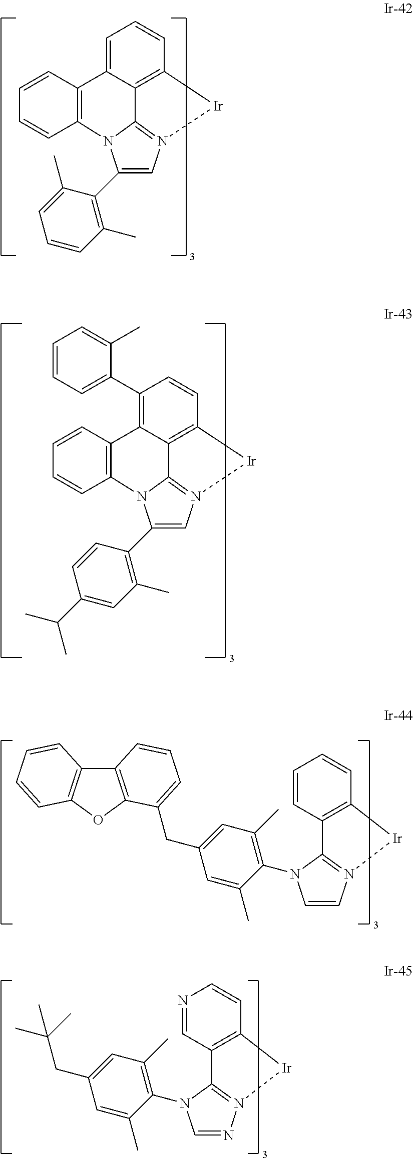

The above mentioned phosphorescent compounds (also called phosphorescent metal complexes) can be synthesized by employing methods mentioned in documents such as Organic Letter, vol. 3, No. 16, pp. 2579-2581 (2001); Inorganic Chemistry, vol. 30, No. 8, pp. 1685-1687 (1991); J. Am. Chem. Soc., vol. 123, p. 4304 (2001); Inorganic Chemistry, vol. 40, No. 7, pp. 1704-1711 (2001); Inorganic Chemistry, vol. 41, No. 12, pp. 3055-3066 (2002); New Journal of Chemistry, vol. 26, p. 1171 (2002); and European Journal of Organic Chemistry, vol. 4, pp. 695-709 (2004); and reference documents and the like mentioned in these documents.

<Fluorescent Material>

Examples of the fluorescent material include a coumarin dye, a pyran dye, a cyanine dye, a croconium dye, a squarium dye, an oxobenzanthracene dye, a fluorescein dye, a rhodamine dye, a pyrylium dye, a perylene dye, a stilbene dye, a polythiophene dye and a rare-earth complex phosphor.

(Injection Layer)

The injection layer(s) (the positive hole injection layer 3a and the electron injection layer 3e) is a layer disposed between an electrode and the luminescent layer 3c for reduction in driving voltage and increase in luminance of light emitted, which is detailed in Part 2, Chapter 2 “Denkyoku Zairyo (Electrode Material)” (pp. 123-166) of “Yuki EL Soshi To Sono Kogyoka Saizensen (Organic EL Element and Front of Industrialization thereof) (Nov. 30, 1998, published by N.T.S Co., Ltd.)”, and examples thereof include the positive hole injection layer 3a and the electron injection layer 3e.

The injection layer can be provided as needed. In the case of the positive hole injection layer 3a, it may be present between the anode and the luminescent layer 3c or the positive hole transport layer 3b. In the case of the electron injection layer 3e, it may be present between the cathode and the luminescent layer 3c or the electron transport layer 3d.

The positive hole injection layer 3a is detailed in documents such as Japanese Patent Application Publication Nos. 9-45479, 9-260062 and 8-288069, and examples thereof include: a phthalocyanine layer of, for example, copper phthalocyanine; an oxide layer of, for example, vanadium oxide; an amorphous carbon layer; and a high polymer layer using a conductive high polymer such as polyaniline (emeraldine) or polythiophene.

The electron injection layer 3e is detailed in documents such as Japanese Patent Application Publication Nos. 6-325871, 9-17574 and 10-74586, and examples thereof include: a metal layer of, for example, strontium or aluminum; an alkali metal halide layer of, for example, potassium fluoride; an alkali earth metal compound layer of, for example, magnesium fluoride; and an oxide layer of, for example, molybdenum oxide. The electron injection layer 3e of one or more embodiments of the invention may be a very thin film, and the thickness thereof be within a range from 1 nm to 10 μm although it depends on the material thereof.

(Positive Hole Transport Layer)

The positive hole transport layer 3b is composed of a positive hole transport material having a function to transport positive holes, and, in a broad sense, the positive hole injection layer 3a and the electron block layer are of the positive hole transport layer 3b. The positive hole transport layer 3b may be composed of a single layer or a plurality of layers.

The positive hole transport material is a material having either the property to inject or transport positive holes or a barrier property against electrons and is either an organic matter or an inorganic matter. Examples thereof include a triazole derivative, an oxadiazole derivative, an imidazole derivative, a polyarylalkane derivative, a pyrazoline derivative, a pyrazolone derivative, a phenylenediamine derivative, an arylamine derivative, an amino-substituted chalcone derivative, an oxazole derivative, a styrylanthracene derivative, a fluorenone derivative, a hydrazone derivative, a stilbene derivative, a silazane derivative, an aniline copolymer and an oligomer of a conductive high polymer such as a thiophene oligomer.

As the positive hole transport material, those mentioned above can be used. However, a porphyrin compound, an aromatic tertiary amine compound or a styrylamine compound may be used.

Representative examples of the aromatic tertiary amine compound and the styrylamine compound include: N,N,N′,N′-tetraphenyl-4,4′-diaminophenyl; N,N′-diphenyl-N,N′-bis(3-methylphenyl)-[1,1′-biphenyl]-4,4′-diamine (abbr.: TDP); 2,2-bis(4-di-p-tolylaminophenyl)propane; 1,1-bis(4-di-p-tolylaminophenyl)cyclohexane; N,N,N′,N′-tetra-p-tolyl-4,4′-diaminobiphenyl; 1,1-bis(4-di-p-tolylaminophenyl)-4-phenylcyclohexane; bis(4-dimethylamino-2-metylphenyl)phenylmethane; bis(4-di-p-tolylaminophenyl)phenylmethane; N,N′-diphenyl-N,N′-di(4-methoxyphenyl)-4,4′-diaminobiphenyl; N,N,N′,N′-tetraphenyl-4,4′-diaminodiphenylether; 4,4′-bis(diphenylamino)quadriphenyl; N,N,N-trip-tolyl)amine; 4-(di-p-tolylamino)-4′-[4-(di-p-tolylamino)styryl]stilbene; 4-N, N-diphenylamino-(2-diphenylvinyl)benzene; 3-methoxy-4′-N,N-diphenylaminostilbezene; N-phenylcarbazole; those having two condensed aromatic rings in a molecule mentioned in U.S. Pat. No. 5,061,569, such as 4,4′-bis[N-(1-naphthyl)-N-phenylamino]biphenyl (abbr.: NDP); and 4,4′,4″-tris[N-(3-methylphenyl)-N-phenylamino]triphenylamine (abbr.: MTDATA) in which three triphenylamine units are bonded in a star burst form mentioned in Japanese Patent Application Publication No. 4-308688.

High polymer materials in each of which any of the above mentioned materials is introduced into a high polymer chain or constitutes a main chain of a high polymer can also be used. Inorganic compounds such as a p type-Si and a p type-SiC can also be used as the positive hole injection material and the positive hole transport material.

It is also possible to use so-called p type positive hole transport materials mentioned in documents such as Japanese Patent Application Publication No. 11-251067 and Applied Physics Letters, 80, p. 139 (2002) by J. Huang et al. In one or more embodiments of the invention, these materials may be used in order to produce a light emitting element having higher efficiency.

The positive hole transport layer 3b can be formed by forming a thin film of any of the above mentioned positive hole transport materials by a well-known method such as vacuum deposition, spin coating, casting, printing including the inkjet method, or the LB (Langmuir Blodgett) method. The thickness of the positive hole transport layer 3b is not particularly limited, but it is generally within a range from about 5 nm to 5 μm, or within a range from 5 to 200 nm. The positive hole transport layer 3b may have a single-layer structure composed of one type or two or more types of the above mentioned materials.

The material of the positive hole transport layer 3b may be doped with impurities so that p property can increase. Examples thereof include those mentioned in documents such as Japanese Patent Application Publication Nos. 4-297076, 2000-196140 and 2001-102175 and J. Appl. Phys., 95, 5773 (2004).

Increase in p property of the positive hole transport layer 3b may enable production of an element which consumes lower electric power.

(Electron Transport Layer)

The electron transport layer 3d is composed of a material having a function to transport electrons, and, in a broad sense, the electron injection layer 3e and the positive hole block layer (not shown) are of the electron transport layer 3d. The electron transport layer 3d may have a single-layer structure or a multilayer structure of a plurality of layers.

The electron transport material (which doubles as a positive hole block material) which constitutes a layer portion adjacent to the luminescent layer 3c in the electron transport layer 3d having a single-layer structure or in the electron transport layer 3d having a multilayer structure should have a function to transport electrons injected from the cathode to the luminescent layer 3c. The material to be used can be suitably selected from well-known compounds. Examples thereof include a nitro-substituted fluorene derivative, a diphenylquinone derivative, a thiopyrandioxide derivative, carbodiimide, a fluorenylidenemethane derivative, anthraquinodimethane, an anthrone derivative and an oxadiazole derivative. A thiadiazole derivative formed in such a way that an oxygen atom of an oxadiazole ring of an oxadiazole derivative is substituted by a sulfur atom and a quinoxaline derivative having a quinoxaline ring which is well known as an electron withdrawing group can also be used as the material for the electron transport layer 3d. Further, high polymer materials in each of which any of the above mentioned materials is introduced into a high polymer chain or constitutes a main chain of a high polymer can also be used.

Still further, metal complexes of 8-quinolinol derivatives such as: tris(8-quinolinol)aluminum(abbr.:Alq₃), tris(5,7-dichloro-8-quinolinol)aluminum, tris(5,7-dibromo-8-quinolinol)aluminum, tris(2-methyl-8-quinolinol)aluminum, tris(5-methyl-8-quinolinol)aluminum and bis(8-quinolinol)zinc (abbr.: Znq); and metal complexes each formed in such a way that central metal of each of the above mentioned metal complexes is substituted by In, Mg, Cu, Ca, Sn, Ga or Pb can also be used as the material for the electron transport layer 3d.

Yet further, metal-free phthalocyanine and metal phthalocyanine and ones each formed in such a way that an end of each of these is substituted by an alkyl group, a sulfonic acid group or the like can also be used as the material for the electron transport layer 3d. Still further, the distyrylpyrazine derivative mentioned as an example of the material for the luminescent layer 3c can also be used as the material for the electron transport layer 3d. Yet further, inorganic semiconductors such as an n type-Si and an n type-SiC can also be used as the material for the electron transport layer 3d, as with the positive hole injection layer 3a and the positive hole transport layer 3b.

The electron transport layer 3d can be formed by forming a thin film of any of the above mentioned materials by a well-known method such as vacuum deposition, spin coating, casting, printing including the inkjet method, or the LB method. The thickness of the electron transport layer 3d is not particularly limited, but it is generally within a range from about 5 nm to 5 μm, or within a range from 5 to 200 nm. The electron transport layer 3d may have a single-layer structure composed of one type or two or more types of the above mentioned materials.

The electron transport layer 3d may be doped with impurities so that n property increases. Examples thereof include those mentioned in documents such as Japanese Patent Application Publication Nos. 4-297076, 10-270172, 2000-196140 and 2001-102175 and J. Appl. Phys., 95, 5773 (2004). The electron transport layer 3d may contain potassium, a potassium compound or the like. As the potassium compound, for example, potassium fluoride can be used. Increase in n property of the electron transport layer 3d enables production of an organic EL element which consumes lower electric power.

As the material (electron transportable compound) of the electron transport layer 3d, materials which are the same as the above mentioned materials for the intermediate layer 1a may be used. The same applies to the electron transport layer 3d which doubles as the electron injection layer 3e. Accordingly, materials which are the same as the above mentioned materials for the intermediate layer 1a may be used therefor.

(Block Layer)

The block layer(s) (the positive hole block layer and the electron block layer) is a layer provided as needed in addition to the above described constituent layers of the light-emitting functional layer 3. Examples thereof include positive hole block layers mentioned in documents such as Japanese Patent Application Publication Nos. 11-204258 and 11-204359 and p. 273 of “Yuki EL Soshi To Sono Kogyoka Saizensen (Organic EL Element and Front of Industrialization thereof) (Nov. 30, 1998, published by N.T.S Co., Ltd.)”.

The positive hole block layer has a function of the electron transport layer 3d in a broad sense. The positive hole block layer is composed of a positive hole block material having a function to transport electrons with a significantly low property to transport positive holes and can increase rebinding probability of electrons and positive holes by blocking positive holes while transporting electrons. The structure of the electron transport layer 3d described below can be used for the positive hole block layer as needed. The positive hole block layer may be disposed adjacent to the luminescent layer 3c.

On the other hand, the electron block layer has a function of the positive hole transport layer 3b in a broad sense. The electron block layer is composed of a material having a function to transport positive holes with a significantly low property to transport electrons and can increase rebinding probability of electrons and positive holes by blocking electrons while transporting positive holes. The structure of the positive hole transport layer 3b described below can be used for the electron block layer as needed. The thickness of the positive hole block layer used in one or more embodiments of the invention may be within a range from 3 to 100 nm or within a range from 5 to 30 nm.

[Auxiliary Electrode]

The auxiliary electrode 15 is provided in order to reduce resistance of the transparent electrode 1 and disposed in contact with the conductive layer 1b of the transparent electrode 1. As a material which forms the auxiliary electrode 15, a metal having low resistance may be used. Examples thereof include gold, platinum, silver, copper and aluminum. Because many of these metals have low optical transparency, the auxiliary electrode 15 is formed in the shape of a pattern shown in FIG. 2 within an area not to be affected by extraction of emission light h from a light extraction face 13a. Examples of a forming method of the auxiliary electrode 15 include vapor deposition, sputtering, printing, the inkjet method and the aerosol-jet method. The line width of the auxiliary electrode 15 may be 50 μm or less in view of an open area ratio of a region to extract light, and the thickness of the auxiliary electrode 15 may be 1 μm or more in view of conductivity.

[Sealing Member]

The sealing member 17 covers the organic EL element 100, and may be a plate-type (film-type) sealing member and fixed to the transparent substrate 13 side with the adhesive 19 or may be a sealing layer. The sealing member 17 is disposed in such a way as to cover at least the light-emitting functional layer 3 while exposing the terminal portions of the transparent electrode 1 and the counter electrode 5a of the organic EL element 100. The sealing member 17 may be provided with an electrode, and the terminal portions of the transparent electrode 1 and the counter electrode 5a of the organic EL element 100 may be conductive with this electrode.

Examples of the plate-type (film-type) sealing member 17 include a glass substrate, a polymer substrate and a metal substrate. These substrate materials may be made to be thinner films to use. Examples of the glass substrate include, in particular, soda-lime glass, glass containing barium and strontium, lead glass, aluminosilicate glass, borosilicate glass, barium borosilicate glass and quartz. Examples of the polymer substrate include polycarbonate, acrylic, polyethylene terephthalate, polyether sulfide and polysulfone. Examples of the metal substrate include ones composed of at least one type of metals or alloys selected from the group consisting of stainless steel, iron, copper, aluminum, magnesium, nickel, zinc, chromium, titanium, molybdenum, silicon, germanium and tantalum.

Among these, a polymer substrate or a metal substrate in the shape of a thin film can be used as the sealing member in order to make an organic EL element thin.

The film-type polymer substrate may have an oxygen permeability of 1×10⁻³ ml/(m²·24 h·atm) or less determined by a method in conformity with JIS K 7126-1987 and a water vapor permeability (at 25±0.5° C. and a relative humidity of 90±2% RH) of 1×10⁻³ g/(m²·24 h) or less determined by a method in conformity with JIS K 7129-1992.

The above mentioned substrate materials may be each processed to be in the shape of a concave plate to be used as the sealing member 17. In this case, the above mentioned substrate materials are processed by sandblasting, chemical etching or the like to be concave.

The adhesive 19 for fixing the plate-type sealing member 17 to the transparent substrate 13 side is used as a sealing agent for sealing the organic EL element 100 which is sandwiched between the sealing member 17 and the transparent substrate 13. Examples of the adhesive 19 include: photo-curable and thermosetting adhesives having a reactive vinyl group of an acrylic acid oligomer or a methacrylic acid oligomer; and moisture-curable adhesives such as 2-cyanoacrylate.

Examples of the adhesive 19 further include thermosetting and chemical curing (two-liquid-mixed) ones such as an epoxy-based one, still further include hot-melt ones such as polyamide, polyester and polyolefin and yet further include cationic curing ones such as a UV-curable epoxy resin adhesive.

The organic material of the organic EL element 100 is occasionally deteriorated by heat treatment. Therefore, the adhesive 19 may be one which is capable of adhesion and curing at from room temperature to 80° C. In addition, a desiccating agent may be dispersed into the adhesive 19.

The adhesive 19 may be applied to an adhesion portion of the sealing member 17 and the transparent substrate 13 with a commercial dispenser or may be printed in the same way as screen printing.

In the case where spaces are formed between the plate-type sealing member 17, the transparent substrate 13 and the adhesive 19, an inert gas may be injected, such as nitrogen or argon, and an inert liquid, such as fluorohydrocarbon or silicone oil, respectively, into the spaces. The spaces may be made to be vacuum, or a hygroscopic compound may be enclosed therein.

Examples of the hygroscopic compound include: metal oxide (sodium oxide, potassium oxide, calcium oxide, barium oxide, magnesium oxide, aluminum oxide, etc.); sulfate (sodium sulfate, calcium sulfate, magnesium sulfate, cobalt sulfate, etc.); metal halide (calcium chloride, magnesium chloride, cesium fluoride, tantalum fluoride, cerium bromide, magnesium bromide, barium iodide, magnesium iodide, etc.); and perchlorate (barium perchlorate, magnesium perchlorate, etc.). With respect to sulfate, metal halide and perchlorate, anhydrous ones may be used.

On the other hand, in the case where the sealing layer is used as the sealing member 17, the sealing layer is disposed on the transparent substrate 13 in such a way as to completely cover the light-emitting functional layer 3 of the organic EL element 100 and also expose the terminal portions of the transparent electrode 1 and the counter electrode 5a of the organic EL element 100.

The sealing layer is made with an inorganic material or an organic material, in particular a material impermeable to matters such as moisture and oxygen which cause deterioration of the light-emitting functional layer 3 of the organic EL element 100. Examples of the material to be used include inorganic materials such as silicon oxide, silicon dioxide and silicon nitride. In order to reduce fragility of the sealing layer, the sealing layer may have a multilayer structure of a layer composed of any of these inorganic materials and a layer composed of an organic material.

A forming method of these layers includes but is not particularly limited to: vacuum deposition, sputtering, reactive sputtering, molecular beam epitaxy, cluster ion beam, ion plating, plasma polymerization, atmospheric pressure plasma polymerization, plasma CVD, laser CVD, thermal CVD and coating.

[Protective Layer/Protective Plate]

Although not shown in the figure described above, a protective layer or protective plate may be disposed in such a way that the organic EL element 100 and the sealing member 17 are sandwiched between the protective layer or protective plate and the transparent substrate 13. The protective layer or protective plate is for mechanical protection of the organic EL element 100. In the case where the sealing member 17 is a sealing layer, the protective layer or protective plate may be provided because mechanical protection of the organic EL element 100 is not enough.

Examples used as the protective layer or protective plate include: a glass plate; a polymer plate and a polymer film thinner than that; a metal plate and a metal film thinner than that; a polymer material layer; and a metal material layer. A polymer film may be used because it is light and thin.

[Production Method of Organic EL Element]

A production method of the organic EL element 100, which is shown in FIG. 2, is described herein as an example in accordance with one or more embodiments of the invention.

First, an intermediate layer 1a containing a compound having a nitrogen atom(s) having an unshared electron pair uninvolved in aromaticity is formed on a transparent substrate 13 by a suitably selected method such as vapor deposition in such a way as to have a thickness of 1 μm or less, or 10 nm to 100 nm. Next, a conductive layer 1b composed of silver or an alloy containing silver as a main component is formed on the intermediate layer 1a by a suitably selected method such as vapor deposition in such a way as to have a thickness of 12 nm or less, or 4 nm to 9 nm. Thus, a transparent electrode 1 as an anode is produced.

Next, a positive hole injection layer 3a, a positive hole transport layer 3b, a luminescent layer 3c, an electron transport layer 3d and an electron injection layer 3e are formed on the transparent electrode 1 in the order named, thereby forming a light-emitting functional layer 3. These layers may be formed by spin coating, casting, the inkjet method, vapor deposition, printing or the like, but vacuum deposition or spin coating may be used because, for example, they tend to produce homogeneous layers and hardly generate pinholes. Further, different forming methods may be used to form the respective layers. In the case where vapor deposition is employed to form these layers, although vapor deposition conditions differ depending on, for example, the type of compounds to use, the conditions may be suitably selected from their respective ranges of: 50° C. to 450° C. for a boat heating temperature; 1×10⁻⁶ Pa to 1×10⁻² Pa for degree of vacuum; 0.01 nm/sec to 50 nm/sec for a deposition rate; −50° C. to 300° C. for a substrate temperature; and 0.1 μm to 5 μm for thickness.

After the light-emitting functional layer 3 is formed in the above described manner, a counter electrode 5a as a cathode is formed on the upper side thereof by a suitably selected forming method such as vapor deposition or sputtering. At the time, the counter electrode 5a is formed by patterning to be a shape of leading from the upper side of the light-emitting functional layer 3 to the periphery of the transparent substrate 13, the terminal portion of the counter electrode 5a being on the periphery of the transparent substrate 13, while being insulated from the transparent electrode 1 by the light-emitting functional layer 3. Thus, the organic EL element 100 is obtained. After that, a sealing member 17 is disposed in such a way as to cover at least the light-emitting functional layer 3 while exposing the terminal portions of the transparent electrode 1 and the counter electrode 5a of the organic EL element 100.

Thus, an organic EL element having a desired structure can be produced on a transparent substrate 13. In production of an organic EL element 100, layers may be produced from a light-emitting functional layer 3 to a counter electrode 5a altogether by one vacuum drawing. However, the transparent substrate 13 may be taken out from the vacuum atmosphere halfway and another forming method may be carried out. In this case, consideration should be given, for example, to doing works under a dry inert gas atmosphere.

In the case where a DC voltage is applied to the organic EL element 100 thus obtained, light emission can be observed by application of a voltage of 2 V to 40 V with the transparent electrode 1 as an anode being the positive polarity and the counter electrode 5a as a cathode being the negative polarity. Alternatively, an AC voltage may be applied thereto. The waveform of the AC voltage to be applied is arbitrary.

[Effects of Organic EL Element Shown as First Embodiment (FIG. 2)]

The organic EL element 100 having the structure described above and shown in FIG. 2 uses the transparent electrode 1 of one or more embodiments of the invention having both conductivity and optical transparency as an anode and is provided with the light-emitting functional layer 3 and the counter electrode 5a as a cathode on the upper side of the transparent electrode 1. Hence, the organic EL element 100 can emit light with high luminance by application of a sufficient voltage to between the transparent electrode 1 and the counter electrode 5a, can further increase the luminance by increase in extraction efficiency of emission light h from the transparent electrode 1 side and can extend emission lifetime by reduction in driving voltage for obtaining a desired luminance.

<<4. Second Embodiment of Organic EL Element>>

[Structure of Organic EL Element]

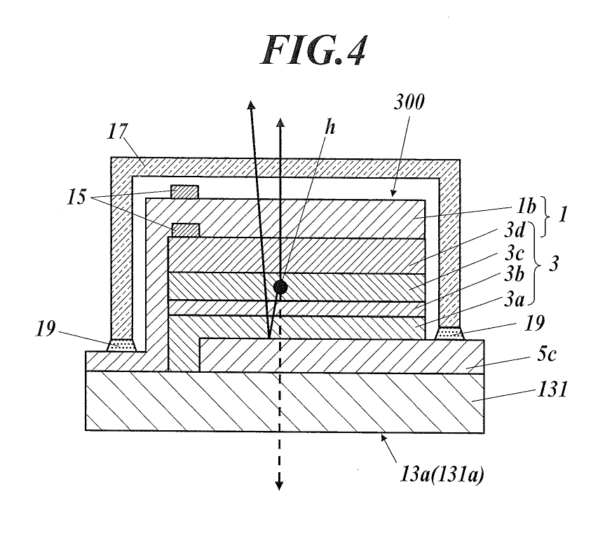

FIG. 3 is a cross sectional view showing the structure of an embodiment of an organic EL element using the above described transparent electrode as an example of an electronic device in accordance with one or more embodiments of the invention. Difference between an organic EL element 200 of the embodiment shown in FIG. 3 and the organic EL element 100 of the embodiment shown in FIG. 2 is that the organic EL element 200 uses a transparent electrode 1 as a cathode. Detailed description about components which are the same these embodiments is not repeated, and components specific to the organic EL element 200 of the embodiments described by FIG. 3 are described below.

The organic EL element 200 shown in FIG. 3 is disposed on a transparent substrate 13, and as with the previous embodiments, uses the above described transparent electrode 1 of one or more embodiments of the invention as a transparent electrode 1 disposed on the transparent substrate 13. Hence, the organic EL element 200 is configured to extract emission light h at least from the transparent substrate 13 side. Note that the transparent electrode 1 is used as a cathode (negative pole), and a counter electrode 5b is used as an anode (positive pole).

The layer structure of the organic EL element 200 thus configured is not limited to the below described example and hence may be a general layer structure, which is the same as in previous embodiments.

As an example of the layer structure for these embodiments, there is shown a layer structure of an electron injection layer 3e, an electron transport layer 3d, a luminescent layer 3c, a positive hole transport layer 3b and a positive hole injection layer 3a stacked on the upper side of the transparent electrode 1, which functions as a cathode, in the order named. It is essential to have, among them, at least the luminescent layer 3c composed of an organic material.

In addition to these layers, as described in previous embodiments, in the light-emitting functional layer 3, various functional layers can be incorporated as needed. In the structure described above, only the portion where the light-emitting functional layer 3 is sandwiched between the transparent electrode 1 and the counter electrode 5b is a luminescent region in the organic EL element 200, which is also the same as in previous embodiments.

Further, in the above described layer structure, in order to reduce resistance of the transparent electrode 1, an auxiliary electrode 15 may be disposed in contact with the conductive layer 1b of the transparent electrode 1, which is also the same as in previous embodiments.

The counter electrode 5b used as an anode is composed of, for example, a metal, an alloy, an organic conductive compound, an inorganic conductive compound or a mixture of any of these. Examples thereof include: metals, such as gold (Au); copper iodide (CuI); and oxide semiconductors, such as ITO, ZnO, TiO₂ and SnO₂.

The counter electrode 5b composed of the above mentioned material can be produced by forming a thin film of any of the above mentioned conductive materials by vapor deposition, sputtering or another method. The sheet resistance of the counter electrode 5b may be several hundred Ω/□ or less. The thickness is selected from normally a range of 5 nm to 5 μm, or a range of 5 nm to 200 nm.

In the case where the organic EL element 200 is configured to extract emission light h from the counter electrode 5b side too, as the material for the counter electrode 5b, a conductive material having excellent optical transparency to be used is selected from the above mentioned conductive materials.

The organic EL element 200 thus configured is, as with previous embodiments, sealed by a sealing member 17 in order to prevent deterioration of the light-emitting functional layer 3.

Detailed structures of the main layers constituting the above described organic EL element 200 except for the counter electrode 5b used as an anode and a production method of the organic EL element 200 are the same as those of the previous embodiments. Hence, detailed description thereof is omitted here.

[Effects of Organic EL Element (FIG. 3)]

The above described organic EL element 200 shown in FIG. 3 uses the transparent electrode 1 of one or more embodiments of the invention having both conductivity and optical transparency as a cathode and is provided with the light-emitting functional layer 3 and the counter electrode 5b as an anode on the upper side of the transparent electrode 1. Hence, as with the previous embodiments, the organic EL element 200 can emit light with high luminance by application of a sufficient voltage to between the transparent electrode 1 and the counter electrode 5a, can further increase the luminance by increase in extraction efficiency of emission light h from the transparent electrode 1 side and can extend emission lifetime by reduction in driving voltage for obtaining a predetermined luminance.

[Structure of Organic EL Element]

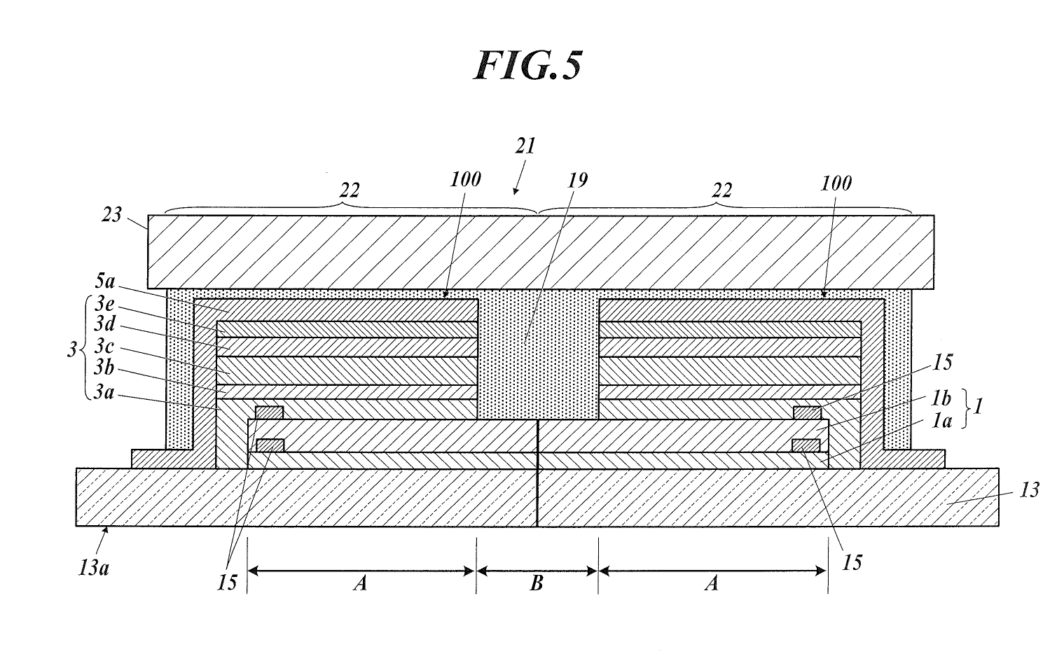

FIG. 4 is a cross sectional view showing the structure of a another embodiment of an organic EL element using the above described transparent electrode as an example of an electronic device of one or more embodiments of the invention. Difference between an organic EL element 300 of the this embodiment shown in FIG. 4 and the organic EL element 100 of the previous embodiments described with reference to FIG. 2 is that the organic EL element 300 is provided with a counter electrode 5c disposed on a substrate 131 and also provided with a light-emitting functional layer 3 and a transparent electrode 1 which are stacked on the upper side of the counter electrode 5c in the order named. Detailed description about components which are the same as those of the previous embodiments is not repeated, and components specific to the organic EL element 300 of this embodiment are described below.

The organic EL element 300 shown in FIG. 4 is disposed on the substrate 131, and the counter electrode 5c as an anode, the light-emitting functional layer 3 and the transparent electrode 1 as a cathode are stacked on the substrate 131 in the order named. As the transparent electrode 1, the above described transparent electrode 1 of one or more embodiments of the invention is used. Hence, the organic EL element 300 is configured to extract emission light h at least from the transparent electrode 1 side which is opposite to the substrate 131 side.

The layer structure of the organic EL element 300 thus configured is not limited to the below described example and hence may be a general layer structure, which is the same as previous embodiments. As an example thereof for this embodiment, there is shown in FIG. 4 a layer structure of a positive hole injection layer 3a, a positive hole transport layer 3b, a luminescent layer 3c and an electron transport layer 3d stacked on the upper side of the counter electrode 5c, which functions as an anode, in the order named. It is essential to have, among them, at least the luminescent layer 3c made with an organic material. The electron transport layer 3d doubles as an electron injection layer 3e and accordingly is provided as an electron transport layer 3d having an electron injection property.

A component specific to the organic EL element 300 of this embodiment is the electron transport layer 3d having the electron injection property being provided as an intermediate layer 1a of the transparent electrode 1. That is, in this embodiment, the transparent electrode 1 used as a cathode is composed of the intermediate layer 1a, which doubles as the electron transport layer 3d having the electron injection property, and a conductive layer 1b disposed on the upper side thereof.

This electron transport layer 3d is made with any of the above mentioned materials for the intermediate layer 1a of the transparent electrode 1.

In addition to these layers, as described in the previous embodiments, the light-emitting functional layer 3 can employ various functional layers as needed. However, there is no occasion where an electron injection layer or a positive hole block layer is disposed between the electron transport layer 3d, which doubles as the intermediate layer 1a of the transparent electrode 1, and the conductive layer 1b of the transparent electrode 1. In the structure described above, only the portion where the light-emitting functional layer 3 is sandwiched between the transparent electrode 1 and the counter electrode 5c is a luminescent region in the organic EL element 300, which is also the same as the previous embodiments.

Further, in the above described layer structure, in order to reduce resistance of the transparent electrode 1, an auxiliary electrode 15 may be disposed in contact with the conductive layer 1b of the transparent electrode 1, which is also the same as the previous embodiments.

The counter electrode 5c used as an anode is composed of, for example, a metal, an alloy, an organic conductive compound, an inorganic conductive compound or a mixture of any of these. Examples thereof include: metals, such as gold (Au); copper iodide (CuI); and oxide semiconductors, such as ITO, ZnO, TiO₂ and SnO₂.

The counter electrode 5c composed of the above mentioned material can be formed by forming a thin film of any of the above mentioned conductive materials by vapor deposition, sputtering or another method. The sheet resistance of the counter electrode 5c may be several hundred Ω/□ or less. The thickness is selected from normally a range of 5 nm to 5 μm, or a range of 5 nm to 200 nm.

In the case where the organic EL element 300 shown in FIG. 4 is configured to extract emission light h from the counter electrode 5c side too, as the material for the counter electrode 5c, a conductive material having excellent optical transparency to be used is selected from the above mentioned conductive materials. Further, in this case, as the substrate 131, one which is the same as the transparent substrate 13 described in the previous embodiments is used, and in this structure, a face of the substrate 131 facing outside is a light extraction face 131a.

[Effects of Organic EL Element (FIG. 4)]

The above described organic EL element 300 shown as this embodiment is provided with: as the intermediate layer 1a, the electron transport layer 3d having the electron injection property and constituting the top portion of the light-emitting functional layer 3; and the conductive layer 1b on the upper side thereof, thereby being provided with, as a cathode, the transparent electrode 1 composed of the intermediate layer 1a and the conductive layer 1b on the upper side thereof. Hence, as with the all the previous embodiments, the organic EL element 300 can emit light with high luminance by application of a sufficient voltage to between the transparent electrode 1 and the counter electrode 5c, can further increase the luminance by increase in extraction efficiency of emission light h from the transparent electrode 1 side and can extend emission lifetime by reduction in driving voltage for obtaining a predetermined luminance. In the case where the counter electrode 5c is composed of an electrode material having optical transparency, emission light h can be extracted from the counter electrode 5c side too.

In this embodiment, the intermediate layer 1a of the transparent electrode 1 doubles as the electron transport layer 3d having the electron injection property. However, embodiments of the invention are not limited to these illustrated components, and hence the intermediate layer 1a may double as an electron transport layer 3d not having the electron injection property or double not as an electron transport layer but as an electron injection layer. The intermediate layer 1a may be formed as a very thin film to the extent of not affecting the light emission function of an organic EL element. In this case, the intermediate layer 1a has neither the electron transport property nor the electron injection property.

In the case where the intermediate layer 1a of the transparent electrode 1 is formed as a very thin film to the extent of not affecting the light emission function of an organic EL element, a counter electrode on the substrate 131 and the transparent electrode 1 on the light-emitting functional layer 3 may be a cathode and an anode, respectively. In this case, the light-emitting functional layer 3 is composed of, for example, an electron injection layer 3e, an electron transport layer 3d, a luminescent layer 3c, a positive hole transport layer 3b and a positive hole injection layer 3a stacked on the counter electrode 5c (cathode) on the substrate 131 in the order named. Then, on the upper side thereof, the transparent electrode 1 having a multilayer structure of the very thin intermediate layer 1a and the conductive layer 1b is disposed as an anode.

<<6. Uses of Organic EL Elements>>

Each of the organic EL elements having the structures described above with reference to the figures is a surface emitting body as described above and hence can be used for various light sources. Examples thereof are not limited to but include illumination devices such as a household light and an interior light, backlights of a timepiece and a liquid crystal display device, a light of a signboard, a light source of a signal, a light source of an optical storage medium, a light source of an electrophotographic copier, a light source of a device for processing in optical communications and a light source of an optical sensor. The organic EL element can be effectively used for a backlight of a crystal liquid display device which is combined with a color filter or a light source of a light.

The organic EL element of one or more embodiments of the invention may be used for a sort of lamp, such as a light source of a light or a light source for exposure, or may be used for a projection device which projects images or a direct-view display device (display) of still images and moving images. In this case, with recent increase in size of illumination devices and displays, a luminescent face may be enlarged by two-dimensionally connecting, namely, tiling, luminescent panels provided with organic EL elements thereof.

A driving system thereof used for a display device for moving image playback may be a simple matrix (passive matrix) system or an active matrix system. Further, use of two or more types of organic EL elements of one or more embodiments of the invention having different luminescent colors enables production of a color or full-color display device.

Hereinafter, as examples of the uses, an illumination device and then an illumination device having a luminescent face enlarged by tiling are described.

<<7. Illumination Device—1>>

An illumination device of embodiments of the invention has the above described organic EL element of one or more embodiments of the invention.

The organic EL element used for an illumination device of embodiments of the invention may be designed as an organic EL element having anyone of the above described structures and a resonator structure. Although not limited thereto, the organic EL element configured to have a resonator structure is intended to be used for a light source of an optical storage medium, a light source of an electrophotographic copier, alight source of a device for processing in optical communications and a light source of an optical sensor. The organic EL element may be used for the above mentioned uses by being configured to carry out laser oscillation.

The materials used for the organic EL element of one or more embodiments of the invention are applicable to an organic EL element which emits substantially white light (also called a white organic EL element). For example, white light can be emitted by simultaneously emitting light of different luminescent colors with luminescent materials and mixing the luminescent colors. A combination of luminescent colors may be one containing three maximum emission wavelengths of three primary colors of red, green and blue or one containing two maximum emission wavelengths utilizing a relationship of complementary colors, such as blue and yellow or blue-green and orange.

A combination of luminescent materials to obtain a plurality of luminescent colors may be a combination of a plurality of phosphorescent or fluorescent materials or a combination of a phosphorescent or fluorescent material and a pigment material which emits light with light from the phosphorescent or fluorescent material as excitation light. In a white organic EL element, a plurality of luminescent dopants may be combined and mixed.

Unlike a structure to emit white light by apposing organic EL elements which emit light of different colors in an array form, this kind of white organic EL element itself emits white light. Hence, most of all the layers constituting the element do not require masks when formed. Consequently, for example, an electrode layer can be formed on the entire surface by vapor deposition, casting, spin coating, the inkjet method, printing or the like, and accordingly productivity increases.

The luminescent materials used for a luminescent layer(s) of this kind of white organic EL element are not particularly limited. For example, in the case of a backlight of a liquid crystal display element, materials therefor are suitably selected from the metal complexes of one or more embodiments of the invention and the well-known luminescent materials to match a wavelength range corresponding to CF (color filter) characteristics and combined, thereby emitting white light.

Use of the above described white organic EL element enables production of an illumination device which emits substantially white light.

<<8. Illumination Device—2>>

FIG. 5 is a cross sectional view showing the structure of an illumination device having a luminescent face enlarged by using a plurality of organic EL elements having any one of the above described structures. An illumination device 21 shown in FIG. 5 has a luminescent face enlarged, for example, by arranging (i.e. tiling), on a support substrate 23, a plurality of luminescent panels 22 provided with organic EL elements 100 on transparent substrates 13. The support substrate 23 may double as a sealing member. The luminescent panels 22 are tiled in such a way that the organic EL elements 100 are sandwiched between the support substrate 23 and the transparent substrates 13 of the luminescent panels 22. The space between the support substrate 23 and the transparent substrates 13 is filled with an adhesive 19, whereby the organic EL elements 100 may be sealed. The terminal portions of transparent electrodes 1 as anodes and counter electrodes 5a as cathodes are exposed on the peripheries of the luminescent panels 22. In the figure, only the exposed portions of the counter electrodes 5a are shown. FIG. 5 shows, as an example of a structure of the light-emitting functional layer 3 which constitutes the organic EL element 100, a structure of a positive hole injection layer 3a, a positive hole transport layer 3b, a luminescent layer 3c, an electron transport layer 3d and an electron injection layer 3e stacked on the transparent electrode 1 in the order named.

In the illumination device 21 having the structure shown in FIG. 5, the center of each of the luminescent panels 22 is a luminescent region A, and a non-luminescent region B is generated between the luminescent panels 22. Hence, a light extraction member for increasing a light extraction amount from the non-luminescent region B may be disposed in the non-luminescent region B of alight extraction face 13a. As the light extraction member, a light condensing sheet or a light diffusing sheet can be used.

### EXAMPLES

Hereinafter, one or more embodiments of the invention are detailed with Examples. However, the present invention is not limited thereto. Note that “%” used in Examples stands for “mass % (percent by mass)” unless otherwise specified.

### First Example

### Production of Transparent Electrodes 1-1 to 1-17

By the method described below, transparent electrodes of 1-1 to 1-17 were each produced in such a way that the area of a conductive region was 5 cm×5 cm. The transparent electrodes 1-1 to 1-4 were each produced as a transparent electrode having a single-layer structure, and the transparent electrodes 1-5 to 1-17 were each produced as a transparent electrode having a multilayer structure of an intermediate layer and a conductive layer.

[Production of Transparent Electrodes 1-1 to 1-4]

By the method described below, the transparent electrodes 1-1 to 1-4 each having a single-layer structure were produced as comparative examples. First, a base composed of transparent alkali-free glass was fixed to a base holder of a commercial vacuum deposition device, and the base holder was mounted in a vacuum tank of the vacuum deposition device. In addition, silver (Ag) was placed in a tungsten resistive heating board, and the heating board was mounted in the vacuum tank. Next, after the pressure of the vacuum tank was reduced to 4×10⁻⁴ Pa, the resistive heating board was electrically heated, and each of the transparent electrodes 1-1 to 1-4 having a single-layer structure composed of silver was formed on the base at a deposition rate of 0.1 nm/sec to 0.2 nm/sec. Values of the thickness of the transparent electrodes 1-1 to 1-4 were 5 nm, 8 nm, 10 nm and 15 nm, respectively, which are shown in TABLE 1 below.

[Production of Transparent Electrode 1-5]

On a base composed of transparent alkali-free glass, Alq₃ represented by the following structural formula was deposited by sputtering in advance to form an intermediate layer having a thickness of 25 nm, and on the upper side thereof, a conductive layer composed of silver (Ag) having a thickness of 8 nm was formed by vapor deposition. Thus, the transparent electrode 1-5 was obtained. The conductive layer composed silver (Ag) was formed by vapor deposition in the same way as that of each of the transparent electrodes 1-1 to 1-4.

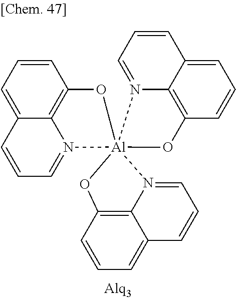

[Production of Transparent Electrode 1-6]

A base composed of transparent alkali-free glass was fixed to a base holder of the commercial vacuum deposition device, ET-4 represented by the following structural formula was placed in a tantalum resistive heating board, and the base holder and the heating board were mounted in a first vacuum tank of the vacuum deposition device. In addition, silver (Ag) was placed in a tungsten resistive heating board, and the heating board was mounted in a second vacuum tank.

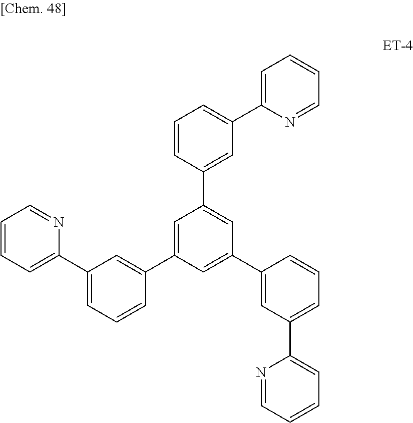 [SMILES: c1ccc(-c2cccc(-c3cc(-c4cccc(-c5ccccn5)c4)cc(-c4cccc(-c5ccccn5)c4)c3)c2)nc1]

In this state, first, after the pressure of the first vacuum tank was reduced to 4×10⁻⁴ Pa, the heating board having ET-4 therein was electrically heated, and an intermediate layer composed of ET-4 having a thickness of 25 nm was formed on the base at a deposition rate of 0.1 nm/sec to 0.2 nm/sec.

Next, the base on which the intermediate layer had been formed was transferred to the second vacuum tank, keeping its vacuum state. After the pressure of the second vacuum tank was reduced to 4×10⁻⁴ Pa, the heating board having silver therein was electrically heated, and a conductive layer composed of silver having a thickness of 8 nm was formed at a deposition rate of 0.1 nm/sec to 0.2 nm/sec. Thus, the transparent electrode 1-6 having a multilayer structure of the intermediate layer and the conductive layer on the upper side thereof was obtained.

[Production of Transparent Electrodes 1-7 to 1-14]

The transparent electrodes 1-7 to 1-14 were each produced in the same way as the transparent electrode 1-6, except that the material of the intermediate layer and the thickness of the conductive layer were changed to those shown in TABLE 1 below.

[Production of Transparent Electrodes 1-15 to 1-17]

The transparent electrodes 1-15 to 1-17 were each produced in the same way as the transparent electrode 1-6, except that the base was changed to PET (Polyethylene terephthalate) and the material of the intermediate layer was changed to those shown in TABLE 1 below.

<<Evaluation of Transparent Electrodes 1-1 to 1-17>>

With respect to each of the produced transparent electrodes 1-1 to 1-17, light transmittance and sheet resistance were measured by the methods described below.

[Light Transmittance Measurement]

With respect to each of the produced transparent electrodes 1-1 to 1-17, light transmittance was measured. The light transmittance was measured with a spectrophotometer (U-3300 manufactured by Hitachi, Ltd.) with a base which was the same as that of each of the samples as a baseline. The result is shown in TABLE 1 below.

[Sheet Resistance Measurement]

With respect to each of the produced transparent electrodes 1-1 to 1-17, sheet resistance was measured. The sheet resistance was measured with a resistivity meter (MCP-T610 manufactured by Mitsubishi Chemical Corporation) by the 4-terminal method, 4-pin probe method and constant-current method. The result is shown in TABLE 1 below.

TABLE 1

| | | | | | | EVALUATION RESULT | | |
|---|---|---|---|---|---|---|---|---|
| TRANS- | | STRUCTURE OF TRANSPARENT ELECTRODE | | | | LIGHT | | |
| PARENT | | INTERMEDIATE LAYER | | CONDUCTIVE LAYER | | TRANSMIT- | | |
| ELEC- | | | THICK- | | THICK- | TANCE | SHEET | |
| TRODE | | MATE- | NESS | MATE- | NESS | (550 nm) | RESISTANCE | |
| NO. | BASE | RIAL | (nm) | RIAL | (nm) | (%) | (Ω/□) | REMARK |
| 1-1 | ALKALI-FREE | — | — | Ag | 5 | 30 | UNMEASUR- | COMPARATIVE |
| | GLASS | | | | | | ABLE | EXAMPLE |
| 1-2 | ALKALI-FREE | — | — | Ag | 8 | 45 | 512 | COMPARATIVE |
| | GLASS | | | | | | | EXAMPLE |
| 1-3 | ALKALI-FREE | — | — | Ag | 10 | 38 | 41 | COMPARATIVE |
| | GLASS | | | | | | | EXAMPLE |
| 1-4 | ALKALI-FREE | — | — | Ag | 15 | 22 | 10 | COMPARATIVE |
| | GLASS | | | | | | | EXAMPLE |
| 1-5 | ALKALI-FREE | Alq₃ | 25 | Ag | 8 | 46 | 212 | COMPARATIVE |
| | GLASS | | | | | | | EXAMPLE |
| 1-6 | ALKALI-FREE | ET-4 | 25 | Ag | 8 | 48 | 120 | COMPARATIVE |
| | GLASS | | | | | | | EXAMPLE |
| 1-7 | ALKALI-FREE | ILLUSTRATED | 25 | Ag | 3 | 61 | 41 | PRESENT |
| | GLASS | COMPOUND (8) | | | | | | INVENTION |
| 1-8 | ALKALI-FREE | ILLUSTRATED | 25 | Ag | 5 | 67 | 12 | PRESENT |
| | GLASS | COMPOUND (8) | | | | | | INVENTION |
| 1-9 | ALKALI-FREE | ILLUSTRATED | 25 | Ag | 8 | 70 | 7 | PRESENT |
| | GLASS | COMPOUND (8) | | | | | | INVENTION |
| 1-10 | ALKALI-FREE | ILLUSTRATED | 25 | Ag | 10 | 62 | 8 | PRESENT |
| | GLASS | COMPOUND (8) | | | | | | INVENTION |
| 1-11 | ALKALI-FREE | ILLUSTRATED | 25 | Ag | 8 | 74 | 6 | PRESENT |
| | GLASS | COMPOUND (9) | | | | | | INVENTION |
| 1-12 | ALKALI-FREE | ILLUSTRATED | 25 | Ag | 8 | 78 | 5 | PRESENT |
| | GLASS | COMPOUND (10) | | | | | | INVENTION |
| 1-13 | ALKALI-FREE | ILLUSTRATED | 25 | Ag | 8 | 82 | 4 | PRESENT |
| | GLASS | COMPOUND (11) | | | | | | INVENTION |
| 1-14 | ALKALI-FREE | ILLUSTRATED | 25 | Ag | 8 | 85 | 3 | PRESENT |
| | GLASS | COMPOUND (12) | | | | | | INVENTION |
| 1-15 | PET | ILLUSTRATED | 25 | Ag | 8 | 79 | 5 | PRESENT |
| | | COMPOUND (10) | | | | | | INVENTION |
| 1-16 | PET | ILLUSTRATED | 25 | Ag | 8 | 80 | 4 | PRESENT |
| | | COMPOUND (11) | | | | | | INVENTION |
| 1-17 | PET | ILLUSTRATED | 25 | Ag | 8 | 82 | 3 | PRESENT |
| | | COMPOUND (12) | | | | | | INVENTION |

As it is obvious from TABLE 1, all the transparent electrodes 1-7 to 1-17 each having the structure of embodiments of the invention, in which a conductive layer composed of silver (Ag) as a main component was disposed on an intermediate layer made with an asymmetric compound having a nitrogen atom(s) having an unshared electron pair uninvolved in aromaticity, had a light transmittance of 61% or more and a sheet resistance of 41Ω/□ or less. On the other hand, all the transparent electrodes 1-1 to 1-6 each not having the structure of one or more embodiments of the invention had a light transmittance of less than 61%, and some of them had a sheet resistance of more than 41 Ω/□.

Thus, it was confirmed that the transparent electrodes each having the structure of one or more embodiments of the invention had high light transmittance and conductivity.

### Second Example

### Production of Luminescent Panels 1-1 to 1-17

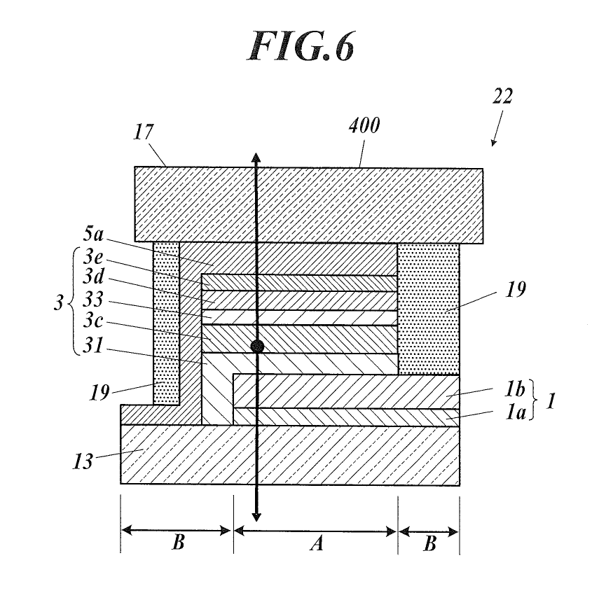

Top-and-bottom emission type organic EL elements respectively using, as anodes, the transparent electrodes 1-1 to 1-17 produced in First Example were produced. The procedure for producing them is described with reference to FIG. 6.

First, a transparent substrate 13 on which the transparent electrode 1 produced in First Example had been formed was fixed to a substrate holder of a commercial vacuum deposition device, and a vapor deposition mask was disposed in such a way as to face a formation face of the transparent electrode 1. Further, heating boards in the vacuum deposition device were filled with materials for respective layers constituting a light-emitting functional layer 3 at their respective amounts optimal to form the layers. The heating boards used were composed of a tungsten material for resistance heating.

Next, the pressure of a vapor deposition room of the vacuum deposition device was reduced to 4×10⁻⁴ Pa, and the heating boards having the respective materials therein were electrically heated successively so that the layers were formed as described below.

First, the heating board having therein α-NPD represented by the following structural formula as a positive hole transport/injection material was electrically heated, and a positive hole transport.injection layer 31 composed of α-NPD and functioning as both a positive hole injection layer and a positive hole transport layer was formed on the conductive layer 1b of the transparent electrode 1. At the time, the deposition rate was 0.1 nm/sec to 0.2 nm/sec, and the thickness was 20 nm.

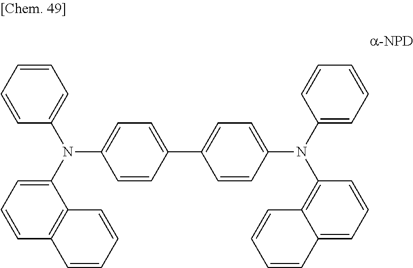 [SMILES: c1ccc(N(c2ccc(-c3ccc(N(c4ccccc4)c4cccc5ccccc45)cc3)cc2)c2cccc3ccccc23)cc1]

Next, the heating board having therein a host material H4 represented by the above structural formula and the heating board having therein a phosphorescent compound Ir-4 represented by the above structural formula were independently electrified, and a luminescent layer 32 composed of the host material H4 and the phosphorescent compound Ir-4 was formed on the positive hole transport.injection layer 31. At the time, the electrification of the heating boards was adjusted in such a way that the deposition rate of the host material H4: the deposition rate of the phosphorescent compound Ir-4=100:6. In addition, the thickness was 30 nm.

Next, the heating board having therein BAlq represented by the following structural formula as a positive hole block material was electrically heated, and a positive hole block layer 33 composed of BAlq was formed on the luminescent layer 32. At the time, the deposition rate was 0.1 nm/sec to 0.2 nm/sec, and the thickness was 10 nm.

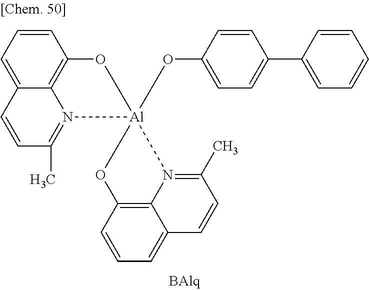

After that, the heating boards having therein ET-5 represented by the following structural formula and potassium fluoride, respectively, as electron transport materials were independently electrified, and an electron transport layer 34 composed of ET-5 and potassium fluoride was formed on the positive hole block layer 33. At the time, the electrification of the heating boards was adjusted in such a way that the deposition rate of ET-5:the deposition rate of potassium fluoride=75:25. In addition, the thickness was 30 nm.

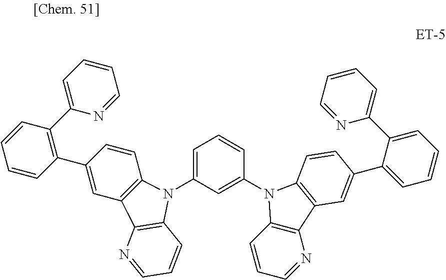 [SMILES: c1ccc(-c2ccccc2-c2ccc3c(c2)c2ncccc2n3-c2cccc(-n3c4ccc(-c5ccccc5-c5ccccn5)cc4c4ncccc43)c2)nc1]

Next, the heating board having therein potassium fluoride as an electron injection material was electrically heated, and an electron injection layer 35 composed of potassium fluoride was formed on the electron transport layer 34. At the time, the deposition rate was 0.01 nm/sec to 0.02 nm/sec, and the thickness was 1 nm.

After that, the transparent substrate 13 on which the layers up to the electron injection layer 35 had been formed was transferred from the vapor deposition room of the vacuum deposition device into a treatment room of a sputtering device, the treatment room in which an ITO target as a counter electrode material had been placed, keeping its vacuum state. Next, in the treatment room, an optically transparent counter electrode 5a composed of ITO having a thickness of 150 nm was formed at a deposition rate of 0.3 nm/sec to 0.5 nm/sec as a cathode. Thus, an organic EL element 400 was formed on the transparent substrate 13.

After that, the organic EL element 400 was covered with a sealing member 17 composed of a glass substrate having a thickness of 300 μm, and the space between the sealing member 17 and the transparent substrate 13 was filled with an adhesive 19 (a seal material) in such a way that the organic EL element 400 was enclosed. As the adhesive 19, an epoxy-based photo-curable adhesive (LUXTRAK LC0629B produced by Toagosei Co., Ltd.) was used. The adhesive 19, with which the space between the sealing member 17 and the transparent substrate 13 was filled, was irradiated with UV light from the glass substrate (sealing member 17) side, thereby being cured, so that the organic EL element 400 was sealed.

In forming the organic EL element 400, a vapor deposition mask was used for forming each layer so that the center having an area of 4.5 cm×4.5 cm of the transparent substrate 13 having an area of 5 cm×5 cm became a luminescent region A, and a non-luminescent region B having a width of 0.25 cm was provided all around the luminescent region A. Further, the transparent electrode 1 as an anode and the counter electrode 5a as a cathode were formed in shapes of leading to the periphery of the transparent substrate 13, their terminal portions being on the periphery of the transparent substrate 13, while being insulated from each other by the light-emitting functional layer 3 composed of the layers from the positive hole transport.injection layer 31 to the electron injection layer 35.

Thus, luminescent panels 1-1 to 1-17, in each of which the organic EL element 400 was disposed on the transparent substrate 13 and sealed by the sealing member 17 and with the adhesive 19, were obtained. In each of these luminescent panels, emission light h of colors generated in the luminescent layer 32 was extracted from both the transparent electrode 1 side, namely, the transparent substrate 13 side, and the counter electrode 5a side, namely, the sealing member 17 side.

<<Evaluation of Luminescent Panels 1-1 to 1-17>>

With respect to each of the produced luminescent panels 1-1 to 1-17, light transmittance and driving voltage were measured by the methods described below.

[Light Transmittance Measurement]

With respect to each of the produced luminescent panels 1-1 to 1-17, light transmittance (% at a wavelength of 550 nm) was measured. The light transmittance was measured with a spectrophotometer (U-3300 manufactured by Hitachi, Ltd.) with a base which was the same as that of each of the samples as a baseline. The result is shown in TABLE 2 below.

[Driving Voltage Measurement]

With respect to each of the produced luminescent panels 1-1 to 1-17, a driving voltage (V) was measured. In the driving voltage measurement, front luminance was measured on both the transparent electrode 1 side (i.e. transparent substrate 13 side) and the counter electrode 5a side (i.e. sealing member 17 side) of the luminescent panel, and a voltage of the time when the sum thereof was 1000 cd/m² was determined as the driving voltage. The luminance was measured with a spectroradiometer CS-1000 (manufactured by Konica Minolta Inc.). The smaller the obtained value of the driving voltage is, the more favorable result it means.

The result is shown in TABLE 2 below.

TABLE 2

| | | | | | | EVALUATION RESULT | | |
|---|---|---|---|---|---|---|---|---|
| | | STRUCTURE OF TRANSPARENT ELECTRODE | | | | LIGHT | | |
| | | INTERMEDIATE LAYER | | CONDUCTIVE LAYER | | TRANSMIT- | | |
| | | | THICK- | | THICK- | TANCE | DRIVING | |
| LUMINESCENT | | MATE- | NESS | MATE- | NESS | (550 nm) | VOLTAGE | |
| PANEL NO. | BASE | RIAL | (nm) | RIAL | (nm) | (%) | (V) | REMARK |
| 1-1 | ALKALI-FREE | — | — | Ag | 5 | 24 | NO LIGHT | COMPARATIVE |
| | GLASS | | | | | | EMITTED | EXAMPLE |
| 1-2 | ALKALI-FREE | — | — | Ag | 8 | 36 | NO LIGHT | COMPARATIVE |
| | GLASS | | | | | | EMITTED | EXAMPLE |
| 1-3 | ALKALI-FREE | — | — | Ag | 10 | 30 | 5.0 | COMPARATIVE |
| | GLASS | | | | | | | EXAMPLE |
| 1-4 | ALKALI-FREE | — | — | Ag | 15 | 18 | 3.5 | COMPARATIVE |
| | GLASS | | | | | | | EXAMPLE |
| 1-5 | ALKALI-FREE | Alq₃ | 25 | Ag | 8 | 43 | 4.4 | COMPARATIVE |
| | GLASS | | | | | | | EXAMPLE |
| 1-6 | ALKALI-FREE | ET-4 | 25 | Ag | 8 | 46 | 4.2 | COMPARATIVE |
| | GLASS | | | | | | | EXAMPLE |
| 1-7 | ALKALI-FREE | ILLUSTRATED | 25 | Ag | 3 | 56 | 4.1 | PRESENT |
| | GLASS | COMPOUND (8) | | | | | | INVENTION |
| 1-8 | ALKALI-FREE | ILLUSTRATED | 25 | Ag | 5 | 65 | 3.4 | PRESENT |
| | GLASS | COMPOUND (8) | | | | | | INVENTION |
| 1-9 | ALKALI-FREE | ILLUSTRATED | 25 | Ag | 8 | 66 | 3.3 | PRESENT |
| | GLASS | COMPOUND (8) | | | | | | INVENTION |
| 1-10 | ALKALI-FREE | ILLUSTRATED | 25 | Ag | 10 | 57 | 3.1 | PRESENT |
| | GLASS | COMPOUND (8) | | | | | | INVENTION |
| 1-11 | ALKALI-FREE | ILLUSTRATED | 25 | Ag | 8 | 69 | 3.1 | PRESENT |
| | GLASS | COMPOUND (9) | | | | | | INVENTION |
| 1-12 | ALKALI-FREE | ILLUSTRATED | 25 | Ag | 8 | 77 | 3.0 | PRESENT |
| | GLASS | COMPOUND (10) | | | | | | INVENTION |
| 1-13 | ALKALI-FREE | ILLUSTRATED | 25 | Ag | 8 | 79 | 3.0 | PRESENT |
| | GLASS | COMPOUND (11) | | | | | | INVENTION |
| 1-14 | ALKALI-FREE | ILLUSTRATED | 25 | Ag | 8 | 81 | 2.9 | PRESENT |
| | GLASS | COMPOUND (12) | | | | | | INVENTION |
| 1-15 | PET | ILLUSTRATED | 25 | Ag | 8 | 75 | 3.1 | PRESENT |
| | | COMPOUND (10) | | | | | | INVENTION |
| 1-16 | PET | ILLUSTRATED | 25 | Ag | 8 | 77 | 3.0 | PRESENT |
| | | COMPOUND (11) | | | | | | INVENTION |
| 1-17 | PET | ILLUSTRATED | 25 | Ag | 8 | 78 | 2.9 | PRESENT |
| | | COMPOUND (12) | | | | | | INVENTION |

As it is obvious from TABLE 2, all the luminescent panels 1-7 to 1-17 each using the transparent electrode 1 having the structure of one or more embodiments of the invention as an anode of the organic EL element had a light transmittance of 56% or more and a driving voltage of 4.1 V or less. On the other hand, all the luminescent panels 1-1 to 1-6 each using the transparent electrode not having the structure in accordance with embodiments of the invention as an anode of the organic EL element had a light transmittance of less than 56%, and some of them did not emit light even when a voltage was applied or emitted light with a driving voltage of more than 4.1 V.

Thus, it was confirmed that the organic EL elements each using the transparent electrode having the structure in accordance with embodiments of the invention were capable of light emission with high luminescence at a low driving voltage. Accordingly, it was confirmed that reduction in driving voltage for obtaining a predetermined luminescence and extension of emission life were expected.

### Third Example

### Production of Transparent Electrodes 2-1 to 2-90

By the methods described below, transparent electrodes 2-1 to 2-90 were each produced in such a way that the area of a conductive region was 5 cm×5 cm. The transparent electrodes 2-1 to 2-4 were each produced as a transparent electrode having a single-layer structure, the transparent electrodes 2-5 to 2-80 and the transparent electrodes 2-88 to 2-90 were each produced as a transparent electrode having a multilayer structure of an intermediate layer and a conductive layer, and the transparent electrodes 2-81 to 2-87 were each produced as a transparent electrode having a multilayer structure of three layers, an intermediate layer, a conductive layer and a second conductive layer.

[Production of Transparent Electrode 2-1]

By the method described below, the transparent electrode 2-1 having a single-layer structure was produced as a comparative example.

A base composed of transparent alkali-free glass was fixed to a base holder of a commercial vacuum deposition device, and the base holder was mounted in a vacuum tank of the vacuum deposition device. Meanwhile, a tungsten resistive heating board was filled with silver (Ag), and the heating board was mounted in the vacuum tank. Next, after the pressure of the vacuum tank was reduced to 4×10⁻⁴ Pa, the resistive heating board was electrically heated, and a conductive layer composed of silver having a thickness of 5 μm of a single layer was formed on the base by vapor deposition at a deposition rate of 0.1 nm/sec to 0.2 nm/sec. Thus, the transparent electrode 2-1 was produced.

[Production of Transparent Electrodes 2-2 to 2-4]

The transparent electrodes 2-2 to 2-4 were each produced in the same way as the transparent electrode 2-1, except that the thickness of the conductive layer was changed to 9 nm, 11 nm and 15 nm, respectively.

[Production of Transparent Electrode 2-5]

On a base composed of transparent alkali-free glass, Alq₃ was deposited by sputtering to form an intermediate layer having a thickness of 22 nm, and on the upper side thereof, a conductive layer composed of silver (Ag) having a thickness of 9 nm was formed by the same method (vacuum deposition) as that used for forming the conductive layer in producing the transparent electrode 2-1. Thus, the transparent electrode 2-5 was produced.

[Production of Transparent Electrode 2-6]

A base composed of transparent alkali-free glass was fixed to a base holder of the commercial vacuum deposition device, a tantalum resistive heating board was filled with ET-1 represented by the structure shown below, and the base holder and the heating board were mounted in a first vacuum tank of the vacuum deposition device. In addition, silver (Ag) was placed in a tungsten resistive heating board, and the heating board was mounted in a second vacuum tank.

Next, after the pressure of the first vacuum tank was reduced to 4×10⁻⁴ Pa, the heating board having ET-1 therein was electrically heated, and an intermediate layer composed of ET-1 having a thickness of 22 nm was formed on the base at a deposition rate of 0.1 nm/sec to 0.2 nm/sec.

Next, the base on which the intermediate layer had been formed was transferred to the second vacuum tank, keeping its vacuum state. After the pressure of the second vacuum tank was reduced to 4×10⁻⁴ Pa, the heating board having silver therein was electrically heated, and a conductive layer composed of silver having a thickness of 9 nm was formed at a deposition rate of 0.1 nm/sec to 0.2 nm/sec. Thus, the transparent electrode 2-6 having a multilayer structure of the intermediate layer and the conductive layer, which was composed of silver, on the upper side thereof was obtained.

[Production of Transparent Electrodes 2-7 and 2-8]

The transparent electrodes 2-7 and 2-8 were each produced in the same way as the transparent electrode 2-6, except that ET-1 used for forming the intermediate layer was changed to ET-2 and ET-3, respectively.

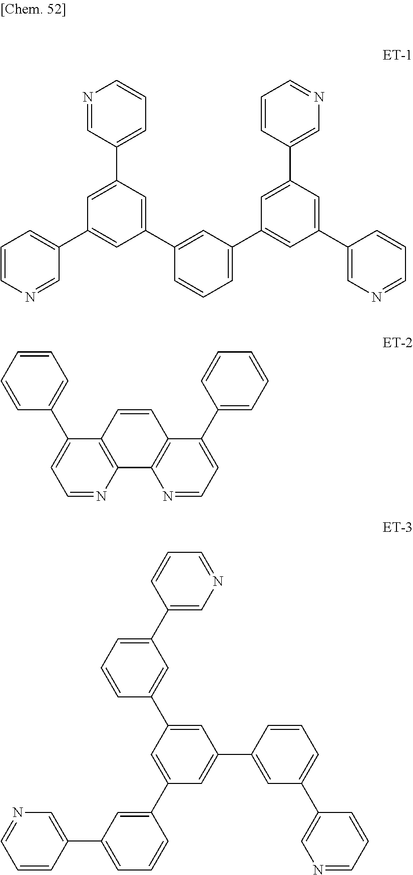 [SMILES: c1cncc(-c2cc(-c3cccnc3)cc(-c3cccc(-c4cc(-c5cccnc5)cc(-c5cccnc5)c4)c3)c2)c1 ; c1ccc(-c2ccnc3c2ccc2c(-c4ccccc4)ccnc23)cc1 ; c1cncc(-c2cccc(-c3cc(-c4cccc(-c5cccnc5)c4)cc(-c4cccc(-c5cccnc5)c4)c3)c2)c1]

[Production of Transparent Electrodes 2-9 to 2-11]

The transparent electrodes 2-9 to 2-11 were each produced in the same way as the transparent electrode 2-6, except that ET-1 used for forming the intermediate layer was changed to Compound 1, Compound 2 and Compound 3, respectively.

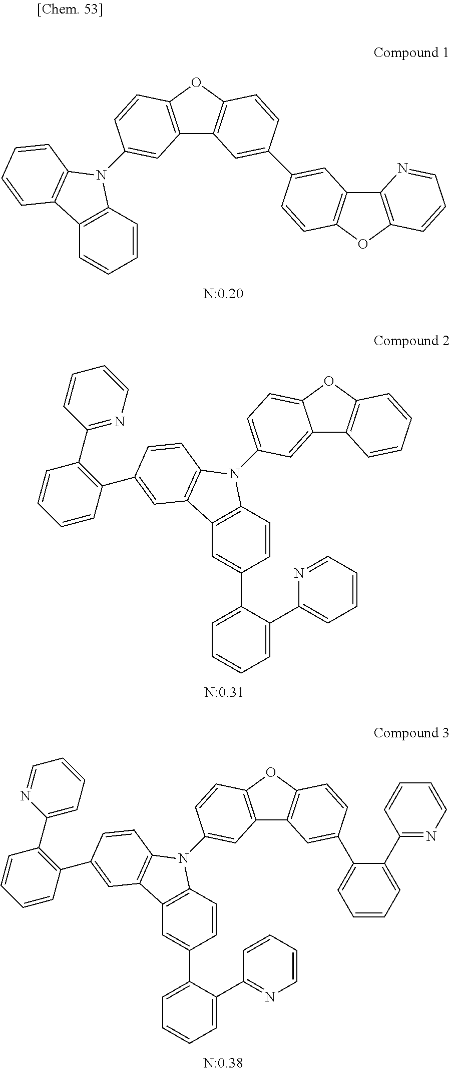 [SMILES: c1cnc2c(c1)oc1ccc(-c3ccc4oc5ccc(-n6c7ccccc7c7ccccc76)cc5c4c3)cc12 ; c1ccc(-c2ccccc2-c2ccc3c(c2)c2cc(-c4ccccc4-c4ccccn4)ccc2n3-c2ccc3oc4ccccc4c3c2)nc1 ; c1ccc(-c2ccccc2-c2ccc3oc4ccc(-n5c6ccc(-c7ccccc7-c7ccccn7)cc6c6cc(-c7ccccc7-c7ccccn7)ccc65)cc4c3c2)nc1]

[Production of Transparent Electrode 2-12]

A base composed of transparent alkali-free glass was fixed to a base holder of the commercial vacuum deposition device, a tantalum resistive heating board was filled with the illustrated compound (1) of the present invention, and the base holder and the heating board were mounted in the first vacuum tank of the vacuum deposition device. In addition, silver (Ag) was placed in a tungsten resistive heating board, and the heating board was mounted in the second vacuum tank.

Next, after the pressure of the first vacuum tank was reduced to 4×10⁻⁴ Pa, the heating board having the illustrated compound (1) therein was electrically heated, and an intermediate layer 1a composed of the illustrated compound (1) having a thickness of 22 nm was formed on the base at a deposition rate of 0.1 nm/sec to 0.2 nm/sec.

Next, the base on which the intermediate layer 1a had been formed was transferred to the second vacuum tank, keeping its vacuum state. After the pressure of the second vacuum tank was reduced to 4×10⁻⁴ Pa, the heating board having silver therein was electrically heated, and a conductive layer 1b composed of silver having a thickness of 3.5 nm was formed at a deposition rate of 0.1 nm/sec to 0.2 nm/sec. Thus, the transparent electrode 2-12 having a multilayer structure of the intermediate layer 1a and the conductive layer 1b, which was composed of silver, on the upper side thereof was obtained.

[Production of Transparent Electrodes 2-13 to 2-16]

The transparent electrodes 2-13 to 2-16 were each produced in the same way as the transparent electrode 2-12, except that the silver thickness of the conductive layer 1b was changed to 5 nm, 9 nm, 12 nm and 20 nm, respectively.

[Production of Transparent Electrodes 2-17 to 2-80]

The transparent electrodes 2-17 to 2-80 were each produced in the same way as the transparent electrode 2-14, except that, as the compound having a nitrogen atom(s) having an unshared electron pair uninvolved in aromaticity used for forming the intermediate layer 1a, instead of the illustrated compound (1), the illustrated compounds shown in TABLES 3 to 6 were used, respectively.

[Production of Transparent Electrodes 2-81 to 2-87]

The transparent electrodes 2-81 to 2-87 were produced in the same way as the transparent electrodes 2-14, 2-17, 2-18, 2-19, 2-20, 2-21 and 2-22, respectively, except that, after the intermediate layer 1a and the conductive layer 1b were formed on the base, a second intermediate layer 1c was formed on the conductive layer 1b by the same method as the forming method of the intermediate layer 1a. Thus, the transparent electrodes 2-81 to 2-87 each having the structure shown in FIG. 1(b) in which the conductive layer 1b was sandwiched between the two intermediate layers 1a and 1c were produced.

[Production of Transparent Electrodes 2-88 to 2-90]

The transparent electrodes 2-88, 2-89 and 2-90 were produced in the same way as the transparent electrodes 2-14, 2-21 and 2-22, respectively, except that the base was changed from alkali-free glass to a PET (polyethylene terephthalate) film.

<<Evaluation of Transparent Electrodes 2-1 to 2-90>>

With respect to each of the produced transparent electrodes 2-1 to 2-90, light transmittance, sheet resistance and durability were measured by the methods described below.

[Light Transmittance Measurement]

With respect to each of the produced transparent electrodes, light transmittance (%) at a wavelength of 550 nm was measured with a spectrophotometer (U-3300 manufactured by Hitachi, Ltd.) with the base which was used for producing each of the transparent electrodes as a reference.

[Sheet Resistance Measurement]

With respect to each of the produced transparent electrodes, sheet resistance (Ω/□) was measured with a resistivity meter (MCP-T610 manufactured by Mitsubishi Chemical Corporation) by the 4-terminal method, 4-pin probe method and constant-current method.

[Evaluation of Durability: Variation Width of Transmittance under Constant Current]

With respect to each of the produced transparent electrodes, a variation percentage of transmittance was measured as follows; a current of 125 mA/cm² was applied thereto at 30° C. for 200 hours, and a variation percentage of the after-200-hours transmittance to the initial transmittance was determined by the following equation.

Variation Percentage of Transmittance=(Initial Transmittance−After-200-Hours Transmittance)/Initial Transmittance×100

The variation percentage of transmittance of each transparent electrode is shown as a relative value with the variation percentage thereof of the transparent electrode 2-8 as 100.

The obtained result is shown in TABLES 3 to 6.

TABLE 3

| | STRUCTURE OF TRANSPARENT ELECTRODE | | | | | | | | | |
|---|---|---|---|---|---|---|---|---|---|---|
| | (STRUCTURE SHOWN IN FIG. 1(a) OR FIG. 1(b)) | | | | | | | | | |
| TRANS- | | INTERMEDIATE LAYER | | | | CONDUCTIVE LAYER | | SECOND INTERMEDIATE | | |
| PARENT | | 1a | | | | 1b | | LAYER 1c | | |
| ELEC- | | | | | THICK- | | THICK- | | | THICK- |
| TRODE | BASE | COMPOUND | | | NESS | MATE- | NESS | MATE- | | NESS |
| NO. | TYPE | TYPE | STRUCTURE | *2 | (nm) | RIAL | (nm) | RIAL | *2 | (nm) |
| 2-1 | *1 | — | — | — | — | Ag | 5 | — | — | — |
| 2-2 | *1 | — | — | — | — | Ag | 9 | — | — | — |
| 2-3 | *1 | — | — | — | — | Ag | 11 | — | — | — |
| 2-4 | *1 | — | — | — | — | Ag | 15 | — | — | — |
| 2-5 | *1 | Alq₃ | SYMMETRIC | 0 | 22 | Ag | 9 | — | — | — |
| 2-6 | *1 | ET-1 | SYMMETRIC | 0.74 | 22 | Ag | 9 | — | — | — |
| 2-7 | *1 | ET-2 | SYMMETRIC | 0.60 | 22 | Ag | 9 | — | — | — |
| 2-8 | *1 | ET-3 | SYMMETRIC | 0.56 | 22 | Ag | 9 | — | — | — |
| 2-9 | *1 | COMPOUND 1 | ASYMMETRIC | 0.20 | 22 | Ag | 9 | — | — | — |
| 2-10 | *1 | COMPOUND 2 | ASYMMETRIC | 0.31 | 22 | Ag | 9 | — | — | — |
| 2-11 | *1 | COMPOUND 3 | ASYMMETRIC | 0.38 | 22 | Ag | 9 | — | — | — |
| 2-12 | *1 | ILLUSTRATED | ASYMMETRIC | 0.52 | 22 | Ag | 3.5 | — | — | — |
| | | COMPOUND (1) | | | | | | | | |
| 2-13 | *1 | ILLUSTRATED | ASYMMETRIC | 0.52 | 22 | Ag | 5 | — | — | — |
| | | COMPOUND (1) | | | | | | | | |
| 2-14 | *1 | ILLUSTRATED | ASYMMETRIC | 0.52 | 22 | Ag | 9 | — | — | — |
| | | COMPOUND (1) | | | | | | | | |
| 2-15 | *1 | ILLUSTRATED | ASYMMETRIC | 0.52 | 22 | Ag | 12 | — | — | — |
| | | COMPOUND (1) | | | | | | | | |
| 2-16 | *1 | ILLUSTRATED | ASYMMETRIC | 0.52 | 22 | Ag | 20 | — | — | — |
| | | COMPOUND (1) | | | | | | | | |
| 2-17 | *1 | ILLUSTRATED | ASYMMETRIC | 0.51 | 22 | Ag | 9 | — | — | — |
| | | COMPOUND (2) | | | | | | | | |
| 2-18 | *1 | ILLUSTRATED | ASYMMETRIC | 0.54 | 22 | Ag | 9 | — | — | — |
| | | COMPOUND (3) | | | | | | | | |
| 2-19 | *1 | ILLUSTRATED | ASYMMETRIC | 0.46 | 22 | Ag | 9 | — | — | — |
| | | COMPOUND (4) | | | | | | | | |
| 2-20 | *1 | ILLUSTRATED | ASYMMETRIC | 0.56 | 22 | Ag | 9 | — | — | — |
| | | COMPOUND (5) | | | | | | | | |
| 2-21 | *1 | ILLUSTRATED | ASYMMETRIC | 0.82 | 22 | Ag | 9 | — | — | — |
| | | COMPOUND (6) | | | | | | | | |
| 2-22 | *1 | ILLUSTRATED | ASYMMETRIC | 1.04 | 22 | Ag | 9 | — | — | — |
| | | COMPOUND (7) | | | | | | | | |
| 2-23 | *1 | ILLUSTRATED | ASYMMETRIC | 0.90 | 22 | Ag | 9 | — | — | — |
| | | COMPOUND (8) | | | | | | | | |
| 2-24 | *1 | ILLUSTRATED | ASYMMETRIC | 0.73 | 22 | Ag | 9 | — | — | — |
| | | COMPOUND (9) | | | | | | | | |
| 2-25 | *1 | ILLUSTRATED | ASYMMETRIC | 0.56 | 22 | Ag | 9 | — | — | — |
| | | COMPOUND (10) | | | | | | | | |

| | EVALUATION RESULT | | | |
|---|---|---|---|---|
| TRANS- | LIGHT | | | |
| PARENT | TRANSMIT- | | DURABILITY | |
| ELEC- | TANCE | SHEET | VARIATION | |
| TRODE | (550 nm) | RESISTANCE | PERCENTAGE OF | |
| NO. | (%) | (Ω/□) | TRANSMITTANCE | REMARK |
| 2-1 | 30 | UNMEASURABLE | 183 | COMPARATIVE |
| | | | | EXAMPLE |
| 2-2 | 43 | 512 | 197 | COMPARATIVE |
| | | | | EXAMPLE |
| 2-3 | 36 | 40 | 168 | COMPARATIVE |
| | | | | EXAMPLE |
| 2-4 | 22 | 10 | 140 | COMPARATIVE |
| | | | | EXAMPLE |
| 2-5 | 44 | 219 | 131 | COMPARATIVE |
| | | | | EXAMPLE |
| 2-6 | 47 | 48 | 125 | COMPARATIVE |
| | | | | EXAMPLE |
| 2-7 | 46 | 38 | 120 | COMPARATIVE |
| | | | | EXAMPLE |
| 2-8 | 46 | 26 | 100 | COMPARATIVE |
| | | | | EXAMPLE |
| 2-9 | 57 | 14 | 90 | PRESENT |
| | | | | INVENTION |
| 2-10 | 55 | 13 | 84 | PRESENT |
| | | | | INVENTION |
| 2-11 | 59 | 12 | 78 | PRESENT |
| | | | | INVENTION |
| 2-12 | 71 | 9.8 | 72 | PRESENT |
| | | | | INVENTION |
| 2-13 | 68 | 9.5 | 69 | PRESENT |
| | | | | INVENTION |
| 2-14 | 72 | 7.1 | 64 | PRESENT |
| | | | | INVENTION |
| 2-15 | 65 | 7.5 | 66 | PRESENT |
| | | | | INVENTION |
| 2-16 | 61 | 7.5 | 70 | PRESENT |
| | | | | INVENTION |
| 2-17 | 75 | 7.1 | 51 | PRESENT |
| | | | | INVENTION |
| 2-18 | 77 | 6.8 | 44 | PRESENT |
| | | | | INVENTION |
| 2-19 | 79 | 6.6 | 34 | PRESENT |
| | | | | INVENTION |
| 2-20 | 81 | 5.6 | 32 | PRESENT |
| | | | | INVENTION |
| 2-21 | 83 | 4.1 | 21 | PRESENT |
| | | | | INVENTION |
| 2-22 | 84 | 3.3 | 11 | PRESENT |
| | | | | INVENTION |
| 2-23 | 83 | 4.1 | 21 | PRESENT |
| | | | | INVENTION |
| 2-24 | 80 | 4.3 | 24 | PRESENT |
| | | | | INVENTION |
| 2-25 | 76 | 6.5 | 41 | PRESENT |
| | | | | INVENTION |

*1: ALKALI-FREE GLASS
*2: NITROGEN ATOM CONTENT PERCENTAGE [(THE NUMBER OF NITROGEN ATOM/MOLECULAR WEIGHT) × 100]

TABLE 4

| | STRUCTURE OF TRANSPARENT ELECTRODE | | | | | | | | | |
|---|---|---|---|---|---|---|---|---|---|---|
| | (STRUCTURE SHOWN IN FIG. 1(a) OR FIG. 1(b)) | | | | | | | | | |
| TRANS- | | INTERMEDIATE LAYER | | | | CONDUCTIVE LAYER | | SECOND INTERMEDIATE | | |
| PARENT | | 1a | | | | 1b | | LAYER 1c | | |
| ELEC- | | | | | THICK- | | THICK- | | | THICK- |
| TRODE | BASE | COMPOUND | | | NESS | MATE- | NESS | MATE- | | NESS |
| NO. | TYPE | TYPE | STRUCTURE | *2 | (nm) | RIAL | (nm) | RIAL | *2 | (nm) |
| 2-26 | *1 | ILLUSTRATED | ASYMMETRIC | 0.58 | 22 | Ag | 9 | — | — | — |
| | | COMPOUND (11) | | | | | | | | |
| 2-27 | *1 | ILLUSTRATED | ASYMMETRIC | 0.86 | 22 | Ag | 9 | — | — | — |
| | | COMPOUND (12) | | | | | | | | |
| 2-28 | *1 | ILLUSTRATED | ASYMMETRIC | 0.56 | 22 | Ag | 9 | — | — | — |
| | | COMPOUND (13) | | | | | | | | |
| 2-29 | *1 | ILLUSTRATED | ASYMMETRIC | 0.56 | 22 | Ag | 9 | — | — | — |
| | | COMPOUND (14) | | | | | | | | |
| 2-30 | *1 | ILLUSTRATED | ASYMMETRIC | 0.53 | 22 | Ag | 9 | — | — | — |
| | | COMPOUND (15) | | | | | | | | |
| 2-31 | *1 | ILLUSTRATED | ASYMMETRIC | 0.71 | 22 | Ag | 9 | — | — | — |
| | | COMPOUND (16) | | | | | | | | |
| 2-32 | *1 | ILLUSTRATED | ASYMMETRIC | 0.73 | 22 | Ag | 9 | — | — | — |
| | | COMPOUND (17) | | | | | | | | |
| 2-33 | *1 | ILLUSTRATED | ASYMMETRIC | 1.21 | 22 | Ag | 9 | — | — | — |
| | | COMPOUND (18) | | | | | | | | |
| 2-34 | *1 | ILLUSTRATED | ASYMMETRIC | 0.58 | 22 | Ag | 9 | — | — | — |
| | | COMPOUND (19) | | | | | | | | |
| 2-35 | *1 | ILLUSTRATED | ASYMMETRIC | 0.80 | 22 | Ag | 9 | — | — | — |
| | | COMPOUND (20) | | | | | | | | |
| 2-36 | *1 | ILLUSTRATED | ASYMMETRIC | 0.52 | 22 | Ag | 9 | — | — | — |
| | | COMPOUND (21) | | | | | | | | |
| 2-37 | *1 | ILLUSTRATED | ASYMMETRIC | 0.69 | 22 | Ag | 9 | — | — | — |
| | | COMPOUND (22) | | | | | | | | |
| 2-38 | *1 | ILLUSTRATED | ASYMMETRIC | 0.45 | 22 | Ag | 9 | — | — | — |
| | | COMPOUND (23) | | | | | | | | |
| 2-39 | *1 | ILLUSTRATED | ASYMMETRIC | 0.60 | 22 | Ag | 9 | — | — | — |
| | | COMPOUND (24) | | | | | | | | |
| 2-40 | *1 | ILLUSTRATED | ASYMMETRIC | 0.53 | 22 | Ag | 9 | — | — | — |
| | | COMPOUND (25) | | | | | | | | |
| 2-41 | *1 | ILLUSTRATED | ASYMMETRIC | 0.88 | 22 | Ag | 9 | — | — | — |
| | | COMPOUND (26) | | | | | | | | |
| 2-42 | *1 | ILLUSTRATED | ASYMMETRIC | 0.45 | 22 | Ag | 9 | — | — | — |
| | | COMPOUND (27) | | | | | | | | |
| 2-43 | *1 | ILLUSTRATED | ASYMMETRIC | 0.61 | 22 | Ag | 9 | — | — | — |
| | | COMPOUND (28) | | | | | | | | |
| 2-44 | *1 | ILLUSTRATED | ASYMMETRIC | 0.49 | 22 | Ag | 9 | — | — | — |
| | | COMPOUND (29) | | | | | | | | |
| 2-45 | *1 | ILLUSTRATED | ASYMMETRIC | 0.73 | 22 | Ag | 9 | — | — | — |
| | | COMPOUND (30) | | | | | | | | |
| 2-46 | *1 | ILLUSTRATED | ASYMMETRIC | 0.60 | 22 | Ag | 9 | — | — | — |
| | | COMPOUND (31) | | | | | | | | |
| 2-47 | *1 | ILLUSTRATED | ASYMMETRIC | 0.99 | 22 | Ag | 9 | — | — | — |
| | | COMPOUND (32) | | | | | | | | |
| 2-48 | *1 | ILLUSTRATED | ASYMMETRIC | 0.80 | 22 | Ag | 9 | — | — | — |
| | | COMPOUND (33) | | | | | | | | |
| 2-49 | *1 | ILLUSTRATED | ASYMMETRIC | 0.50 | 22 | Ag | 9 | — | — | — |
| | | COMPOUND (34) | | | | | | | | |
| 2-50 | *1 | ILLUSTRATED | ASYMMETRIC | 0.48 | 22 | Ag | 9 | — | — | — |
| | | COMPOUND (35) | | | | | | | | |

| | EVALUATION RESULT | | | |
|---|---|---|---|---|
| TRANS- | LIGHT | | | |
| PARENT | TRANSMIT- | | DURABILITY | |
| ELEC- | TANCE | SHEET | VARIATION | |
| TRODE | (550 nm) | RESISTANCE | PERCENTAGE OF | |
| NO. | (%) | (Ω/□) | TRANSMITTANCE | REMARK |
| 2-26 | 79 | 6.7 | 42 | PRESENT |
| | | | | INVENTION |
| 2-27 | 85 | 4.6 | 22 | PRESENT |
| | | | | INVENTION |
| 2-28 | 76 | 6.9 | 41 | PRESENT |
| | | | | INVENTION |
| 2-29 | 75 | 6.9 | 43 | PRESENT |
| | | | | INVENTION |
| 2-30 | 73 | 6.9 | 58 | PRESENT |
| | | | | INVENTION |
| 2-31 | 79 | 4.9 | 29 | PRESENT |
| | | | | INVENTION |
| 2-32 | 76 | 4.3 | 27 | PRESENT |
| | | | | INVENTION |
| 2-33 | 69 | 7.1 | 53 | PRESENT |
| | | | | INVENTION |
| 2-34 | 79 | 6.8 | 41 | PRESENT |
| | | | | INVENTION |
| 2-35 | 80 | 4.2 | 26 | PRESENT |
| | | | | INVENTION |
| 2-36 | 73 | 7.0 | 62 | PRESENT |
| | | | | INVENTION |
| 2-37 | 81 | 6.4 | 39 | PRESENT |
| | | | | INVENTION |
| 2-38 | 71 | 7.3 | 51 | PRESENT |
| | | | | INVENTION |
| 2-39 | 76 | 6.9 | 45 | PRESENT |
| | | | | INVENTION |
| 2-40 | 76 | 6.9 | 45 | PRESENT |
| | | | | INVENTION |
| 2-41 | 82 | 3.3 | 15 | PRESENT |
| | | | | INVENTION |
| 2-42 | 79 | 6.7 | 36 | PRESENT |
| | | | | INVENTION |
| 2-43 | 82 | 5.6 | 31 | PRESENT |
| | | | | INVENTION |
| 2-44 | 73 | 7.0 | 58 | PRESENT |
| | | | | INVENTION |
| 2-45 | 79 | 3.7 | 18 | PRESENT |
| | | | | INVENTION |
| 2-46 | 75 | 6.9 | 44 | PRESENT |
| | | | | INVENTION |
| 2-47 | 81 | 3.5 | 17 | PRESENT |
| | | | | INVENTION |
| 2-48 | 83 | 3.3 | 15 | PRESENT |
| | | | | INVENTION |
| 2-49 | 74 | 7.2 | 65 | PRESENT |
| | | | | INVENTION |
| 2-50 | 73 | 7.0 | 55 | PRESENT |
| | | | | INVENTION |

*1: ALKALI-FREE GLASS
*2: NITROGEN ATOM CONTENT PERCENTAGE [(THE NUMBER OF NITROGEN ATOMS/MOLECULAR WEIGHT) × 100)

TABLE 5

| | STRUCTURE OF TRANSPARENT ELECTRODE | | | | | | | | | |
|---|---|---|---|---|---|---|---|---|---|---|
| | (STRUCTURE SHOWN IN FIG. 1(a) OR FIG. 1(b)) | | | | | | | | | |
| TRANS- | | INTERMEDIATE LAYER | | | | CONDUCTIVE LAYER | | SECOND INTERMEDIATE | | |
| PARENT | | 1a | | | | 1b | | LAYER 1c | | |
| ELEC- | | | | | THICK- | | THICK- | | | THICK- |
| TRODE | BASE | COMPOUND | | | NESS | MATE- | NESS | MATE- | | NESS |
| NO. | TYPE | TYPE | STRUCTURE | *2 | (nm) | RIAL | (nm) | RIAL | *2 | (nm) |
| 2-51 | *1 | ILLUSTRATED | ASYMMETRIC | 0.46 | 22 | Ag | 9 | — | — | — |
| | | COMPOUND (36) | | | | | | | | |
| 2-52 | *1 | ILLUSTRATED | ASYMMETRIC | 0.60 | 22 | Ag | 9 | — | — | — |
| | | COMPOUND (37) | | | | | | | | |
| 2-53 | *1 | ILLUSTRATED | ASYMMETRIC | 0.50 | 22 | Ag | 9 | — | — | — |
| | | COMPOUND (38) | | | | | | | | |
| 2-54 | *1 | ILLUSTRATED | ASYMMETRIC | 0.49 | 22 | Ag | 9 | — | — | — |
| | | COMPOUND (39) | | | | | | | | |
| 2-55 | *1 | ILLUSTRATED | ASYMMETRIC | 0.62 | 22 | Ag | 9 | — | — | — |
| | | COMPOUND (40) | | | | | | | | |
| 2-56 | *1 | ILLUSTRATED | ASYMMETRIC | 0.47 | 22 | Ag | 9 | — | — | — |
| | | COMPOUND (41) | | | | | | | | |
| 2-57 | *1 | ILLUSTRATED | ASYMMETRIC | 0.61 | 22 | Ag | 9 | — | — | — |
| | | COMPOUND (42) | | | | | | | | |
| 2-58 | *1 | ILLUSTRATED | ASYMMETRIC | 0.92 | 22 | Ag | 9 | — | — | — |
| | | COMPOUND (43) | | | | | | | | |
| 2-59 | *1 | ILLUSTRATED | ASYMMETRIC | 0.50 | 22 | Ag | 9 | — | — | — |
| | | COMPOUND (44) | | | | | | | | |
| 2-60 | *1 | ILLUSTRATED | ASYMMETRIC | 0.62 | 22 | Ag | 9 | — | — | — |
| | | COMPOUND (45) | | | | | | | | |
| 2-61 | *1 | ILLUSTRATED | ASYMMETRIC | 0.78 | 22 | Ag | 9 | — | — | — |
| | | COMPOUND (46) | | | | | | | | |
| 2-62 | *1 | ILLUSTRATED | ASYMMETRIC | 0.42 | 22 | Ag | 9 | — | — | — |
| | | COMPOUND (47) | | | | | | | | |
| 2-63 | *1 | ILLUSTRATED | ASYMMETRIC | 0.46 | 22 | Ag | 9 | — | — | — |
| | | COMPOUND (48) | | | | | | | | |
| 2-64 | *1 | ILLUSTRATED | ASYMMETRIC | 0.42 | 22 | Ag | 9 | — | — | — |
| | | COMPOUND (49) | | | | | | | | |
| 2-65 | *1 | ILLUSTRATED | ASYMMETRIC | 0.41 | 22 | Ag | 9 | — | — | — |
| | | COMPOUND (50) | | | | | | | | |
| 2-66 | *1 | ILLUSTRATED | ASYMMETRIC | 0.47 | 22 | Ag | 9 | — | — | — |
| | | COMPOUND (51) | | | | | | | | |
| 2-67 | *1 | ILLUSTRATED | ASYMMETRIC | 0.46 | 22 | Ag | 9 | — | — | — |
| | | COMPOUND (52) | | | | | | | | |
| 2-68 | *1 | ILLUSTRATED | ASYMMETRIC | 0.50 | 22 | Ag | 9 | — | — | — |
| | | COMPOUND (53) | | | | | | | | |
| 2-69 | *1 | ILLUSTRATED | ASYMMETRIC | 0.49 | 22 | Ag | 9 | — | — | — |
| | | COMPOUND (54) | | | | | | | | |
| 2-70 | *1 | ILLUSTRATED | ASYMMETRIC | 0.71 | 22 | Ag | 9 | — | — | — |
| | | COMPOUND (55) | | | | | | | | |
| 2-71 | *1 | ILLUSTRATED | ASYMMETRIC | 0.87 | 22 | Ag | 9 | — | — | — |
| | | COMPOUND (56) | | | | | | | | |
| 2-72 | *1 | ILLUSTRATED | ASYMMETRIC | 0.82 | 22 | Ag | 9 | — | — | — |
| | | COMPOUND (57) | | | | | | | | |
| 2-73 | *1 | ILLUSTRATED | ASYMMETRIC | 0.85 | 22 | Ag | 9 | — | — | — |
| | | COMPOUND (58) | | | | | | | | |
| 2-74 | *1 | ILLUSTRATED | ASYMMETRIC | 0.68 | 22 | Ag | 9 | — | — | — |
| | | COMPOUND (59) | | | | | | | | |
| 2-75 | *1 | ILLUSTRATED | ASYMMETRIC | 0.90 | 22 | Ag | 9 | — | — | — |
| | | COMPOUND (60) | | | | | | | | |

| | EVALUATION RESULT | | | |
|---|---|---|---|---|
| TRANS- | LIGHT | | | |
| PARENT | TRANSMIT- | | DURABILITY | |
| ELEC- | TANCE | SHEET | VARIATION | |
| TRODE | (550 nm) | RESISTANCE | PERCENTAGE OF | |
| NO. | (%) | (Ω/□) | TRANSMITTANCE | REMARK |
| 2-51 | 71 | 7.3 | 55 | PRESENT |
| | | | | INVENTION |
| 2-52 | 78 | 6.9 | 42 | PRESENT |
| | | | | INVENTION |
| 2-53 | 75 | 7.2 | 66 | PRESENT |
| | | | | INVENTION |
| 2-54 | 73 | 7.4 | 67 | PRESENT |
| | | | | INVENTION |
| 2-55 | 77 | 6.8 | 40 | PRESENT |
| | | | | INVENTION |
| 2-56 | 70 | 7.3 | 53 | PRESENT |
| | | | | INVENTION |
| 2-57 | 76 | 6.7 | 45 | PRESENT |
| | | | | INVENTION |
| 2-58 | 79 | 3.5 | 18 | PRESENT |
| | | | | INVENTION |
| 2-59 | 77 | 7.0 | 68 | PRESENT |
| | | | | INVENTION |
| 2-60 | 75 | 6.8 | 43 | PRESENT |
| | | | | INVENTION |
| 2-61 | 81 | 3.8 | 22 | PRESENT |
| | | | | INVENTION |
| 2-62 | 70 | 7.3 | 53 | PRESENT |
| | | | | INVENTION |
| 2-63 | 71 | 7.5 | 55 | PRESENT |
| | | | | INVENTION |
| 2-64 | 69 | 6.9 | 68 | PRESENT |
| | | | | INVENTION |
| 2-65 | 68 | 7.0 | 68 | PRESENT |
| | | | | INVENTION |
| 2-66 | 72 | 7.0 | 55 | PRESENT |
| | | | | INVENTION |
| 2-67 | 77 | 7.2 | 48 | PRESENT |
| | | | | INVENTION |
| 2-68 | 77 | 7.0 | 63 | PRESENT |
| | | | | INVENTION |
| 2-69 | 75 | 7.3 | 67 | PRESENT |
| | | | | INVENTION |
| 2-70 | 79 | 4.8 | 32 | PRESENT |
| | | | | INVENTION |
| 2-71 | 79 | 3.2 | 15 | PRESENT |
| | | | | INVENTION |
| 2-72 | 80 | 3.6 | 22 | PRESENT |
| | | | | INVENTION |
| 2-73 | 83 | 3.0 | 18 | PRESENT |
| | | | | INVENTION |
| 2-74 | 72 | 6.3 | 40 | PRESENT |
| | | | | INVENTION |
| 2-75 | 81 | 4.2 | 21 | PRESENT |
| | | | | INVENTION |

*1: ALKALI-FREE GLASS
*2: NITROGEN ATOM CONTENT PERCENTAGE [(THE NUMBER OF NITROGEN ATOMS/MOLECULAR WEIGHT) × 100)

TABLE 6

| | STRUCTURE OF TRANSPARENT ELECTRODE | | | | | | | | | |
|---|---|---|---|---|---|---|---|---|---|---|
| | (STRUCTURE SHOWN IN FIG. 1(a) OR FIG. 1(b)) | | | | | | | | | |
| TRANS- | | INTERMEDIATE LAYER | | | | CONDUCTIVE LAYER | | SECOND INTERMEDIATE | | |
| PARENT | | 1a | | | | 1b | | LAYER 1c | | |
| ELEC- | | | | | THICK- | | THICK- | | | THICK- |
| TRODE | BASE | COMPOUND | | | NESS | MATE- | NESS | MATE- | | NESS |
| NO. | TYPE | TYPE | STRUCTURE | *2 | (nm) | RIAL | (nm) | RIAL | *2 | (nm) |
| 2-76 | *1 | ILLUSTRATED | ASYMMETRIC | 0.89 | 22 | Ag | 9 | — | — | — |
| | | COMPOUND (61) | | | | | | | | |
| 2-77 | *1 | ILLUSTRATED | ASYMMETRIC | 0.50 | 22 | Ag | 9 | — | — | — |
| | | COMPOUND (62) | | | | | | | | |
| 2-78 | *1 | ILLUSTRATED | ASYMMETRIC | 0.80 | 22 | Ag | 9 | — | — | — |
| | | COMPOUND (63) | | | | | | | | |
| 2-79 | *1 | ILLUSTRATED | ASYMMETRIC | 0.41 | 22 | Ag | 9 | — | — | — |
| | | COMPOUND (64) | | | | | | | | |
| 2-80 | *1 | ILLUSTRATED | ASYMMETRIC | 0.50 | 22 | Ag | 9 | — | — | — |
| | | COMPOUND (65) | | | | | | | | |
| 2-81 | *1 | ILLUSTRATED | ASYMMETRIC | 0.52 | 22 | Ag | 9 | ILLUS- | 0.52 | 20 |
| | | COMPOUND (1) | | | | | | TRATED | | |
| | | | | | | | | COM- | | |
| | | | | | | | | POUND (1) | | |
| 2-82 | *1 | ILLUSTRATED | ASYMMETRIC | 0.51 | 22 | Ag | 9 | ILLUS- | 0.51 | 20 |
| | | COMPOUND (2) | | | | | | TRATED | | |
| | | | | | | | | COM- | | |
| | | | | | | | | POUND (2) | | |
| 2-83 | *1 | ILLUSTRATED | ASYMMETRIC | 0.54 | 22 | Ag | 9 | ILLUS- | 0.54 | 20 |
| | | COMPOUND (3) | | | | | | TRATED | | |
| | | | | | | | | COM- | | |
| | | | | | | | | POUND (3) | | |
| 2-84 | *1 | ILLUSTRATED | ASYMMETRIC | 0.46 | 22 | Ag | 9 | ILLUS- | 0.46 | 20 |
| | | COMPOUND (4) | | | | | | TRATED | | |
| | | | | | | | | COM- | | |
| | | | | | | | | POUND (4) | | |
| 2-85 | *1 | ILLUSTRATED | ASYMMETRIC | 0.56 | 22 | Ag | 9 | ILLUS- | 0.56 | 20 |
| | | COMPOUND (5) | | | | | | TRATED | | |
| | | | | | | | | COM- | | |
| | | | | | | | | POUND (5) | | |
| 2-86 | *1 | ILLUSTRATED | ASYMMETRIC | 0.82 | 22 | Ag | 9 | ILLUS- | 0.82 | 20 |
| | | COMPOUND (6) | | | | | | TRATED | | |
| | | | | | | | | COM- | | |
| | | | | | | | | POUND (6) | | |
| 2-87 | *1 | ILLUSTRATED | ASYMMETRIC | 1.04 | 22 | Ag | 9 | ILLUS- | 1.04 | 25 |
| | | COMPOUND (7) | | | | | | TRATED | | |
| | | | | | | | | COM- | | |
| | | | | | | | | POUND (7) | | |
| 2-88 | PET | ILLUSTRATED | ASYMMETRIC | 0.52 | 22 | Ag | 9 | — | — | — |
| | | COMPOUND (1) | | | | | | | | |
| 2-89 | PET | ILLUSTRATED | ASYMMETRIC | 0.82 | 22 | Ag | 9 | — | — | — |
| | | COMPOUND (6) | | | | | | | | |
| 2-90 | PET | ILLUSTRATED | ASYMMETRIC | 1.04 | 22 | Ag | 9 | — | — | — |
| | | COMPOUND (7) | | | | | | | | |

| | EVALUATION RESULT | | | |
|---|---|---|---|---|
| TRANS- | LIGHT | | | |
| PARENT | TRANSMIT- | | DURABILITY | |
| ELEC- | TANCE | SHEET | VARIATION | |
| TRODE | (550 nm) | RESISTANCE | PERCENTAGE OF | |
| NO. | (%) | (Ω/□) | TRANSMITTANCE | REMARK |
| 2-76 | 83 | 3.3 | 18 | PRESENT |
| | | | | INVENTION |
| 2-77 | 74 | 7.1 | 65 | PRESENT |
| | | | | INVENTION |
| 2-78 | 82 | 3.1 | 18 | PRESENT |
| | | | | INVENTION |
| 2-79 | 63 | 6.8 | 67 | PRESENT |
| | | | | INVENTION |
| 2-80 | 72 | 7.4 | 57 | PRESENT |
| | | | | INVENTION |
| 2-81 | 71 | 6.7 | 47 | PRESENT |
| | | | | INVENTION |
| 2-82 | 73 | 6.3 | 42 | PRESENT |
| | | | | INVENTION |
| 2-83 | 75 | 6.1 | 40 | PRESENT |
| | | | | INVENTION |
| 2-84 | 78 | 5.8 | 29 | PRESENT |
| | | | | INVENTION |
| 2-85 | 80 | 5.1 | 27 | PRESENT |
| | | | | INVENTION |
| 2-86 | 81 | 3.9 | 18 | PRESENT |
| | | | | INVENTION |
| 2-87 | 84 | 3.3 | 10 | PRESENT |
| | | | | INVENTION |
| 2-88 | 70 | 7.1 | 67 | PRESENT |
| | | | | INVENTION |
| 2-89 | 81 | 4.1 | 23 | PRESENT |
| | | | | INVENTION |
| 2-90 | 82 | 3.3 | 14 | PRESENT |
| | | | | INVENTION |

*1: ALKALI-FREE GLASS
*2: NITROGEN ATOM CONTENT PERCENTAGE [(THE NUMBER OF NITROGEN ATOMS/MOLECULAR WEIGHT) × 100]

As it is obvious from the result shown in TABLES 3 to 6, all the transparent electrodes 2-12 to 2-80 of embodiments of the invention, in which a conductive layer composed of silver (Ag) as a main component was disposed on an intermediate layer formed with a compound having a nitrogen atom(s) having an unshared electron pair uninvolved in aromaticity, had a light transmittance of 61% or more and a sheet resistance of 10Ω/□ or less. This is considered that the intermediate layer formed with the compound having a nitrogen atom(s) having an unshared electron pair uninvolved in aromaticity kept the silver layer formed thereon from cohering and mottles from being generated, and consequently even when a silver layer having a thickness of certain degree was formed, silver was kept from cohering, and both high optical transparency and low sheet resistance were achieved.

Further, it was confirmed that the transparent electrodes 2-81 to 2-87 each having the structure in which the conductive layer was sandwiched between the two intermediate layers achieved more favorite result.

On the other hand, the transparent electrodes 2-1 to 2-4 as comparative examples having no intermediate layer were incapable of achieving optical transparency and sheet resistance together because, although the sheet resistance decreased as the conductive layer as a silver layer was thicker, the light transmittance significantly decreased by silver cohesion (mottles) which occurred when the conductive layer was formed. The transparent electrodes 2-5 to 2-8 respectively using Alq₃, ET-1, ET-2 and ET-3 for their intermediate layers also had low light transmittance and were incapable of achieving reduction in sheet resistance to a desired condition.

### Fourth Example

### Production of Luminescent Panels 2-1 to 2-90

[Production of Luminescent Panel 2-1]

A top-and-bottom emission type luminescent panel 2-1 having the structure (but having no intermediate layer 1a) shown in FIG. 6 was produced through the procedure described below by using, as an anode, the transparent electrode 2-1 produced in Third Example.

First, a transparent substrate 13 having the transparent electrode 1 formed of only the conductive layer 1b produced in Third Example was fixed to a substrate holder of a commercial vacuum deposition device, and a vapor deposition mask was disposed in such a way as to face a formation face of the transparent electrode 1 (conductive layer 1b only). Further, heating boards in the vacuum deposition device were filled with materials for respective layers constituting a light-emitting functional layer 3 at their respective amounts optimal to form the layers. The heating boards used were composed of a tungsten material for resistance heating.

Next, the pressure of a vapor deposition room of the vacuum deposition device was reduced to 4×10⁻⁴ Pa, and the heating boards having the respective materials therein were electrically heated successively so that the layers, described below, constituting the light-emitting functional layer 3 were formed.

First, the heating board having therein α-NPD as a positive hole transport/injection material was electrically heated, and a positive hole transport.injection layer 31 composed of α-NPD and functioning as both a positive hole injection layer and a positive hole transport layer was formed on the conductive layer 1b of the transparent electrode 1. At the time, the deposition rate was within a range from 0.1 nm/sec to 0.2 nm/sec, and vapor deposition was carried out under a condition that the thickness became 20 nm.

Next, the heating board having therein the illustrated compound H4 as a host compound and the heating board having therein the illustrated compound Ir-4 as a phosphorescent compound were independently electrified, and a luminescent layer 3c composed of the illustrated compound H4 as a host compound and the illustrated compound Ir-4 as a phosphorescent compound was formed on the positive hole transport.injection layer 31. At the time, under a condition that the deposition rate (nm/sec) of the illustrated compound H4:the deposition rate (nm/sec) of the illustrated compound Ir-4=100:6 held, electrification conditions of the heating boards were suitably adjusted so that the thickness of the luminescent layer became 30 nm.

Next, the heating board having therein BAlq as a positive hole block material was electrically heated, and a positive hole block layer 33 composed of BAlq was formed on the luminescent layer 3c. At the time, the deposition rate was within a range from 0.1 nm/sec to 0.2 nm/sec, and vapor deposition was carried out under a condition that the thickness became 10 nm.

After that, the heating boards having therein ET-5 shown below and potassium fluoride, respectively, as electron transport materials were independently electrified, and an electron transport layer 3d composed of ET-5 and potassium fluoride was formed on the positive hole block layer 33. At the time, under a condition that the deposition rate (nm/sec) of ET-5: the deposition rate (nm/sec) of potassium fluoride=75:25 held, electrification conditions of the heating boards were suitably adjusted so that vapor deposition was carried out in such a way that the thickness of the electron transport layer 3d became 30 nm.

Next, the heating board having therein potassium fluoride as an electron injection material was electrically heated, and an electron injection layer 3e composed of potassium fluoride was formed on the electron transport layer 3d. At the time, the deposition rate was within a range from 0.01 nm/sec to 0.02 nm/sec, and vapor deposition was carried out in such away that the thickness became 1 nm.

After that, the transparent substrate 13 on which the layers up to the electron injection layer 3e had been formed was transferred from the vapor deposition room of the vacuum deposition device into a treatment room of a sputtering device, the treatment room in which an ITO target as a counter electrode material had been placed, keeping its vacuum state. Next, in the treatment room, an optically transparent counter electrode 5a composed of ITO having a thickness of 150 nm was formed at a deposition rate of 0.3 nm/sec to 0.5 nm/sec as a cathode.

Thus, an organic EL element 400 was formed on the transparent substrate 13.

Next, the organic EL element 400 was covered with a sealing member 17 composed of a glass substrate having a thickness of 300 μm, and the space between the sealing member 17 and the transparent substrate 13 was filled with an adhesive 19 (a seal material) in such a way that the organic EL element 400 was enclosed. As the adhesive 19, an epoxy-based photo-curable adhesive (LUXTRAK LC0629B produced by Toagosei Co., Ltd.) was used. The adhesive 19, with which the space between the sealing member 17 and the transparent substrate 13 was filled, was irradiated with UV light from the glass substrate (sealing member 17) side, thereby being cured, so that the organic EL element 400 was sealed.

In forming the organic EL element 400, a vapor deposition mask was used for forming each layer so that the center having an area of 4.5 cm×4.5 cm of the transparent substrate 13 having an area of 5 cm×5 cm became a luminescent region A, and a non-luminescent region B having a width of 0.25 cm was provided all around the luminescent region A. Further, the transparent electrode 1 as an anode and the counter electrode 5a as a cathode were formed in shapes of leading to the periphery of the transparent substrate 13, their terminal portions being on the periphery of the transparent substrate 13, while being insulated from each other by the light-emitting functional layer 3 composed of the layers from the positive hole transport.injection layer 31 to the electron injection layer 35.

Thus, the luminescent panel 2-1, in which the organic EL element 400 was disposed on the transparent substrate 13 and sealed by the sealing member 17 and with the adhesive 19, was obtained. In the luminescent panel 2-1, emission light h of colors generated in the luminescent layer 3c was extracted from both the transparent electrode 1 side, namely, the transparent substrate 13 side, and the counter electrode 5a side, namely, the sealing member 17 side.

[Production of Luminescent Panels 2-2 to 2-90]

Luminescent panels 2-2 to 2-90 were each produced in the same way as the luminescent panel 2-1, except that, instead of the transparent electrode 2-1, the transparent electrodes 2-2 to 2-90 produced in Third Example were used, respectively.

<<Evaluation of Luminescent Panels 2-1 to 2-90>>

With respect to each of the produced luminescent panels 2-1 to 2-90, light transmittance, driving voltage and durability were evaluated by the methods described below.

[Light Transmittance Measurement]

With respect to each of the produced luminescent panels, light transmittance (%) at a wavelength of 550 nm was measured with a spectrophotometer (U-3300 manufactured by Hitachi, Ltd.) with the base which was used for producing each of the transparent electrodes as a reference.

[Driving Voltage Measurement]

Front luminance was measured on both the transparent electrode 1 side (i.e. transparent substrate 13 side) and the counter electrode 5a side (i.e. sealing member 17 side) of each of the produced luminescent panels, and a voltage of the time when the sum thereof was 1000 cd/m² was determined as the driving voltage (V). The luminance was measured with a spectroradiometer CS-1000 (manufactured by Konica Minolta Inc.). The smaller the obtained value of the driving voltage is, the more favorable result it means.

[Evaluation of Durability: Variation Width of Transmittance under Constant Current]

With respect to each of the produced luminescent panels, a variation percentage of transmittance was measured as follows; a current of 125 mA/cm² was applied thereto at 30° C. for 200 hours, and a variation percentage of the after-200-hours transmittance to the initial transmittance was determined by the following equation.

Variation Percentage of Transmittance=(Initial Transmittance After−200-Hours Transmittance)/Initial Transmittance×100

The variation percentage of transmittance of each luminescent panel is shown as a relative value with the variation percentage thereof of the luminescent panel 2-8 as 100.

The obtained result is shown in TABLES 7 and 8.

TABLE 7

| | | LIGHT | | | |
|---|---|---|---|---|---|
| LUMINESCENT | TRANSPARENT | TRANSMITTANCE | | DURABILITY | |
| PANEL | ELECTRODE | (550 nm) | DRIVING VOLTAGE | VARIATION PERCENTAGE | |
| NO. | NO. | (%) | (V) | OF TRANSMITTANCE | REMARK |
| 2-1 | 2-1 | 24 | NO LIGHT EMITTED | 193 | COMPARATIVE EXAMPLE |
| 2-2 | 2-2 | 36 | NO LIGHT EMITTED | 199 | COMPARATIVE EXAMPLE |
| 2-3 | 2-3 | 30 | 5.0 | 173 | COMPARATIVE EXAMPLE |
| 2-4 | 2-4 | 18 | 3.5 | 155 | COMPARATIVE EXAMPLE |
| 2-5 | 2-5 | 41 | 4.4 | 139 | COMPARATIVE EXAMPLE |
| 2-6 | 2-6 | 44 | 4.2 | 131 | COMPARATIVE EXAMPLE |
| 2-7 | 2-7 | 42 | 4.2 | 125 | COMPARATIVE EXAMPLE |
| 2-8 | 2-8 | 40 | 4.1 | 100 | COMPARATIVE EXAMPLE |
| 2-9 | 2-9 | 50 | 3.8 | 95 | PRESENT INVENTION |
| 2-10 | 2-10 | 49 | 3.8 | 89 | PRESENT INVENTION |
| 2-11 | 2-11 | 55 | 3.9 | 83 | PRESENT INVENTION |
| 2-12 | 2-12 | 65 | 3.6 | 75 | PRESENT INVENTION |
| 2-13 | 2-13 | 63 | 3.5 | 71 | PRESENT INVENTION |
| 2-14 | 2-14 | 69 | 3.4 | 67 | PRESENT INVENTION |
| 2-15 | 2-15 | 61 | 3.3 | 69 | PRESENT INVENTION |
| 2-16 | 2-16 | 60 | 3.2 | 70 | PRESENT INVENTION |
| 2-17 | 2-17 | 71 | 3.2 | 53 | PRESENT INVENTION |
| 2-18 | 2-18 | 72 | 3.2 | 47 | PRESENT INVENTION |
| 2-19 | 2-19 | 75 | 3.1 | 37 | PRESENT INVENTION |
| 2-20 | 2-20 | 77 | 3.1 | 35 | PRESENT INVENTION |
| 2-21 | 2-21 | 79 | 3.1 | 23 | PRESENT INVENTION |
| 2-22 | 2-22 | 80 | 3.0 | 13 | PRESENT INVENTION |
| 2-23 | 2-23 | 78 | 3.2 | 24 | PRESENT INVENTION |
| 2-24 | 2-24 | 76 | 3.2 | 25 | PRESENT INVENTION |
| 2-25 | 2-25 | 71 | 3.7 | 41 | PRESENT INVENTION |
| 2-26 | 2-26 | 76 | 3.4 | 44 | PRESENT INVENTION |
| 2-27 | 2-27 | 80 | 2.7 | 24 | PRESENT INVENTION |
| 2-28 | 2-28 | 72 | 3.2 | 40 | PRESENT INVENTION |
| 2-29 | 2-29 | 70 | 3.6 | 45 | PRESENT INVENTION |
| 2-30 | 2-30 | 69 | 3.5 | 58 | PRESENT INVENTION |
| 2-31 | 2-31 | 74 | 3.3 | 30 | PRESENT INVENTION |
| 2-32 | 2-32 | 72 | 2.9 | 29 | PRESENT INVENTION |
| 2-33 | 2-33 | 65 | 3.3 | 51 | PRESENT INVENTION |
| 2-34 | 2-34 | 75 | 3.5 | 43 | PRESENT INVENTION |
| 2-35 | 2-35 | 77 | 3.0 | 25 | PRESENT INVENTION |
| 2-36 | 2-36 | 69 | 3.4 | 60 | PRESENT INVENTION |
| 2-37 | 2-37 | 77 | 3.4 | 38 | PRESENT INVENTION |
| 2-38 | 2-38 | 68 | 3.5 | 53 | PRESENT INVENTION |
| 2-39 | 2-39 | 72 | 3.4 | 47 | PRESENT INVENTION |
| 2-40 | 2-40 | 73 | 3.5 | 46 | PRESENT INVENTION |
| 2-41 | 2-41 | 79 | 2.9 | 16 | PRESENT INVENTION |
| 2-42 | 2-42 | 75 | 3.6 | 33 | PRESENT INVENTION |
| 2-43 | 2-43 | 79 | 3.3 | 32 | PRESENT INVENTION |
| 2-44 | 2-44 | 69 | 3.6 | 56 | PRESENT INVENTION |
| 2-45 | 2-45 | 75 | 3.0 | 19 | PRESENT INVENTION |

TABLE 8

| LUMINESCENT | TRANSPARENT | LIGHT TRANSMITTANCE | | DURABILITY | |
|---|---|---|---|---|---|
| PANEL | ELECTRODE | (550 nm) | DRIVING VOLTAGE | VARIATION PERCENTAGE | |
| NO. | NO. | (%) | (V) | OF TRANSMITTANCE | REMARK |
| 2-46 | 2-46 | 71 | 3.3 | 46 | PRESENT INVENTION |
| 2-47 | 2-47 | 78 | 2.9 | 19 | PRESENT INVENTION |
| 2-48 | 2-48 | 77 | 2.9 | 17 | PRESENT INVENTION |
| 2-49 | 2-49 | 70 | 3.4 | 58 | PRESENT INVENTION |
| 2-50 | 2-50 | 68 | 3.5 | 61 | PRESENT INVENTION |
| 2-51 | 2-51 | 67 | 3.5 | 56 | PRESENT INVENTION |
| 2-52 | 2-52 | 73 | 3.3 | 44 | PRESENT INVENTION |
| 2-53 | 2-53 | 70 | 3.4 | 68 | PRESENT INVENTION |
| 2-54 | 2-54 | 68 | 3.5 | 65 | PRESENT INVENTION |
| 2-55 | 2-55 | 72 | 3.2 | 42 | PRESENT INVENTION |
| 2-56 | 2-56 | 65 | 3.5 | 51 | PRESENT INVENTION |
| 2-57 | 2-57 | 71 | 3.2 | 47 | PRESENT INVENTION |
| 2-58 | 2-58 | 73 | 3.0 | 19 | PRESENT INVENTION |
| 2-59 | 2-59 | 72 | 3.4 | 66 | PRESENT INVENTION |
| 2-60 | 2-60 | 71 | 3.2 | 45 | PRESENT INVENTION |
| 2-61 | 2-61 | 77 | 3.0 | 24 | PRESENT INVENTION |
| 2-62 | 2-62 | 68 | 3.6 | 51 | PRESENT INVENTION |
| 2-63 | 2-63 | 68 | 3.5 | 57 | PRESENT INVENTION |
| 2-64 | 2-64 | 67 | 3.6 | 68 | PRESENT INVENTION |
| 2-65 | 2-65 | 65 | 3.6 | 68 | PRESENT INVENTION |
| 2-66 | 2-66 | 69 | 3.4 | 56 | PRESENT INVENTION |
| 2-67 | 2-67 | 72 | 3.4 | 47 | PRESENT INVENTION |
| 2-68 | 2-68 | 72 | 3.2 | 61 | PRESENT INVENTION |
| 2-69 | 2-69 | 71 | 3.2 | 65 | PRESENT INVENTION |
| 2-70 | 2-70 | 76 | 3.0 | 34 | PRESENT INVENTION |
| 2-71 | 2-71 | 75 | 2.9 | 17 | PRESENT INVENTION |
| 2-72 | 2-72 | 78 | 2.9 | 23 | PRESENT INVENTION |
| 2-73 | 2-73 | 77 | 2.9 | 18 | PRESENT INVENTION |
| 2-74 | 2-74 | 68 | 3.3 | 42 | PRESENT INVENTION |
| 2-75 | 2-75 | 77 | 2.8 | 20 | PRESENT INVENTION |
| 2-76 | 2-76 | 79 | 2.8 | 18 | PRESENT INVENTION |
| 2-77 | 2-77 | 70 | 3.4 | 66 | PRESENT INVENTION |
| 2-78 | 2-78 | 77 | 3.0 | 19 | PRESENT INVENTION |
| 2-79 | 2-79 | 60 | 3.6 | 65 | PRESENT INVENTION |
| 2-80 | 2-80 | 68 | 3.4 | 59 | PRESENT INVENTION |
| 2-81 | 2-81 | 67 | 3.2 | 47 | PRESENT INVENTION |
| 2-82 | 2-82 | 68 | 3.1 | 44 | PRESENT INVENTION |
| 2-83 | 2-83 | 69 | 3.1 | 42 | PRESENT INVENTION |
| 2-84 | 2-84 | 73 | 3.1 | 28 | PRESENT INVENTION |
| 2-85 | 2-85 | 75 | 3.0 | 29 | PRESENT INVENTION |
| 2-86 | 2-86 | 76 | 3.0 | 19 | PRESENT INVENTION |
| 2-87 | 2-87 | 80 | 3.0 | 12 | PRESENT INVENTION |
| 2-88 | 2-88 | 66 | 3.4 | 65 | PRESENT INVENTION |
| 2-89 | 2-89 | 76 | 3.1 | 25 | PRESENT INVENTION |
| 2-90 | 2-90 | 78 | 3.0 | 17 | PRESENT INVENTION |

As it is obvious from the result shown in TABLES 7 and 8, all the luminescent panels 2-12 to 2-90 of embodiments of the invention each using the transparent electrode in accordance with one or more embodiments of the invention as an anode of the organic EL element had a light transmittance of 60% or more and a driving voltage of 3.7 V or less. On the other hand, all the luminescent panels 2-1 to 2-8 each using the transparent electrode of the comparative example as an anode of the organic EL element had a light transmittance of less than 45%, and some of them did not emit light even when a voltage was applied or emitted light with a driving voltage of more than 4.0 V.

Thus, it was confirmed that the luminescent panels each provided with the organic EL element in accordance with one or more embodiments of the invention using the transparent electrode having the structure defined by one or more embodiments of the invention were capable of light emission with high luminescence at a low driving voltage and also were excellent in durability. Accordingly, it was confirmed that reduction in driving voltage for obtaining a predetermined luminescence and extension of emission life were expected.

### INDUSTRIAL APPLICABILITY

As described above, embodiments of the invention are suitable to provide a transparent electrode having sufficient conductivity and optical transparency, and an electronic device and an organic electroluminescent element each provided with the transparent electrode, thereby capable of being driven at a low voltage.

Although the disclosure has been described with respect to only a limited number of embodiments, those skilled in the art, having benefit of this disclosure, will appreciate that various other embodiments may be devised without departing from the scope of the present invention. Accordingly, the scope of the invention should be limited only by the attached claims.

### DESCRIPTION OF REFERENCE NUMERALS

1 Transparent Electrode
1a, 1c Intermediate Layer
1b Conductive Layer
3 Light-Emitting Functional Layer
3a Positive Hole Injection Layer
3b Positive Hole Transport Layer
3c Luminescent Layer
3d Electron Transport Layer
3e Electron Injection Layer
5a, 5b, 5c Counter Electrode
11 Base
13, 131 Transparent Substrate
13a, 131a Light Extraction Face
15 Auxiliary Electrode
17 Sealing Member
19 Adhesive
21 Illumination Device
22 Luminescent Panel
23 Support Substrate
31 Positive Hole Transport Injection Layer
33 Positive Hole Block Layer
100, 200, 300, 400 Organic EL Element
A Luminescent Region
B Non-Luminescent Region
h Emission Light

1. A transparent electrode comprising:
a conductive layer; and
an intermediate layer disposed adjacent to the conductive layer, wherein
the intermediate layer contains an asymmetric compound having a nitrogen atom having an unshared electron pair uninvolved in aromaticity, and
the conductive layer is composed of silver as a main component.

2. The transparent electrode according to claim 1, wherein a content percentage of the nitrogen atom having the unshared electron pair uninvolved in aromaticity in the asymmetric compound determined by an equation (1) below is 0.40 or more:
Content Percentage of Nitrogen Atom=(The Number of Nitrogen Atoms Having Unshared Electron Pairs Uninvolved in Aromaticity/Molecular Weight of Asymmetric Compound)×100. Equation (1)

3. The transparent electrode according to claim 1, wherein the asymmetric compound has an aromatic heterocyclic ring containing a nitrogen atom having an unshared electron pair uninvolved in aromaticity.

4. The transparent electrode according to claim 1, wherein the asymmetric compound has an azacarbazole ring, an azadibenzofuran ring or an azadibenzothiophene ring.

5. The transparent electrode according to claim 1, wherein the asymmetric compound has an azacarbazole ring.

6. The transparent electrode according to claim 1, wherein the asymmetric compound has a pyridine ring.

7. The transparent electrode according to claim 1, wherein the asymmetric compound has a γ,γ′-diazacarbazole ring or a β-carboline ring.

8. An electronic device comprising the transparent electrode according claim 1.

9. An organic electroluminescent element comprising the transparent electrode according to claim 1.
